(19) United States
(12) Patent Application Publication
(10) Pub. No.: US 2024/0329534 A1
(43) Pub. Date: Oct. 3, 2024

(54) FILM-FORMING COMPOSITION, RESIST PATTERN FORMATION METHOD, AND POLYHEDRAL OLIGOMERIC SILSESQUIOXANE

(71) Applicant: TOKYO OHKA KOGYO CO., LTD., Kawasaki-shi (JP)

(72) Inventors: Keiichi Ibata, Kawasaki-shi (JP); Hayato Ouchi, Kawasaki-shi (JP)

(21) Appl. No.: 18/606,762

(22) Filed: Mar. 15, 2024

(30) Foreign Application Priority Data
Mar. 20, 2023 (JP) 2023-044212

(51) Int. Cl. G03F 7/075; G03F 7/004

(52) U.S. Cl. CPC G03F 7/0757; G03F 7/0045

(57) ABSTRACT

A film-forming composition including a polyhedral oligomeric silsesquioxane represented by General Formula (a1), an acid generating agent component, and a crosslinking agent component. In Formula (a1), R¹ to R⁸ represent an aromatic group containing a phenolic hydroxyl group, a hydrocarbon group having 1 to 10 carbon atoms, or a hydrogen atom; at least one of R¹ to R⁸ represents an aromatic group containing a phenolic hydroxyl group; L¹ to L⁸ represent a specific divalent linking group at least one of L¹ to L⁸ represents a divalent linking group represented by General Formula (a1-L-2) or General Formula (a1-L-3), Z^{X} and Z^{Y} represent a hydrocarbon group having 1 to 6 carbon atoms or a hydrogen atom, and n2 and n3 represent an integer of 0 to 10).

### BACKGROUND OF THE INVENTION

### Field of the Invention

The present invention relates to a film-forming composition, a resist pattern formation method, and a polyhedral oligomeric silsesquioxane.

Priority is claimed on Japanese Patent Application No. 2023-044212, filed on Mar. 20, 2023, the content of which is incorporated herein by reference.

### Description of Related Art

In the manufacture of electronic components, a treatment including etching is carried out on a laminate in which a resist film is formed on a substrate such as a silicon wafer using a resist material. For example, a treatment in which a resist pattern is formed on a resist film by selectively exposing the resist film, and dry etching is carried out using the resist film as a mask to form a pattern on the substrate is performed.

In recent years, in the manufacture of semiconductor elements and liquid crystal display elements, advances in lithography technologies have led to rapid progress in the field of pattern fining. These pattern fining techniques typically involve shortening the wavelength (increasing the energy) of the exposure light source.

Resist materials require lithography characteristics such as a high resolution that enables reproduction of patterns with fine dimensions, and a high level of sensitivity to these kinds of exposure light sources.

As a resist material that satisfies these requirements, a chemically amplified resist composition containing a base material component whose solubility in a developing solution is changed due to an action of an acid and an acid generating agent component that generates an acid upon light exposure has been used.

In the chemically amplified resist composition, a resin having a plurality of constitutional units is typically used in order to improve lithography characteristics and the like. In addition, a chemically amplified resist composition in which an acid generating agent component is used in combination with an acid diffusion control agent that controls the diffusion of an acid generated from the acid generating agent component upon light exposure has been suggested.

Further, as the resist material, a material having etching resistance is required in order to fulfill the function as a mask for substrate processing. Meanwhile, a silicon-containing compound has been typically used as a base material component.

For example, Patent Document 1 discloses a resist composition containing a silicon-containing resin, an acid generating agent component, and a photodecomposable base that controls the diffusion of an acid in order to cope with pattern fining and etching processing.

### CITATION LIST

### Patent Document

[Patent Document 1] Japanese Unexamined Patent Application, First Publication No. 2022-59575

### SUMMARY OF THE INVENTION

With further advances in lithography techniques, rapid progress in the field of pattern fining is being achieved together with the expansion of application fields. In association with this, in a case of producing a semiconductor element or the like, a technique of forming a pattern with fine dimensions in a favorable shape is required. For example, lithography using an extreme ultraviolet ray (EUV) aims to form a fine pattern with a size of several tens of nanometers. As the pattern dimensions decrease as described above, both etching resistance and lithography characteristics are difficult to achieve.

Meanwhile, a film-forming composition containing a silicon-containing compound as a base material component as disclosed in Patent Document 1 is advantageous in terms of high dry etching resistance as compared with a film-forming composition that uses a typical organic material as a base material component, but is required to further improve an effect of reducing pattern roughness in the formation of a target fine pattern.

The present invention has been made in consideration of the above-described circumstances, and an object of the present invention is to provide a film-forming composition containing a silicon-containing compound and having an enhanced effect of reducing pattern roughness, a resist pattern formation method using the film-forming composition, and a silicon-containing compound useful as a base material component of the film-forming composition.

In order to achieve the above-described object, the present invention employs the following configurations.

That is, according to a first aspect of the present invention, there is provided a film-forming composition including: a silicon-containing compound (A); an acid generating agent component that generates an acid upon light exposure; and a crosslinking agent component, in which the silicon-containing compound (A) contains a polyhedral oligomeric silsesquioxane (A1) represented by General Formula (a1).

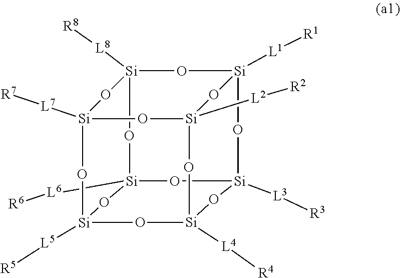

[In Formula (a1), R¹ to R⁸ each independently represent an aromatic group containing a phenolic hydroxyl group, a hydrocarbon group having 1 to 10 carbon atoms, or a hydrogen atom. Here, at least one of R¹ to R⁸ represents an aromatic group containing a phenolic hydroxyl group. L¹ to L⁸ each independently represent a divalent linking group represented by any one of General Formulae (a1-L-1) to (a1-L-6). Here, at least one of L¹ to L⁸ represents a divalent linking group represented by General Formula (a1-L-2) or General Formula (a1-L-3).]

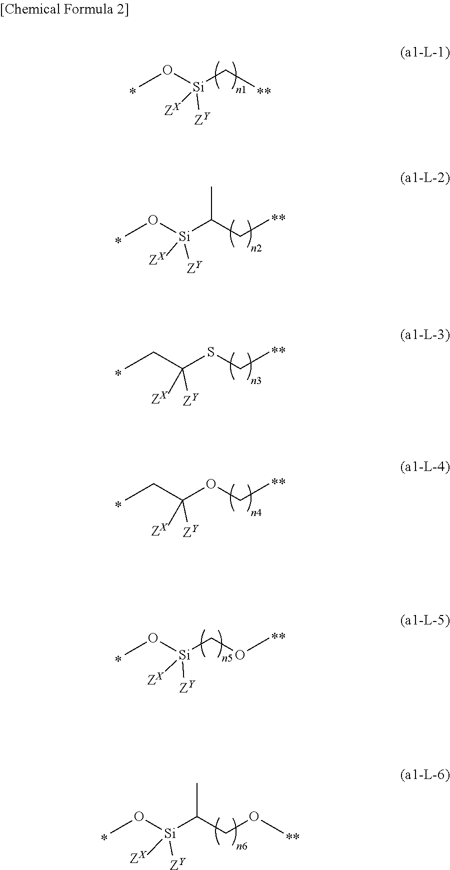

[In Formulae (a1-L-1) to (a1-L-6), Z^{X} and Z^{Y} each independently represent a hydrocarbon group having 1 to 6 carbon atoms or a hydrogen atom. n1 to n6 each independently represent an integer of 0 to 10. * represents a bonding site with respect to Si. ** represents a bonding site with respect to any one of R¹ to R⁸.]

According to a second aspect of the present invention, there is provided a resist pattern formation method including: a step of forming a resist film on a support using the film-forming composition according to the first aspect; a step of exposing the resist film to light; and a step of developing the resist film exposed to light to form a negative-tone resist pattern.

According to a third aspect of the present invention, there is provided a polyhedral oligomeric silsesquioxane represented by General Formula (a0).

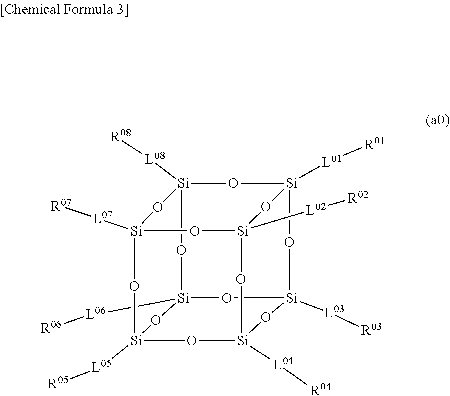

[In Formula (a0), R⁰¹ to R⁰⁸ each independently represent an aromatic group containing a phenolic hydroxyl group, a hydrocarbon group having 1 to 10 carbon atoms, or a hydrogen atom. Here, at least one of R⁰¹ to R⁰⁸ represents an aromatic group containing a phenolic hydroxyl group. L⁰¹ to L⁰⁸ each independently represent a divalent linking group represented by any one of General Formulae (a0-L-1) to (a0-L-3), (a0-L-5), and (a0-L-6).]

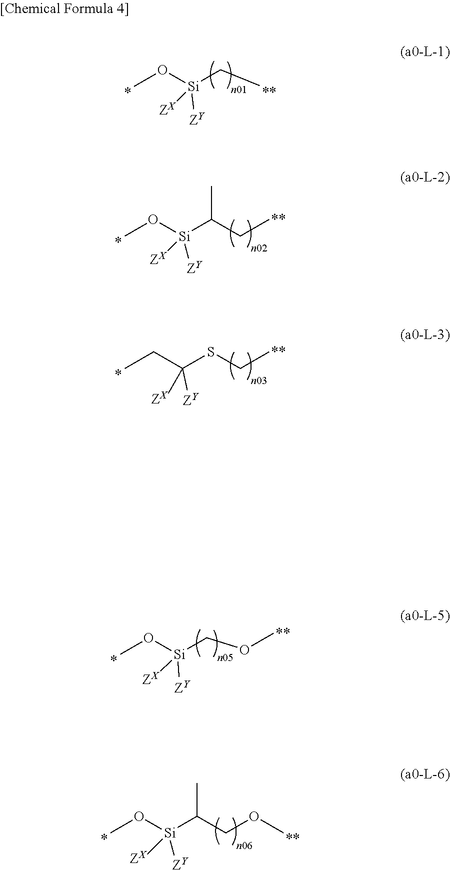

[In Formulae (a0-L-1) to (a0-L-3), (a0-L-5), and (a0-L-6), Z^{X} and Z^{Y} each independently represent a hydrocarbon group having 1 to 6 carbon atoms or a hydrogen atom. n01 represents an integer of 3 or greater. n02 represents an integer of 1 or greater. n03 represents an integer of 0 or greater. n05 represents an integer of 2 or greater. n06 represents an integer of 0 or greater. * represents a bonding site with respect to Si. ** represents a bonding site with respect to any one of R⁰¹ to R⁰⁸.]

According to the present invention, it is possible to provide a film-forming composition containing a silicon-containing compound and having an enhanced effect of reducing pattern roughness, a resist pattern formation method using the film-forming composition, and a silicon-containing compound useful as a base material component of the film-forming composition.

### DETAILED DESCRIPTION OF THE INVENTION

In the present specification and the scope of the present claims, the term “aliphatic” is a relative concept used in relation to the term “aromatic”, and defines a group or compound that has no aromaticity.

The term “alkyl group” includes a linear, branched, or cyclic monovalent saturated hydrocarbon group unless otherwise specified. The same applies to the alkyl group in an alkoxy group.

The term “alkylene group” includes a linear, branched, or cyclic divalent saturated hydrocarbon group unless otherwise specified.

Examples of “halogen atom” include a fluorine atom, a chlorine atom, a bromine atom, and an iodine atom. The term “constitutional unit” indicates a monomer unit constituting a high molecular weight compound (a resin, a polymer, or a copolymer).

The expression “may have a substituent” includes both a case where a hydrogen atom (—H) is substituted with a monovalent group and a case where a methylene (—CH₂—) group is substituted with a divalent group.

The term “exposure” is used as a general concept that includes irradiation with active energy rays such as an ultraviolet ray, a radiation, and an electron beam.

The term “acid decomposable group” indicates a group having acid decomposability in which at least a part of a bond in the structure of the acid decomposable group can be cleaved due to the action of an acid.

Examples of the acid decomposable group whose polarity is increased due to the action of an acid include groups which are decomposed due to the action of an acid to generate a polar group.

Examples of the polar group include a carboxy group, a hydroxyl group, an amino group, and a sulfo group (—SO₃H).

More specific examples of the acid decomposable group include a group in which the above-described polar group has been protected by an acid dissociable group (such as a group in which a hydrogen atom of the OH-containing polar group has been protected by an acid dissociable group).

Here, the term “acid dissociable group” indicates both a group (i) having an acid dissociation property in which a bond between the acid dissociable group and an atom adjacent to the acid dissociable group can be cleaved due to the action of an acid and a group (ii) in which some bonds are cleaved due to the action of an acid, a decarboxylation reaction occurs, and thus the bond between the acid dissociable group and the atom adjacent to the acid dissociable group can be cleaved.

It is necessary that the acid dissociable group that constitutes the acid decomposable group is a group which exhibits a lower polarity than that of the polar group generated by the dissociation of the acid dissociable group. Thus, in a case where the acid dissociable group is dissociated by the action of an acid, a polar group exhibiting a higher polarity than that of the acid dissociable group is generated so that the polarity is increased. As a result, the polarity of the entire component containing this acid dissociable group is increased. Due to the increase in the polarity, the solubility in a developing solution is relatively changed such that the solubility is increased in a case where the developing solution is an alkali developing solution and the solubility is decreased in a case where the developing solution is an organic developing solution.

The term “base material component” denotes an organic compound having a film-forming ability. Organic compounds used as the base material component are classified into non-polymers and polymers. As the non-polymers, those having a molecular weight of 500 or greater and less than 4,000 are typically used. Hereinafter, the term “low-molecular-weight compound” denotes a non-polymer having a molecular weight of 500 or greater and less than 4,000. As the polymer, those having a molecular weight of 1,000 or greater are typically used. Hereinafter, “resin”, “high molecular weight compound”, or “polymer” denotes a polymer having a molecular weight of 1,000 or greater. As the molecular weight of the polymer, the weight-average molecular weight in terms of polystyrene according to gel permeation chromatography (GPC) is used.

The expression “constitutional unit to be derived” denotes a constitutional unit formed by cleavage of a multiple bond between carbon atoms, for example, an ethylenic double bond.

In the present specification and the scope of the present claims, asymmetric carbons may be present and enantiomers or diastereomers may be present depending on the structures of the chemical formulae. In this case, these isomers are represented by one chemical formula. These isomers may be used alone or in the form of a mixture.

### (Film-Forming Composition)

A film-forming composition according to a first aspect of the present invention is a composition which generates an acid upon light exposure and whose solubility in a developing solution is changed due to an action of an acid. Such a film-forming composition according to an embodiment contains a silicon-containing compound (A) (hereinafter, also referred to as “component (A)”), an acid generating agent component (B) that generates an acid upon light exposure (hereinafter, also referred to as “component (B)”), and a crosslinking agent component (C) (hereinafter, also referred to as “component (C)”). The component (A) contains a polyhedral oligomeric silsesquioxane (A1) represented by General Formula (a1).

The film-forming composition according to the present embodiment is suitable for applications for which a cured film is used and, for example, can be used as a composition for a so-called resist mask in a case of performing etching in the formation of a processing pattern in the semiconductor manufacturing process, a composition for a hard mask, or a composition for forming a resist underlayer film formed between a support and a resist film.

The film-forming composition according to the present embodiment may be used for an alkali developing process in which an alkali developing solution is used in a developing treatment in the resist pattern formation, or may be used for a solvent developing process in which a developing solution containing an organic solvent (organic developing solution) is used in the developing treatment.

In a case where the film-forming composition according to the present embodiment is “negative-tone resist composition for an alkali developing process” that forms a negative-tone resist pattern in an alkali developing process or “positive-tone resist composition for a solvent developing process” that forms a positive-tone resist pattern in a solvent developing process, a polymer that is soluble in an alkali developing solution is used as a preferable component (A), and the component (C) is further blended thereinto. In such a film-forming composition, in a case where an acid is generated from the component (B) upon light exposure, the acid acts to cause crosslinking between the polymer that is soluble in an alkali developing solution and the component (C), and as a result, the solubility in an alkali developing solution is decreased (the solubility in an organic developing solution is increased).

Therefore, in the resist pattern formation, in a case where a resist film obtained by coating a support with the film-forming composition is selectively exposed to light, the exposed portions of the resist film becomes insoluble in an alkali developing solution (soluble in an organic developing solution), whereas the unexposed portions of the resist film remain soluble in an alkali developing solution (insoluble in an organic developing solution), and thus a negative-tone resist pattern is formed by carrying out development with an alkali developing solution. Alternatively, in this case, a positive-tone resist pattern is formed by performing development with the organic developing solution.

That is, in a case where the film-forming composition according to the present embodiment is “positive-tone resist composition for an alkali developing process” that forms a positive-tone resist pattern in an alkali developing process or “negative-tone resist composition for a solvent developing process” that forms a negative-tone resist pattern in a solvent developing process, a polymer whose polarity is increased due to the action of an acid is used as a preferable component (A). In a case where a polymer whose polarity is increased due to the action of an acid is used, the polarity of the polymer changes before and after light exposure, and thus an excellent development contrast can be obtained not only in the alkali developing process but also in the solvent developing process.

In a case of applying an alkali developing process, the polymer whose polarity is increased due to the action of an acid is insoluble in an alkali developing solution before the light exposure, but in a case where an acid is generated from the component (B) upon light exposure, the polarity is increased due to the action of the acid, and the solubility in an alkali developing solution is increased.

Therefore, in the resist pattern formation, in a case where a resist film obtained by coating a support with the film-forming composition is selectively exposed to light, the exposed portions of the resist film becomes soluble from being insoluble in an alkali developing solution, whereas the unexposed portions of the resist film remain insoluble in an alkali, and thus a positive-tone resist pattern is formed by carrying out alkali development. Alternatively, in this case, a negative-tone resist pattern is formed by performing development with an organic developing solution.

Here, the film-forming composition according to the present embodiment is particularly useful for the alkali developing process, and is suitable as “negative-tone resist composition for an alkali developing process”.

### <Silicon-Containing Compound (A)>

In the film-forming composition according to the present embodiment, the silicon-containing compound (A) contains a polyhedral oligomeric silsesquioxane. In the film-forming composition according to the present embodiment, at least a polyhedral oligomeric silsesquioxane (A1) represented by General Formula (a1) (hereinafter, also referred to as “component (A1)”) is used as the polyhedral oligomeric silsesquioxane.

### <<Polyhedral Oligomeric Silsesquioxane Represented by General Formula (A1)>>

In the film-forming composition according to the present embodiment, the component (A1) is a polyhedral oligomeric silsesquioxane represented by General Formula (a1), which is a siloxane with a complete cage type structure containing a phenolic hydroxyl group in a molecule.

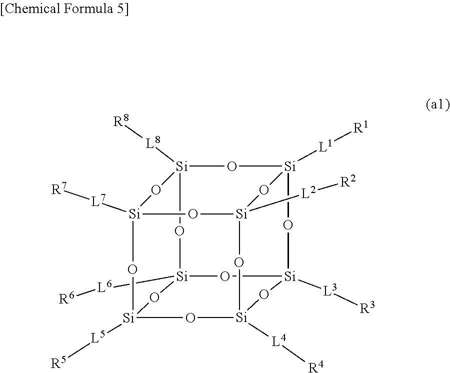

[In Formula (a1), R¹ to R⁸ each independently represent an aromatic group containing a phenolic hydroxyl group, a hydrocarbon group having 1 to 10 carbon atoms, or a hydrogen atom. Here, at least one of R¹ to R⁸ represents an aromatic group containing a phenolic hydroxyl group. L¹ to L⁸ each independently represent a divalent linking group represented by any one of General Formulae (a1-L-1) to (a1-L-6). Here, at least one of L¹ to L⁸ represents a divalent linking group represented by General Formula (a1-L-2) or General Formula (a1-L-3).]

In Formula (a1), examples of the aromatic group of the aromatic group containing a phenolic hydroxyl group as R¹ to R⁸ include a hydrocarbon group having at least one aromatic ring. The aromatic ring here is not particularly limited as long as the aromatic ring is a cyclic conjugated system having (4n+2) π electrons and may be monocyclic or polycyclic. The aromatic ring has preferably 5 to 30 carbon atoms, more preferably 5 to 20 carbon atoms, still more preferably 6 to 15 carbon atoms, and particularly preferably 6 to 12 carbon atoms. Here, the number of carbon atoms in a substituent is not included in the number of carbon atoms. Specific examples of the aromatic ring include benzene, naphthalene, anthracene, and phenanthrene. Among these, benzene or naphthalene is preferable, and benzene is more preferable.

Examples of the aromatic group include a group (an arylene group) in which two hydrogen atoms have been removed from the aromatic ring and a group in which two hydrogen atoms have been removed from an aromatic compound (such as biphenyl or fluorene) having two or more aromatic rings.

The number of phenolic hydroxyl groups contained in the aromatic group as R¹ to R⁸ is preferably 1, 2, or 3, more preferably 1 or 2, and particularly preferably 1 for one aromatic group.

In the aromatic group, the hydrogen atom bonded to the aromatic ring may be substituted with a substituent other than the phenolic hydroxyl group. Examples of substituents include an alkyl group, a halogenated alkyl group, and a halogen atom.

Examples of the alkyl group as the substituent include an alkyl group having 1 to 5 carbon atoms, and the alkyl group may be linear or branched. Examples of the halogenated alkyl group as the substituent include a group in which some or all hydrogen atoms in an alkyl group having 1 to 5 carbon atoms have been substituted with halogen atoms. The halogen atom as the substituent is preferably a fluorine atom.

The hydrocarbon group having 1 to 10 carbon atoms as R¹ to R⁸ may be linear, branched, or cyclic, and it is preferable that the hydrocarbon group is linear or branched. Further, the hydrocarbon group here may be a saturated hydrocarbon group or an unsaturated hydrocarbon group and is preferably a saturated hydrocarbon group. Here, the number of carbon atoms of the hydrocarbon group is preferably in a range of 1 to 6, more preferably in a range of 1 to 5, and still more preferably in a range of 1 to 3. Among the examples, a methyl group, an ethyl group, a propyl group, or an isopropyl group is more preferable, a methyl group or an ethyl group is still more preferable, and a methyl group is particularly preferable.

Here, in Formula (a1), at least one of R¹ to R⁸ represents an aromatic group containing a phenolic hydroxyl group.

Specific suitable examples of R¹ to R⁸ are shown below. * represents a bonding site with respect to any of L¹ to L⁸.

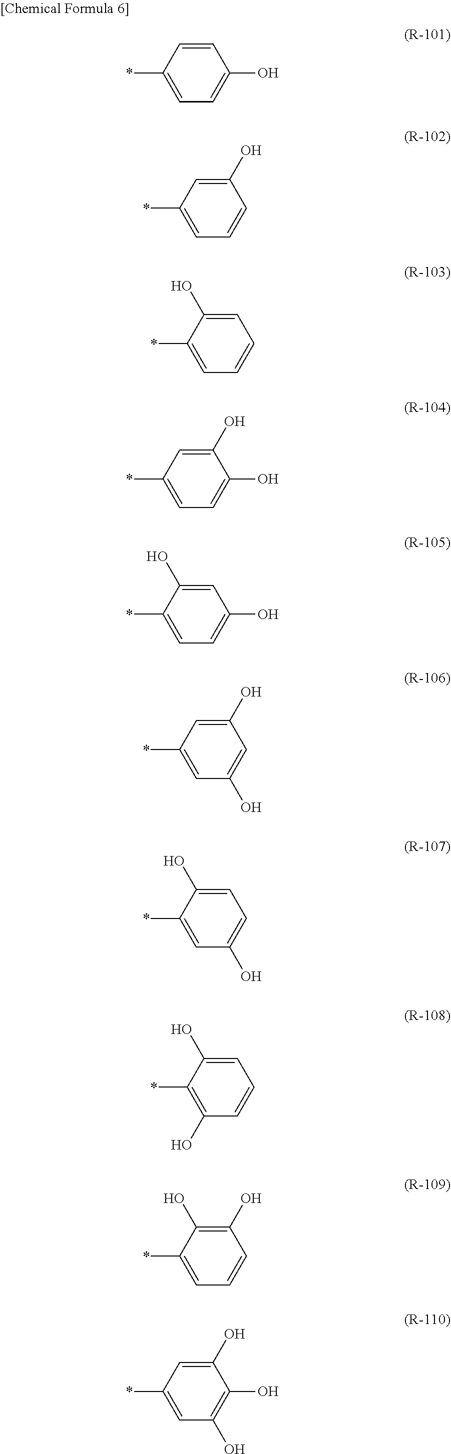

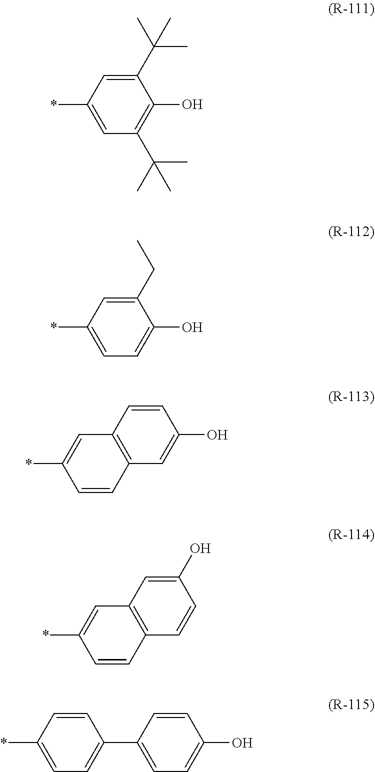

R¹ to R⁸ represent a group preferably selected from the group consisting of groups each represented by Chemical Formulae (R-101) to (R-115), more preferably selected from the group consisting of groups each represented by Chemical Formulae (R-101) to (R-109), and particularly preferably selected from the group consisting of groups each represented by Chemical Formulae (R-101) to (R-104).

In Formula (a1), L¹ to L⁸ each independently represent a divalent linking group represented by any of General Formulae (a1-L-1) to (a1-L-6).

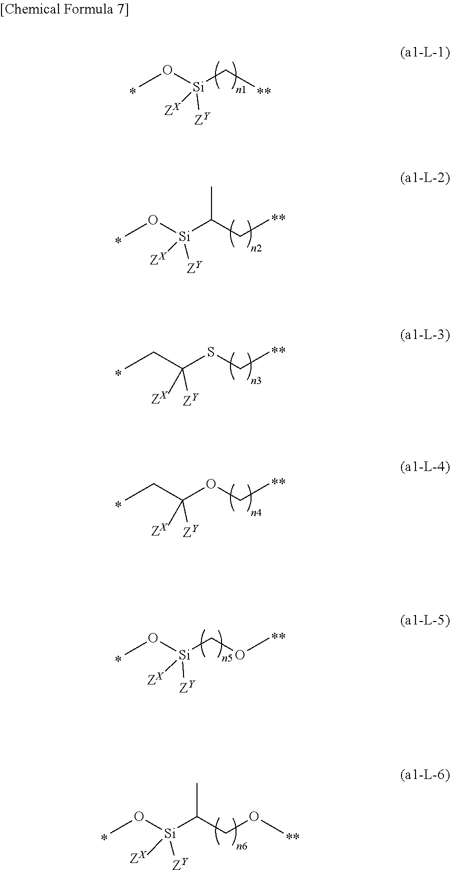

[In Formulae (a1-L-1) to (a1-L-6), Z^{X} and Z^{Y} each independently represent a hydrocarbon group having 1 to 6 carbon atoms or a hydrogen atom. n1 to n6 each independently represent an integer of 0 to 10. * represents a bonding site with respect to Si. ** represents a bonding site with respect to any one of R¹ to R⁸.]

In Formulae (a1-L-1) to (a1-L-6), the hydrocarbon group having 1 to 6 carbon atoms as Z^{X} and Z^{Y} may be any of linear, branched, or cyclic and is preferably linear or branched. Further, the hydrocarbon group as Z^{X} and Z^{Y} may be a saturated hydrocarbon group or an unsaturated hydrocarbon group and is preferably a saturated hydrocarbon group.

The hydrocarbon group as Z^{X} and Z^{Y} has 1 to 6 carbon atoms, preferably 1 to 5 carbon atoms, and more preferably 1 to 3 carbon atoms. Among these, a methyl group, an ethyl group, a propyl group, or an isopropyl group is more preferable, a methyl group or an ethyl group is still more preferable, and a methyl group is particularly preferable.

In Formulae (a1-L-1) and (a1-L-2), it is preferable that Z^{X} and Z^{Y} each represent a hydrocarbon group having 1 to 6 carbon atoms, Z^{X} and Z^{Y} both represent more preferably a hydrocarbon group having 1 to 6 carbon atoms, still more preferably a hydrocarbon group having 1 to 3 carbon atoms, and particularly preferably a methyl group.

In Formula (a1-L-3), Z^{X} and Z^{Y} preferably each represent a hydrogen atom and more preferably both represent a hydrogen atom.

In Formula (a1-L-4), Z^{X} and Z^{Y} preferably each represent a hydrogen atom and more preferably both represent a hydrogen atom.

In Formulae (a1-L-5) and (a1-L-6), it is preferable that Z^{X} and Z^{Y} each represent a hydrocarbon group having 1 to 6 carbon atoms, Z^{X} and Z^{Y} both represent more preferably a hydrocarbon group having 1 to 6 carbon atoms, still more preferably a hydrocarbon group having 1 to 3 carbon atoms, and particularly preferably a methyl group.

In Formula (a1-L-1), n1 represents preferably an integer of 0 to 7, more preferably an integer of 2 to 5, and still more preferably 2 or 3.

In Formula (a1-L-2), n2 represents preferably an integer of 0 to 5, more preferably an integer of 0 to 3, and still more preferably 0 or 1.

In Formula (a1-L-3), n3 represents preferably an integer of 0 to 5, more preferably an integer of 0 to 3, and still more preferably 0 or 1.

In Formula (a1-L-4), n4 represents preferably an integer of 0 to 5, more preferably an integer of 0 to 3, and still more preferably 1.

In Formula (a1-L-5), n5 represents preferably an integer of 0 to 8, more preferably an integer of 2 to 5, and still more preferably 2 or 3.

In Formula (a1-L-6), n6 represents preferably an integer of 0 to 6, more preferably an integer of 0 to 3, and still more preferably 0 or 1.

Here, in Formula (a1), at least one of L¹ to L⁸ represents a divalent linking group represented by General Formula (a1-L-2) or (a1-L-3).

Specific suitable examples of L¹ to L⁸ are shown below. * represents a bonding site with respect to Si. ** represents a bonding site with respect to any of R¹ to R⁸.

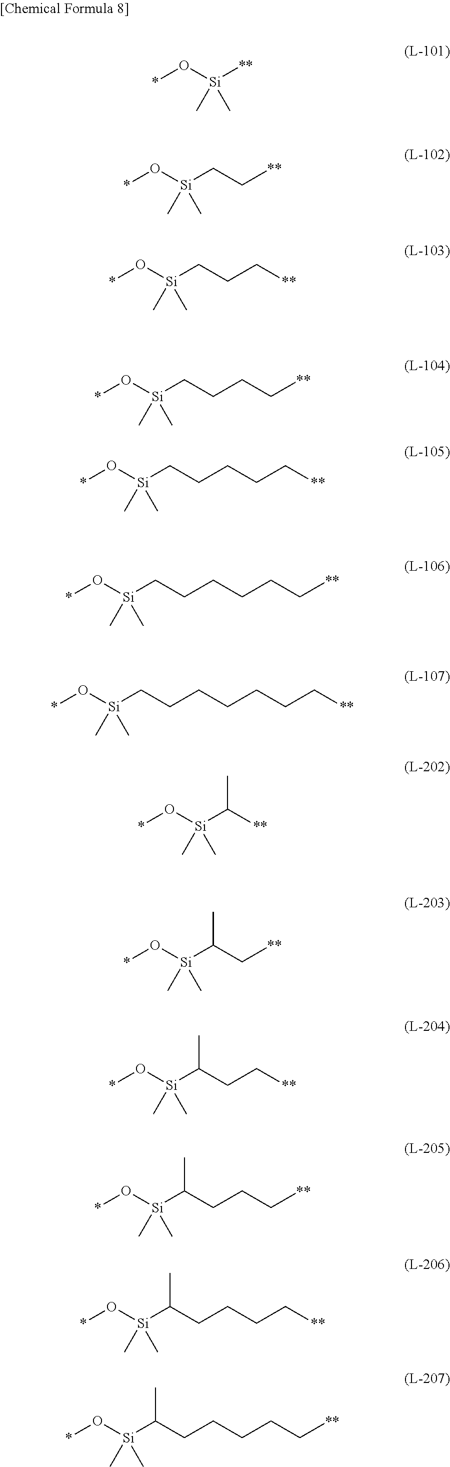

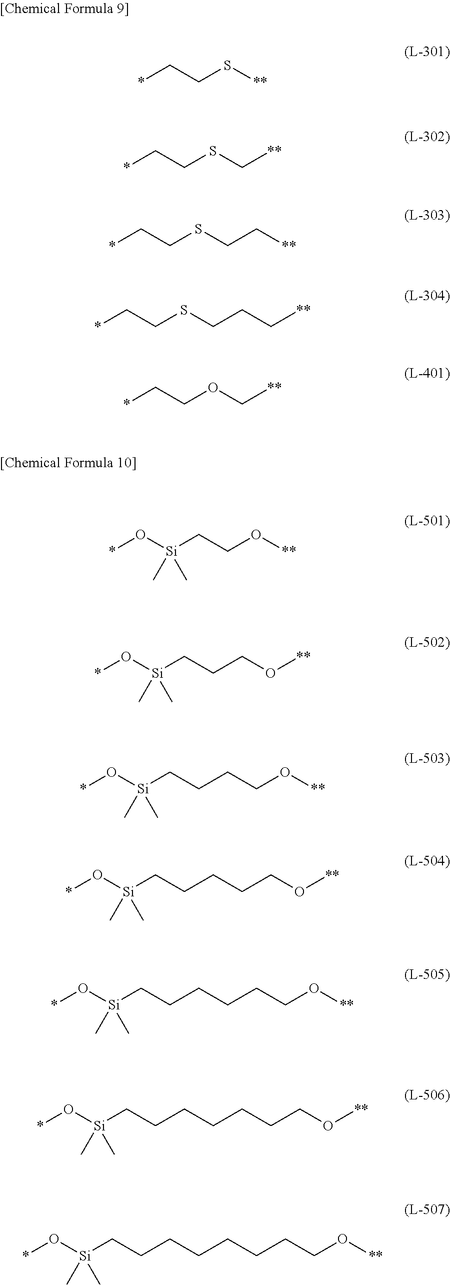

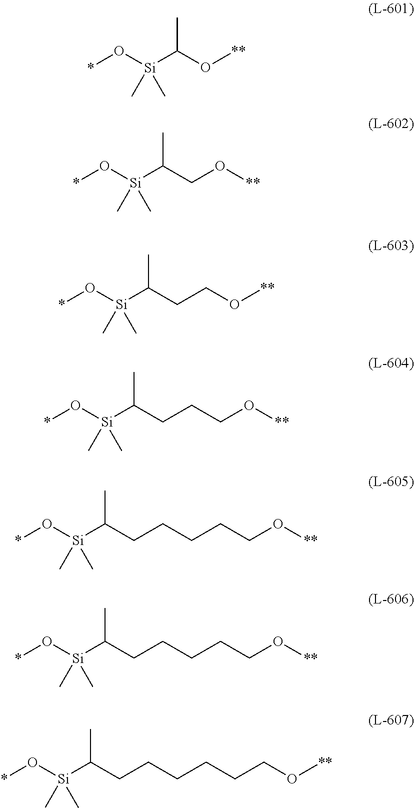

L¹ to L⁸ represent a divalent linking group selected from the group consisting of groups each represented by Formulae (a1-L-1) to (a1-L-6) and more preferably a divalent linking group selected from the group consisting of groups each represented by Formulae (a1-L-1) to (a1-L-3).

Alternatively, L¹ to L⁸ represent preferably a group selected from the group consisting of groups each represented by Chemical Formulae (L-101) to (L-107), groups each represented by Chemical Formulae (L-202) to (L-207), groups each represented by Chemical Formulae (L-301) to (L-304), a group represented by Chemical Formula (L-401), groups each represented by Chemical Formulae (L-501) to (L-507), and groups each represented by Chemical Formulae (L-601) to (L-607), more preferably a group selected from the group consisting of groups each represented by Chemical Formulae (L-101) to (L-107), groups each represented by Chemical Formulae (L-202) to (L-207), and groups each represented by Chemical Formulae (L-301) to (L-304), and still more preferably a group selected from the group consisting of groups each represented by Chemical Formula (L-102), Chemical Formula (L-103), Chemical Formula (L-202), Chemical Formula (L-203), Chemical Formula (L-301), and Chemical Formula (L-302).

The weight-average molecular weight (Mw) (in terms of polystyrene according to gel permeation chromatography (GPC)) of the component (A1) is not particularly limited, but is preferably in a range of 1,000 to 4,000, more preferably in a range of 1,200 to 3,000, and still more preferably in a range of 1,500 to 2,500.

The solubility in a solvent is sufficiently high in a case where the Mw of the component (A1) is less than or equal to the upper limits of the above-described preferable ranges, and dry etching resistance is enhanced and the cross-sectional shape of the resist pattern is satisfactory in a case where the Mw is greater than or equal to the lower limits of the above-described preferable ranges.

Further, the dispersity (Mw/Mn) of the component (A1) is not particularly limited, but is preferably in a range of 1.0 to 1.2, more preferably in a range of 1.0 to 1.1, and particularly preferably in a range of 1.0 to 1.05.

Further, Mn represents the number average molecular weight.

Specific suitable examples of the polyhedral oligomeric silsesquioxane (A1) are shown below. * represents a bonding site with respect to Si constituting the cage.

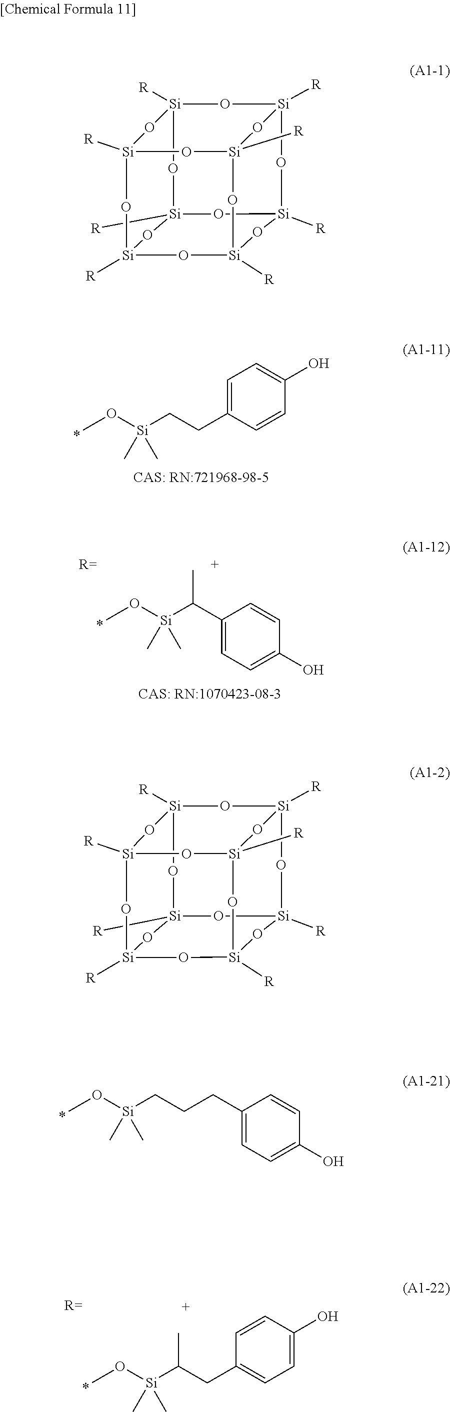

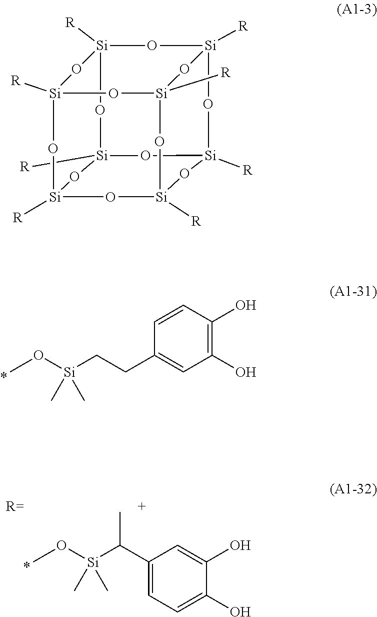

A polyhedral oligomeric silsesquioxane (A1-1) is a polymer in which a group (group that contains an aromatic group containing a phenolic hydroxyl group) represented by Chemical Formula (A1-11) on the upper side and a group (group that contains an aromatic group containing a phenolic hydroxyl group) represented by Chemical Formula (A1-12) on the lower side are bonded to R in the cage type structure.

The polymer in which a group (group that contains an aromatic group containing a phenolic hydroxyl group) represented by Chemical Formula (A1-11) on the upper side is bonded to all R's in the cage type structure is represented by CAS RN: 721968-98-5.

The polymer in which a group (group that contains an aromatic group containing a phenolic hydroxyl group) represented by Chemical Formula (A1-12) on the lower side is bonded to all R's in the cage type structure is represented by CAS RN: 1070423-08-3.

A polyhedral oligomeric silsesquioxane (A1-2) is a polymer in which a group (group that contains an aromatic group containing a phenolic hydroxyl group) represented by Chemical Formula (A1-21) on the upper side and a group (group that contains an aromatic group containing a phenolic hydroxyl group) represented by Chemical Formula (A1-22) on the lower side are bonded to R in the cage type structure.

A polyhedral oligomeric silsesquioxane (A1-3) is a polymer in which a group (group that contains an aromatic group containing a phenolic hydroxyl group) represented by Chemical Formula (A1-31) on the upper side and a group (group that contains an aromatic group containing a phenolic hydroxyl group) represented by Chemical Formula (A1-32) on the lower side are bonded to R in the cage type structure.

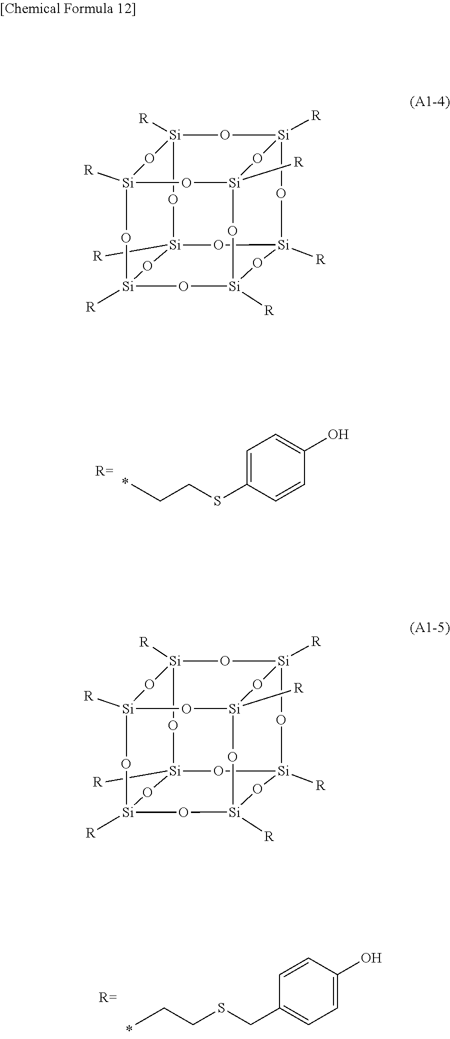

A polyhedral oligomeric silsesquioxane (A1-4) is a polymer in which the group represented by the above-described chemical formula (group that contains an aromatic group containing a phenolic hydroxyl group) is bonded to R in the cage type structure.

A polyhedral oligomeric silsesquioxane (A1-5) is a polymer in which the group represented by the above-described chemical formula (group that contains an aromatic group containing a phenolic hydroxyl group) is bonded to R in the cage type structure.

The component (A1) contained in the film-forming composition according to the present embodiment may be used alone or in combination of two or more kinds thereof.

The component (A1) is preferably selected from the group consisting of polyhedral oligomeric silsesquioxanes each represented by Chemical Formulae (A1-1) to (A1-5) and more preferably selected from the group consisting of polyhedral oligomeric silsesquioxanes each represented by Chemical Formula (A1-1), Chemical Formula (A1-2), Chemical Formula (A1-4), and Chemical Formula (A1-5) from the viewpoint of increasing the sensitivity.

Alternatively, from the viewpoint of the effects of increasing the sensitivity and reducing roughness, it is more preferable that the component (A1) is selected from the group consisting of polyhedral oligomeric silsesquioxanes each represented by Chemical Formula (A1-1) and Chemical Formula (A1-2).

### <<Other Siloxanes>>

Other siloxanes in addition to the component (A1) may be used as the component (A).

Examples of the other siloxanes include a silsesquioxane other than the component (A1) and a polysiloxane such as silicone having a linear main chain.

Examples of the silsesquioxane other than the component (A1) include those having a random structure, a ladder type structure, and an incomplete cage type structure.

In the film-forming composition of the present embodiment, the total content of the polyhedral oligomeric silsesquioxanes including the polyhedral oligomeric silsesquioxane (A1) in the silicon-containing compound (A) is preferably 70% by mass or greater and may be 80% by mass or greater, 90% by mass or greater, or 100% by mass with respect to the total mass of the silicon-containing compound (A).

The effect of reducing pattern roughness is more likely to be exhibited as the total content of the polyhedral oligomeric silsesquioxanes increases.

In the film-forming composition according to the present embodiment, the content of the component (A1) in the entire polyhedral oligomeric silsesquioxane is preferably 50% by mass or higher, more preferably 75% by mass or higher, and may be 80% by mass or greater, 90% by mass or greater, 100% by mass, and most preferably 100% by mass with respect to the total mass of the entire polyhedral oligomeric silsesquioxane.

The effect of reducing pattern roughness is more likely to be exhibited as the content of the component (A1) increases.

In the film-forming composition of the present embodiment, the content of the silicon-containing compound (A) is preferably less than 5% by mass, more preferably 2% by mass or less, still more preferably 1% by mass or less, and particularly preferably 0.10% by mass or greater and 1% by mass or less with respect to the total mass of the film-forming composition.

In a case where the content of the silicon-containing compound (A) is in the above-described preferable ranges, the film thickness can be effectively reduced in the pattern formation.

### <Acid Generating Agent Component>

The film-forming composition according to the present embodiment contains an acid generating agent component (component (B)) that generates an acid upon light exposure in addition to the silicon-containing compound (A) and the crosslinking agent component. The component (B) here functions as an acid component that causes crosslinking between the component (A1) described above and the crosslinking agent component described below in the film-forming composition.

The component (B) is not particularly limited, and those which have been suggested as an acid generating agent for a chemically amplified resist composition in the related art can be used.

Examples of the acid generating agent include various acid generating agents, for example, onium salt-based acid generating agents such as iodonium salts and sulfonium salts; oxime sulfonate-based acid generating agents; diazomethane-based acid generating agents such as bisalkyl or bisaryl sulfonyl diazomethanes and poly(bis-sulfonyl)diazomethanes; nitrobenzyl sulfonate-based acid generating agents, iminosulfonate-based acid generating agents, and disulfone-based acid generating agents.

Preferred examples of such a component (B) include an onium salt represented by General Formula (b0) (hereinafter, also referred to as “component (B0)”).

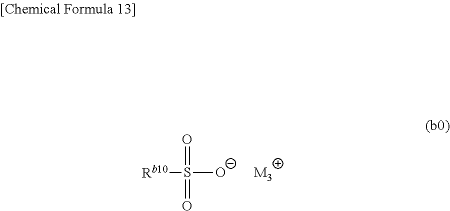

[In Formula (b0), R^{b10} represents an organic group having 1 to 40 carbon atoms. M₃⁺ represents an onium cation.]

In Formula (b0), examples of the organic group as R^{b10} include a hydrocarbon group which may have a substituent, a divalent linking group having an oxygen atom, and a combination thereof.

Preferred examples of the onium salt include a sulfonate represented by General Formula (b0-1b).

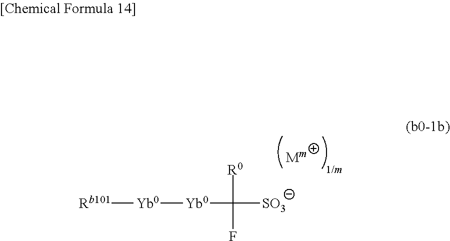

[In Formula (b0-1b), Rb¹⁰¹ represents a cyclic group which may have a substituent, a chain-like alkyl group which may have a substituent, or a chain-like alkenyl group which may have a substituent. Yb⁰ represents a divalent linking group or a single bond, Vb⁰ represents a single bond, an alkylene group, or a fluorinated alkylene group, R⁰ represents a hydrogen atom, a fluorinated alkyl group having 1 to 5 carbon atoms, or a fluorine atom, Mⁿ⁺ represents an m-valent onium cation. m represents an integer of 1 or greater.]In regard to anion moiety

Cyclic Group which May have Substituent:

In Formula (B0-1b), the cyclic group as R^{b101} is preferably a cyclic hydrocarbon group and the cyclic hydrocarbon group may be an aromatic hydrocarbon group or an aliphatic hydrocarbon group. The aliphatic hydrocarbon group indicates a hydrocarbon group that has no aromaticity. Further, the aliphatic hydrocarbon group may be saturated or unsaturated. In general, it is preferable that the aliphatic hydrocarbon group is saturated.

The aromatic hydrocarbon group as R^{b101} is a hydrocarbon group having an aromatic ring. The aromatic hydrocarbon group has preferably 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. Here, the number of carbon atoms in a substituent is not included in the number of carbon atoms.

Specific examples of the aromatic ring contained in the aromatic hydrocarbon group as R^{b101} include benzene, fluorene, naphthalene, anthracene, phenanthrene, biphenyl, or an aromatic heterocyclic ring obtained by substituting part of carbon atoms constituting this aromatic ring with a hetero atom. Examples of the hetero atom in the aromatic heterocyclic rings include an oxygen atom, a sulfur atom, and a nitrogen atom.

Specific examples of the aromatic hydrocarbon group as R^{b101} include a group in which one hydrogen atom has been removed from the above-described aromatic ring (an aryl group such as a phenyl group or a naphthyl group), and a group in which one hydrogen atom in the aromatic ring has been substituted with an alkylene group (for example, an arylalkyl group such as a benzyl group, a phenethyl group, a 1-naphthylmethyl group, a 2-naphthylmethyl group, 1-naphthylethyl group, or a 2-naphthylethyl group). The alkylene group (an alkyl chain in the arylalkyl group) has preferably 1 to 4 carbon atoms, more preferably 1 or 2 carbon atoms, and particularly preferably 1 carbon atom.

Examples of the cyclic aliphatic hydrocarbon group as R^{b101} include aliphatic hydrocarbon groups containing a ring in the structure thereof.

Examples of the aliphatic hydrocarbon group having a ring in the structure thereof include an alicyclic hydrocarbon group (group in which one hydrogen atom has been removed from an aliphatic hydrocarbon ring), a group in which the alicyclic hydrocarbon group is bonded to the terminal of a linear or branched aliphatic hydrocarbon group, and a group in which the alicyclic hydrocarbon group is interposed in the middle of a linear or branched aliphatic hydrocarbon group.

The alicyclic hydrocarbon group has preferably 3 to 20 carbon atoms and more preferably 3 to 12 carbon atoms.

The alicyclic hydrocarbon group may be a polycyclic group or a monocyclic group. As the monocyclic alicyclic hydrocarbon group, a group in which one or more hydrogen atoms have been removed from a monocycloalkane is preferable. The monocycloalkane has preferably 3 to 6 carbon atoms, and specific examples thereof include cyclopentane and cyclohexane. As the polycyclic alicyclic hydrocarbon group, a group in which one or more hydrogen atoms have been removed from a polycycloalkane is preferable, and the number of carbon atoms of the polycycloalkane is preferably in a range of 7 to 30. Among these, a polycycloalkane having a crosslinked ring polycyclic skeleton such as adamantane, norbornane, isobornane, tricyclodecane, or tetracyclododecane; and a polycycloalkane having a fused ring polycyclic skeleton such as a cyclic group having a steroid skeleton are preferable as the polycycloalkane.

Among these examples, as the cyclic aliphatic hydrocarbon group as R^{b101}, a group in which one or more hydrogen atoms have been removed from a monocycloalkane or a polycycloalkane is preferable, a group in which one hydrogen atom has been removed from a polycycloalkane is more preferable, an adamantyl group or a norbornyl group is particularly preferable, and an adamantyl group is most preferable.

The linear aliphatic hydrocarbon group which may be bonded to the alicyclic hydrocarbon group has preferably 1 to 10 carbon atoms, more preferably 1 to 6 carbon atoms, still more preferably 1 to 4 carbon atoms, and most preferably 1 to 3 carbon atoms. As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group which may be bonded to the alicyclic hydrocarbon group has preferably 2 to 10 carbon atoms, more preferably 3 to 6 carbon atoms, still more preferably 3 or 4 carbon atoms, and most preferably 3 carbon atoms. As the branched chain-like aliphatic hydrocarbon group, a branched chain-like alkylene group is preferable, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As the alkyl group in the alkylalkylene group, a linear alkyl group having 1 to 5 carbon atoms is preferable.

The cyclic hydrocarbon group as R^{b101} may contain a hetero atom such as a heterocyclic ring.

The cyclic hydrocarbon group as R^{b101} may be a fused cyclic group containing a fused ring in which an aliphatic hydrocarbon ring and an aromatic ring are fused. Examples of the fused ring include those obtained by fusing one or more aromatic rings with a polycycloalkane having a crosslinked ring-based polycyclic skeleton. Specific examples of the crosslinked ring-based polycycloalkane include a bicycloalkane such as bicyclo[2.2.1]heptane (norbornane) and bicyclo[2.2.2]octane. As the fused cyclic group, a group having a fused ring in which two or three aromatic rings are fused with a bicycloalkane is preferable, and a group having a fused ring in which two or three aromatic rings are fused with bicyclo[2.2.2]octane is more preferable. Specific examples of the fused cyclic group as R^{b101} include fused cyclic groups each represented by Chemical Formulae (r-br-1) and (r-br-2). In the formulae, * represents a bonding site bonded to Yb⁰ in General Formula (b0-1b).

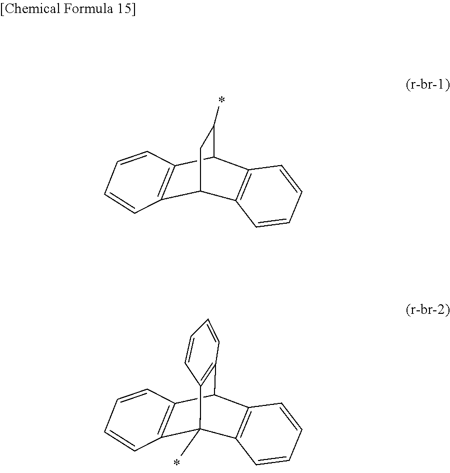

The cyclic group as Rb¹⁰¹ may have a substituent. Examples of the substituent include an alkyl group, an alkoxy group, a halogen atom, a halogenated alkyl group, a hydroxyl group, a carbonyl group, and a nitro group. From the viewpoint of increasing the sensitivity, the substituent is preferably a halogen atom, preferably an iodine atom or a bromine atom, and more preferably an iodine atom.

In a case where the cyclic group has an iodine atom as a substituent, the number of iodine atoms bonded to the cyclic group is preferably in a range of 1 to 3 and more preferably 2 or 3.

Chain-Like Alkyl Group which May have Substituent:

In Formula (b0-1b), the chain-like alkyl group as R^{b101} may be linear or branched.

The linear alkyl group has preferably 1 to 20 carbon atoms, more preferably 1 to 15 carbon atoms, and most preferably 1 to 10 carbon atoms.

The branched chain-like alkyl group has preferably 3 to 20 carbon atoms, more preferably 3 to 15 carbon atoms, and most preferably 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group which May have Substituent:

In Formula (b0-1b), the chain-like alkenyl group as R^{b101} may be linear or branched, and the number of carbon atoms in the chain-like alkenyl group is preferably in a range of 2 to 10, more preferably in a range of 2 to 5, still more preferably in a range of 2 to 4, and particularly preferably 3. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the examples, as the chain-like alkenyl group, a linear alkenyl group is preferable, a vinyl group or a propenyl group is more preferable, and a vinyl group is particularly preferable.

The chain-like alkyl group or chain-like alkenyl group as R^{b101} may have a substituent. Examples of the substituent include an alkoxy group, a halogen atom, a halogenated alkyl group, a hydroxyl group, a carbonyl group, and a nitro group. From the viewpoint of increasing the sensitivity, the substituent is preferably a halogen atom, preferably an iodine atom or a bromine atom, and more preferably an iodine atom.

In a case where the chain-like alkyl group or the chain-like alkenyl group has an iodine atom as a substituent, the number of iodine atoms bonded to the chain-like alkyl group or the chain-like alkenyl group is preferably in a range of 1 to 3 and more preferably 2 or 3.

Among these, Rb¹⁰¹ represents preferably a cyclic group having an iodine atom or a cyclic group having a bromine atom, more preferably a cyclic group having an iodine atom, still more preferably an aromatic hydrocarbon group having an iodine atom, and particularly preferably a phenyl group having an iodine atom, a naphthyl group having an iodine atom, or a group containing these groups.

It is preferable that R^{b101} represents, for example, a group represented by General Formula (b0-r-1p) or a cyclic group to which a group represented by General Formula (b0-r-1p) is bonded.

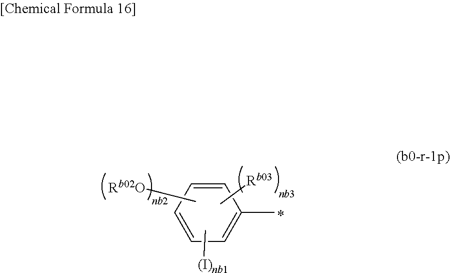

[In the formula, I is an iodine atom. R^{b02} represents a hydrocarbon group having 1 to 6 carbon atoms or a hydrogen atom. R^{b03} represents a hydrocarbon group having 1 to 6 carbon atoms. nb1 represents an integer of 1 to 5. nb2 represents an integer of 0 to 4. nb3 represents an integer of 0 to 4. Here, 1≤nb1+nb2+nb3≤5 is satisfied. * represents a bonding site bonded to Yb⁰ in General Formula (b0-1b) or a bonding site bonded to a cyclic group.]

In General Formula (b0-r-1p), the hydrocarbon group as R^{b02} has 1 to 6 carbon atoms and preferably has 1 to 5 carbon atoms. Among these, a methyl group, an ethyl group, a propyl group, or an isopropyl group is more preferable, a methyl group or an ethyl group is still more preferable, and a methyl group is particularly preferable.

Among these, it is preferable that R^{b02} represents a hydrogen atom, that is, —OR^{b02} represents a phenolic hydroxyl group.

In General Formula (b0-r-1p), the hydrocarbon group as R^{b03} has 1 to 6 carbon atoms and preferably 1 to 5 carbon atoms. Among these, a methyl group, an ethyl group, a propyl group, or an isopropyl group is more preferable, and a methyl group or an ethyl group is still more preferable.
nb1 represents an integer of 1 to 5, preferably an integer of 1 to 3, more preferably 2 or 3, and still more preferably 3.
nb2 represents an integer of 0 to 4, preferably an integer of 0 to 2, more preferably 0 or 1, and still more preferably 0.
nb3 represents an integer of 0 to 4, preferably an integer of 0 to 2, more preferably 0 or 1, and still more preferably 0.

In General Formula (b0-1b), Yb⁰ represents a divalent linking group or a single bond. Suitable examples of the divalent linking group as Yb⁰ include a divalent linking group containing an oxygen atom.

In a case where Yb⁰ represents a divalent linking group containing an oxygen atom, Yb⁰ may contain an atom other than the oxygen atom. Examples of the atom other than the oxygen atom include a carbon atom, a hydrogen atom, a sulfur atom, and a nitrogen atom.

Examples of divalent linking groups containing an oxygen atom include non-hydrocarbon-based oxygen atom-containing linking groups such as an oxygen atom (an ether bond; —O—), an ester bond (—C(═O)—O—), an oxycarbonyl group (—O—C(═O)—), an amide bond (—C(═O)—NH—), a carbonyl group (—C(═O)—), or a carbonate bond (—O—C(═O)—O—); and combinations of the above-described non-hydrocarbon-based oxygen atom-containing linking groups with an alkylene group. Further, a sulfonyl group (—SO₂—) may be further linked to the combination. Among the divalent linking groups containing an oxygen atom, an ester bond (—C(═O)—O—) or an oxycarbonyl group (—O—C(═O)—) is more preferable.

Among these, Yb⁰ represents preferably a divalent linking group, more preferably a divalent linking group containing an oxygen atom, and still more preferably an ester bond (—C(═O)—O—) or an oxycarbonyl group (—O—C(═O)—).

In General Formula (b0-1b), Vb⁰ represents a single bond, an alkylene group, or a fluorinated alkylene group.

The alkylene group and the fluorinated alkylene group as Vb⁰ each preferably have 1 to 4 carbon atoms and more preferably 1 to 3 carbon atoms. Examples of the fluorinated alkylene group as Vb⁰ include a group obtained by substituting part or all of hydrogen atoms in the alkylene group with a fluorine atom. Among these, Vb⁰ represents preferably an alkylene group having 1 to 4 carbon atoms, a fluorinated alkylene group having 1 to 4 carbon atoms, or a single bond, more preferably a group obtained by substituting part of hydrogen atoms of an alkylene group having 1 to 3 carbon atoms with a fluorine atom, or a single bond, and still more preferably —CH(CF₃)— or —CH₂—.

In General Formula (b0-1b), R⁰ represents a hydrogen atom, a fluorinated alkyl group having 1 to 5 carbon atoms, or a fluorine atom. R⁰ represents preferably a fluorine atom or a perfluoroalkyl group having 1 to 5 carbon atoms and more preferably a fluorine atom.

Specific examples of the anion moiety of a sulfonate represented by General Formula (b0-1b), are shown below.

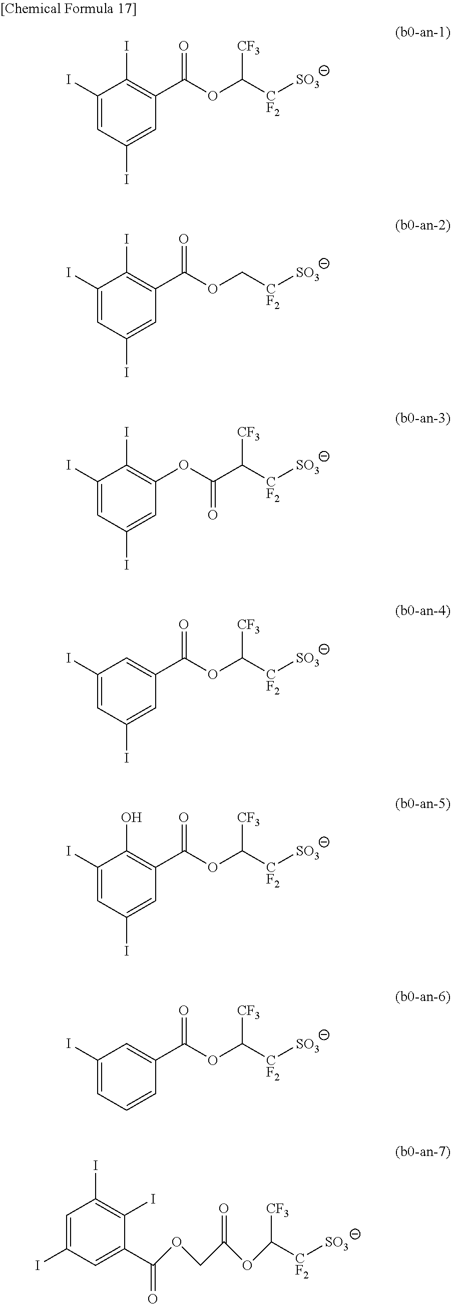

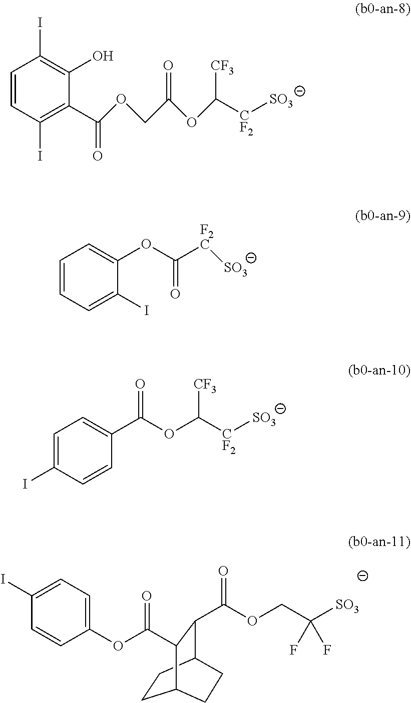

As the anion moiety of a sulfonate represented by General Formula (b0-1b), at least one selected from the group consisting of anions each represented by Chemical Formulae (b0-an-1) to (a0-an-11) is preferable, and at least one selected from the group consisting of anions each represented by Chemical Formulae (a0-an-1) to (a0-an-6) and Chemical Formulae (a0-an-9) to (a0-an-11) is more preferable.

### In Regard to Anion Moiety

In Formula (b0-1b), Mⁿ⁺ represents an m-valent onium cation and preferably a sulfonium cation or an iodonium cation. m represents an integer of 1 or greater.

Examples of the onium cation as Mⁿ⁺ include organic cations each represented by General Formulae (ca-1) to (ca-3).

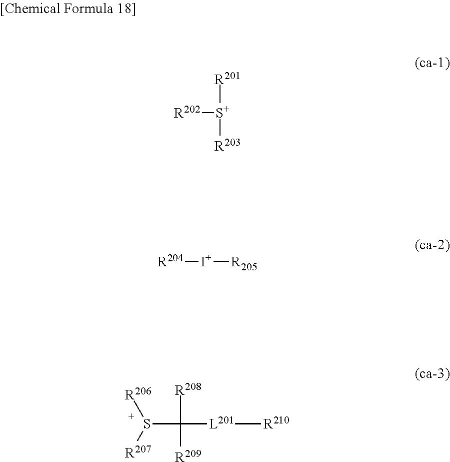

[In the formulae, R²⁰¹ to R²⁰⁷ each independently represent an aryl group, an alkyl group, or an alkenyl group, each of which may have a substituent. R²⁰¹ to R²⁰³, and R²⁰⁶ and R²⁰⁷ may be bonded to each other to form a ring together with the sulfur atoms in the formulae. R²⁰⁸ and R²⁰⁹ each independently represent a hydrogen atom or an alkyl group having 1 to 5 carbon atoms. R²¹⁰ represents an aryl group which may have a substituent, an alkyl group which may have a substituent, an alkenyl group which may have a substituent, or a —SO₂-containing cyclic group which may have a substituent. L²⁰¹ represents —C(═O)— or —C(═O)—O—.]

In General Formulae (ca-1) to (ca-3), examples of the aryl group as R²⁰¹ to R²⁰⁷ include an unsubstituted aryl group having 6 to 20 carbon atoms, and a phenyl group or a naphthyl group is preferable.

The alkyl group as R²⁰¹ to R²⁰⁷ is preferably a chain-like or cyclic alkyl group which has 1 to 30 carbon atoms.

The alkenyl group as R²⁰¹ to R²⁰⁷ preferably has 2 to 10 carbon atoms.

Examples of the substituent which may be contained in R²⁰¹ to R²⁰⁷ and R²¹⁰ include an alkyl group, a halogen atom, a halogenated alkyl group, a carbonyl group, a cyano group, an amino group, an aryl group, and groups each represented by General Formulae (ca-r-1) to (ca-r-7).

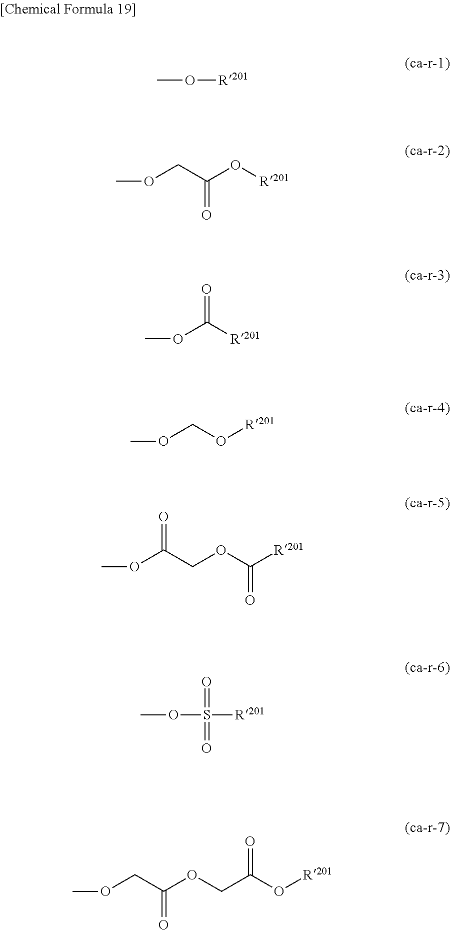

[In the formulae, R′²⁰¹'s each independently represents a hydrogen atom, a cyclic group which may have a substituent, a chain-like alkyl group which may have a substituent, or a chain-like alkenyl group which may have a substituent.]

Cyclic Group which May have Substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. Further, the aliphatic hydrocarbon group may be saturated or unsaturated. In general, it is preferable that the aliphatic hydrocarbon group is saturated.

The aromatic hydrocarbon group as R′²⁰¹ is a hydrocarbon group having an aromatic ring. The aromatic hydrocarbon group has preferably 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. Here, the number of carbon atoms in a substituent is not included in the number of carbon atoms.

Specific examples of the aromatic ring contained in the aromatic hydrocarbon group as R′²⁰¹ include benzene, fluorene, naphthalene, anthracene, phenanthrene, biphenyl, or an aromatic heterocyclic ring in which some carbon atoms constituting any of these aromatic rings have been substituted with hetero atoms. Examples of the hetero atom in the aromatic heterocyclic rings include an oxygen atom, a sulfur atom, and a nitrogen atom.

Specific examples of the aromatic hydrocarbon group as R′²⁰¹ include a group in which one hydrogen atom has been removed from the aromatic ring (an aryl group such as a phenyl group or a naphthyl group), and a group in which one hydrogen atom in the aromatic ring has been substituted with an alkylene group (for example, an arylalkyl group such as a benzyl group, a phenethyl group, a 1-naphthylmethyl group, a 2-naphthylmethyl group, 1-naphthylethyl group, or a 2-naphthylethyl group). The alkylene group (alkyl chain in the arylalkyl group) has preferably 1 to 4 carbon atoms, more preferably 1 or 2 carbon atoms, and particularly preferably 1 carbon atom.

Examples of the cyclic aliphatic hydrocarbon group as R′²⁰¹ include an aliphatic hydrocarbon group having a ring in the structure thereof.

Examples of the aliphatic hydrocarbon group having a ring in the structure thereof include an alicyclic hydrocarbon group (group in which one hydrogen atom has been removed from an aliphatic hydrocarbon ring), a group in which the alicyclic hydrocarbon group is bonded to the terminal of a linear or branched aliphatic hydrocarbon group, and a group in which the alicyclic hydrocarbon group is interposed in the middle of a linear or branched aliphatic hydrocarbon group.

The alicyclic hydrocarbon group has preferably 3 to 20 carbon atoms and more preferably 3 to 12 carbon atoms.

The alicyclic hydrocarbon group may be a polycyclic group or a monocyclic group. As the monocyclic alicyclic hydrocarbon group, a group in which one or more hydrogen atoms have been removed from a monocycloalkane is preferable. The monocycloalkane has preferably 3 to 6 carbon atoms, and specific examples thereof include cyclopentane and cyclohexane. As the polycyclic alicyclic hydrocarbon group, a group in which one or more hydrogen atoms have been removed from a polycycloalkane is preferable, and the number of carbon atoms of the polycycloalkane is preferably in a range of 7 to 30. Among these, a polycycloalkane having a crosslinked ring polycyclic skeleton such as adamantane, norbornane, isobornane, tricyclodecane, or tetracyclododecane; and a polycycloalkane having a fused ring polycyclic skeleton such as a cyclic group having a steroid skeleton are preferable as the polycycloalkane.

Among these examples, as the cyclic aliphatic hydrocarbon group as R′²⁰¹, a group in which one or more hydrogen atoms have been removed from a monocycloalkane or a polycycloalkane is preferable, a group in which one hydrogen atom has been removed from a polycycloalkane is more preferable, an adamantyl group or a norbornyl group is particularly preferable, and an adamantyl group is most preferable.

The linear or branched aliphatic hydrocarbon group which may be bonded to the alicyclic hydrocarbon group has preferably 1 to 10 carbon atoms, more preferably 1 to 6 carbon atoms, still more preferably 1 to 4 carbon atoms, and particularly preferably 1 to 3 carbon atoms.

As the linear aliphatic hydrocarbon group, a linear alkylene group is preferable. Specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

As the branched chain-like aliphatic hydrocarbon group, a branched chain-like alkylene group is preferable, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As the alkyl group in the alkylalkylene group, a linear alkyl group having 1 to 5 carbon atoms is preferable.

Further, the cyclic hydrocarbon group as R′²⁰¹ may have a hetero atom such as a heterocyclic ring.

Examples of the substituent for the cyclic group as R′²⁰¹ include an alkyl group, an alkoxy group, a halogen atom, a halogenated alkyl group, a hydroxyl group, a carbonyl group, and a nitro group.

As the alkyl group as the substituent, an alkyl group having 1 to 5 carbon atoms is preferable, and a methyl group, an ethyl group, a propyl group, an n-butyl group, or a tert-butyl group is most preferable.

As the alkoxy group as the substituent, an alkoxy group having 1 to 5 carbon atoms is preferable, a methoxy group, an ethoxy group, an n-propoxy group, an iso-propoxy group, an n-butoxy group, or a tert-butoxy group is more preferable, and a methoxy group or an ethoxy group is most preferable.

As the halogen atom as a substituent, a fluorine atom is preferable.

Example of the above-described halogenated alkyl group as the substituent includes a group in which some or all hydrogen atoms in an alkyl group having 1 to 5 carbon atoms such as a methyl group, an ethyl group, a propyl group, an n-butyl group, or a tert-butyl group have been substituted with the above-described halogen atoms.

The carbonyl group as the substituent is a group that substitutes a methylene group (—CH₂—) constituting the cyclic hydrocarbon group.

Chain-Like Alkyl Group which May have Substituent:

The chain-like alkyl group as R′²⁰¹ may be linear or branched.

The linear alkyl group has preferably 1 to 20 carbon atoms, more preferably 1 to 15 carbon atoms, and most preferably 1 to 10 carbon atoms.

The branched alkyl group has preferably 3 to 20 carbon atoms, more preferably 3 to 15 carbon atoms, and most preferably 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group which May have Substituent:

The chain-like alkenyl group as R′²⁰¹ may be linear or branched, and the number of carbon atoms thereof is preferably in a range of 2 to 10, more preferably in a range of 2 to 5, still more preferably in a range of 2 to 4, and particularly preferably 3. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the examples, as the chain-like alkenyl group, a linear alkenyl group is preferable, a vinyl group or a propenyl group is more preferable, and a vinyl group is particularly preferable.

Examples of the substituent for the chain-like alkyl group or alkenyl group as R′²⁰¹ include an alkoxy group, a halogen atom, a halogenated alkyl group, a hydroxyl group, a carbonyl group, a nitro group, an amino group, and a cyclic group as R′²⁰¹.

Examples of the cyclic group which may have a substituent, the chain-like alkyl group which may have a substituent, or the chain-like alkenyl group which may have a substituent, as R′²⁰¹ include those described above and an acid dissociable group as the cyclic group which may have a substituent or the chain-like alkyl group which may have a substituent.

Among the examples, R′²⁰¹ represents preferably a cyclic group which may have a substituent and more preferably a cyclic hydrocarbon group which may have a substituent. More specifically, for example, a group in which one or more hydrogen atoms have been removed from a phenyl group, a naphthyl group, or a polycycloalkane is preferable.

In General Formulae (ca-1) to (ca-3), in a case where R²⁰¹ to R²⁰³ and R²⁰⁶ and R²⁰⁷ are bonded to each other to form a ring with a sulfur atom in the formula, these groups may be bonded to each other via a hetero atom such as a sulfur atom, an oxygen atom, or a nitrogen atom, or a functional group such as a carbonyl group, —SO—, —SO₂—, —SO₃—, —COO—, —CONH—, or —N(R_{N})— (here, R_{N} represents an alkyl group having 1 to 5 carbon atoms). As a ring to be formed, a ring containing the sulfur atom in the formula in the ring skeleton thereof is preferably a 3- to 10-membered ring and particularly preferably a 5- to 7-membered ring containing the sulfur atom. Specific examples of the ring to be formed include a thiophene ring, a thiazole ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

R²⁰⁸ and R²⁰⁹ each independently represent a hydrogen atom or an alkyl group having 1 to 5 carbon atoms and preferably a hydrogen atom or an alkyl group having 1 to 3 carbon atoms. In a case where R²⁰⁸ and R²⁰⁹ each represent an alkyl group, R²⁰⁸ and R²⁰⁹ may be bonded to each other to form a ring.

R²¹⁰ represents an aryl group which may have a substituent, an alkyl group which may have a substituent, an alkenyl group which may have a substituent, or a —SO₂— containing cyclic group which may have a substituent.

Examples of the aryl group as R²¹⁰ include an unsubstituted aryl group having 6 to 20 carbon atoms, and a phenyl group or a naphthyl group is preferable.

As the alkyl group as R²¹⁰, a chain-like or cyclic alkyl group having 1 to 30 carbon atoms is preferable.

It is preferable that the alkenyl group as R²¹⁰ has 2 to 10 carbon atoms.

The —SO₂-containing cyclic group which may have a substituent, as R²¹⁰, is preferably “—SO₂-containing polycyclic group”.

Specific examples of the suitable cation represented by General Formula (ca-1) include cations each represented by the following chemical formulae.

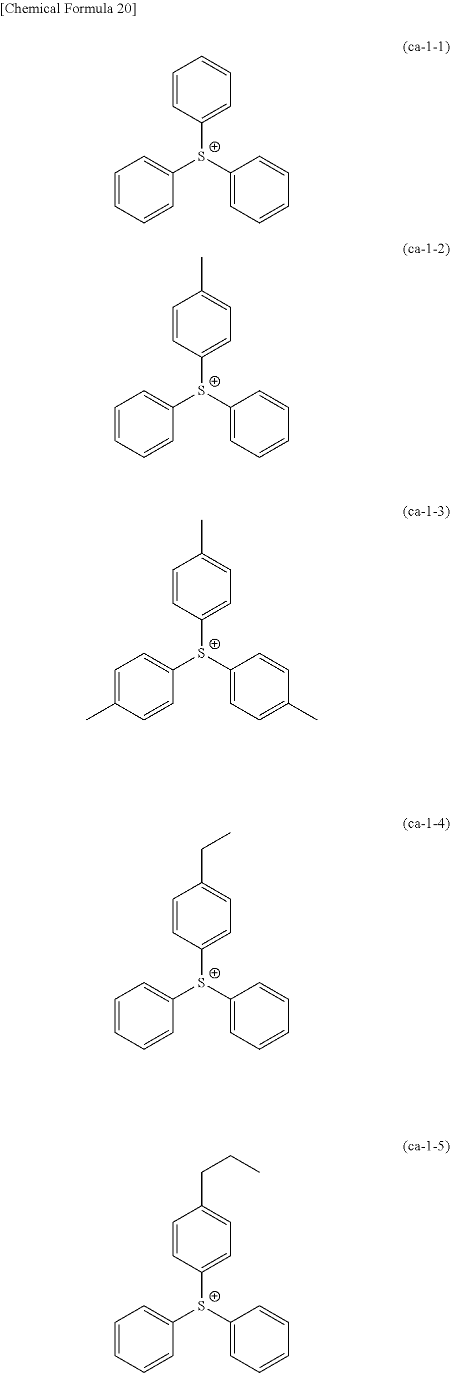

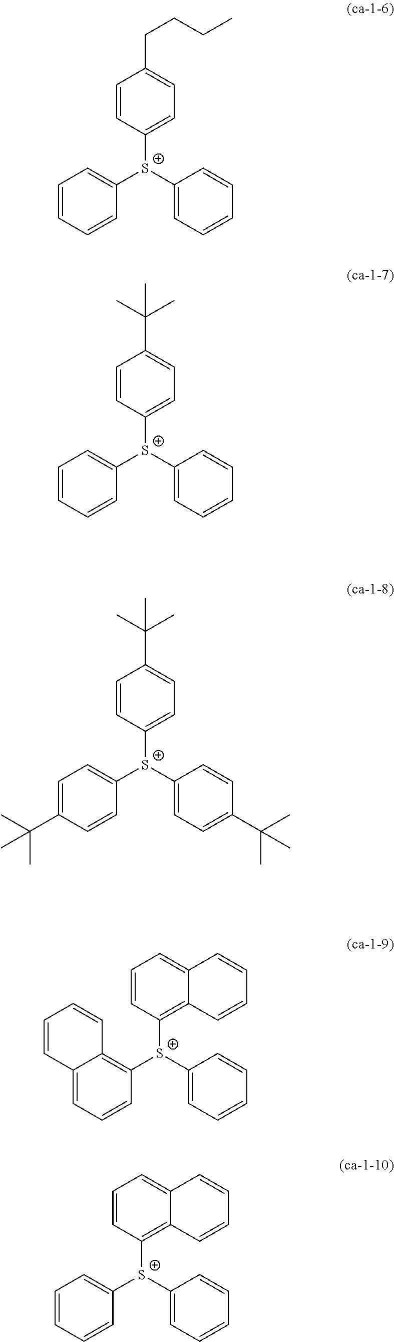

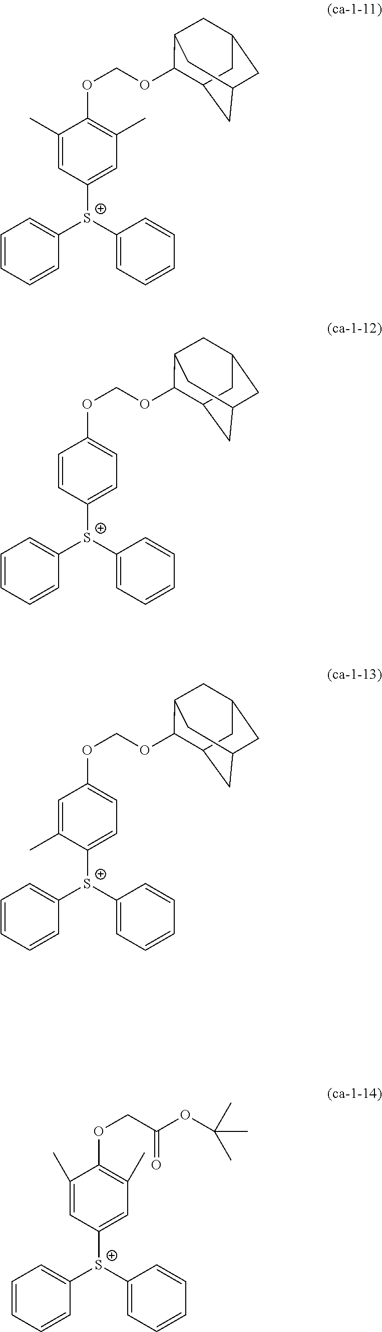

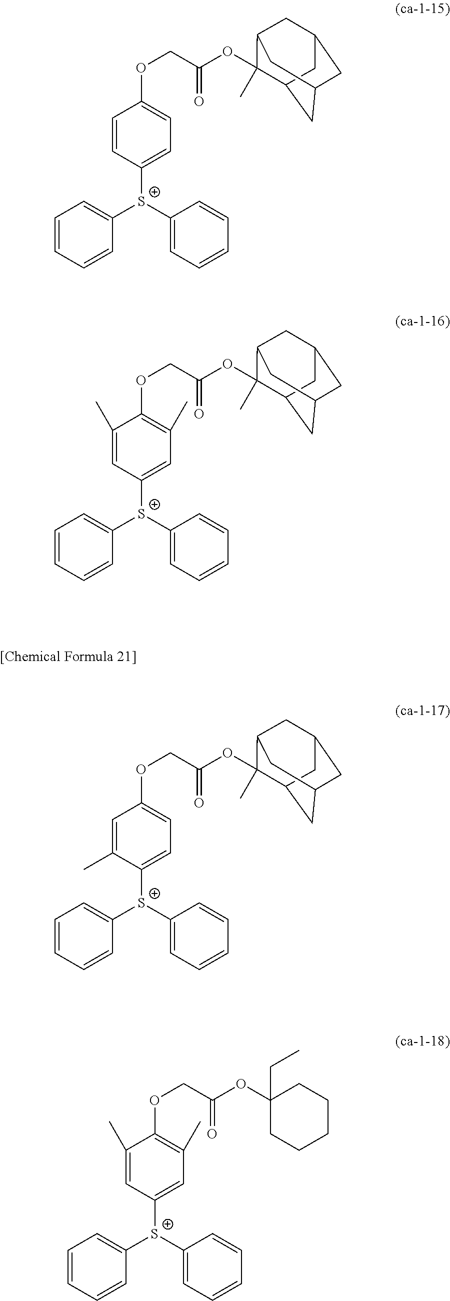

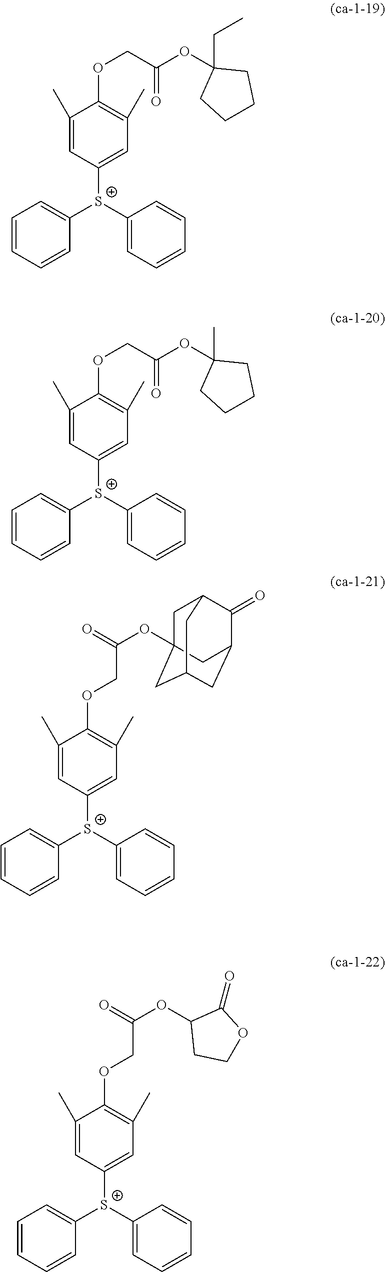

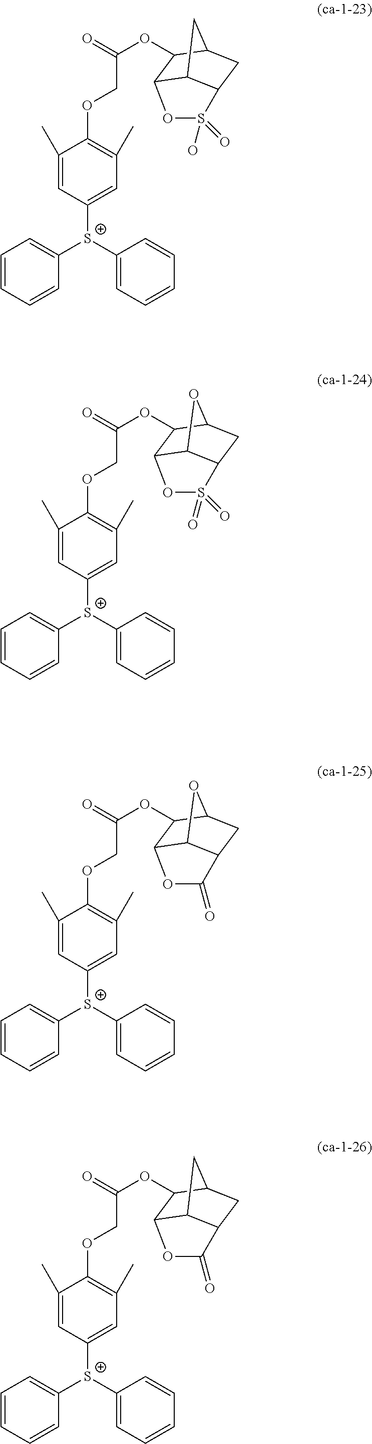

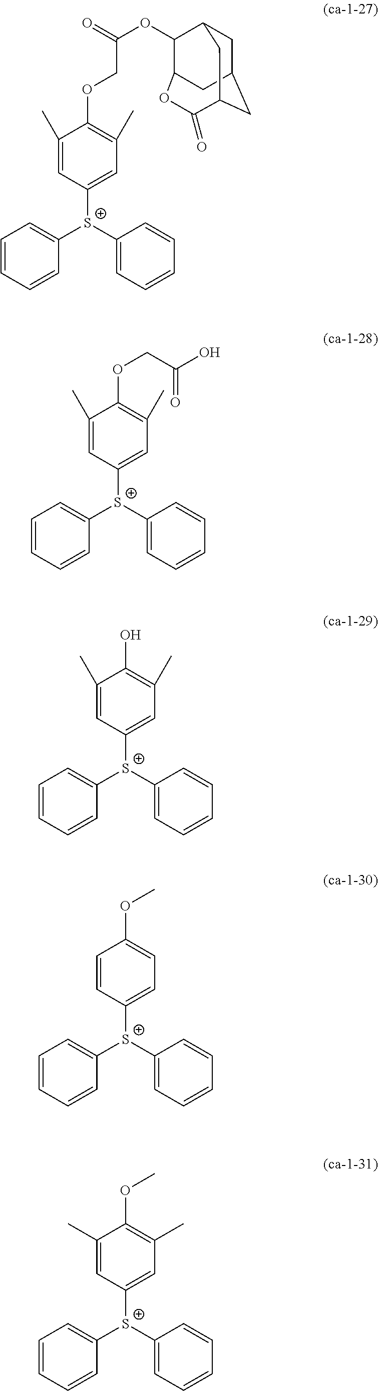

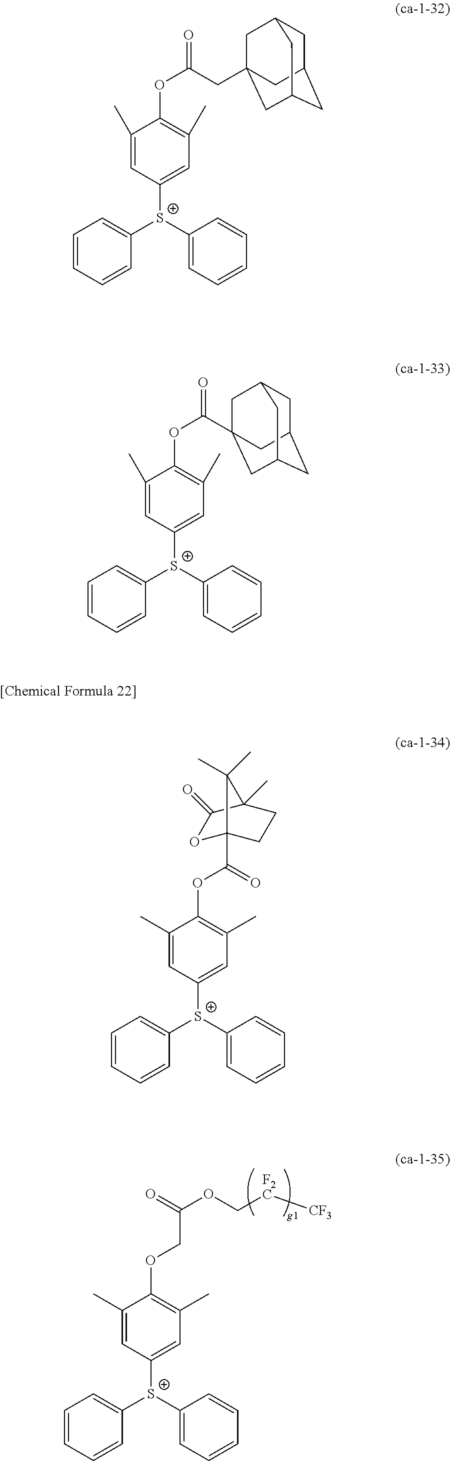

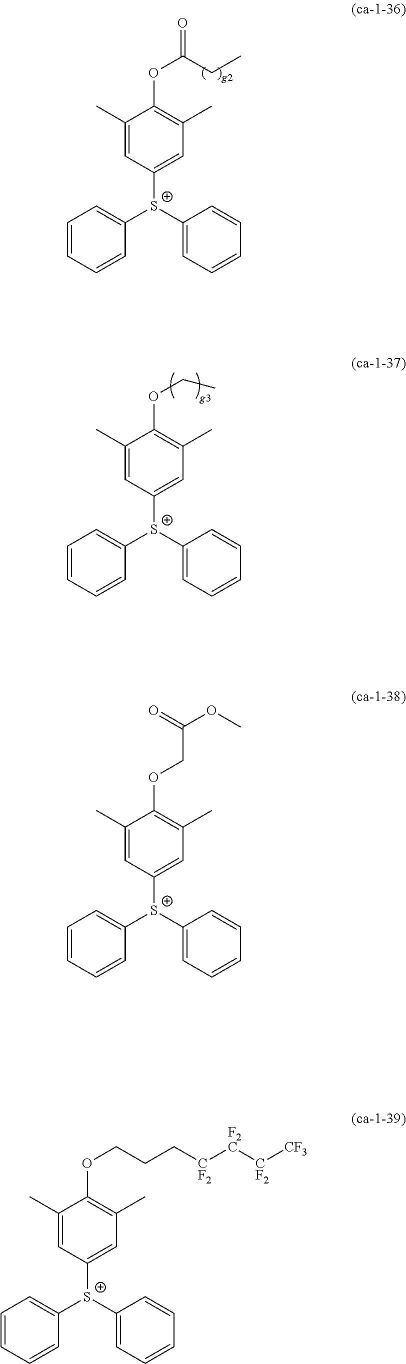

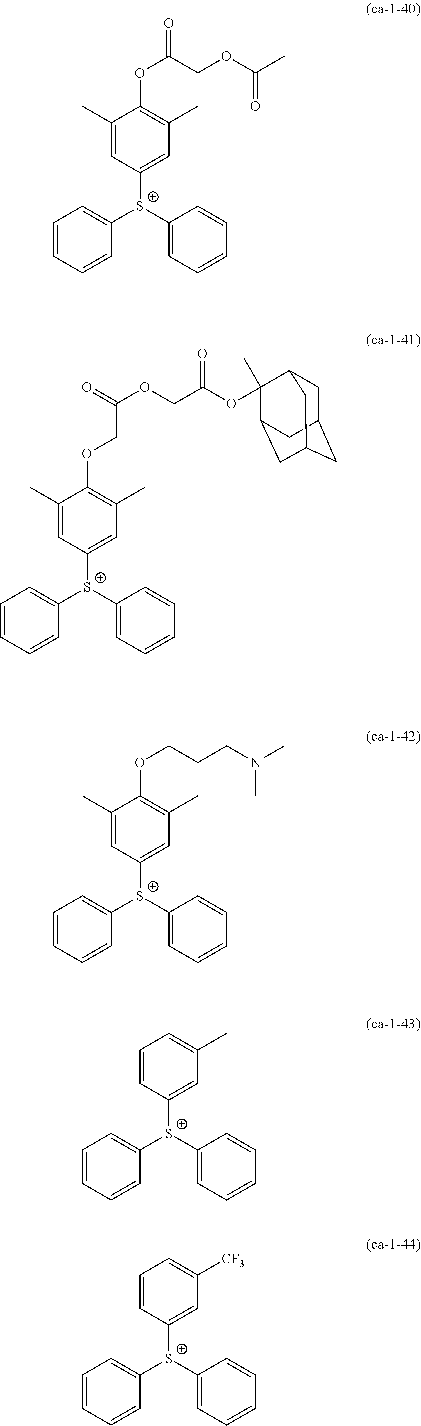

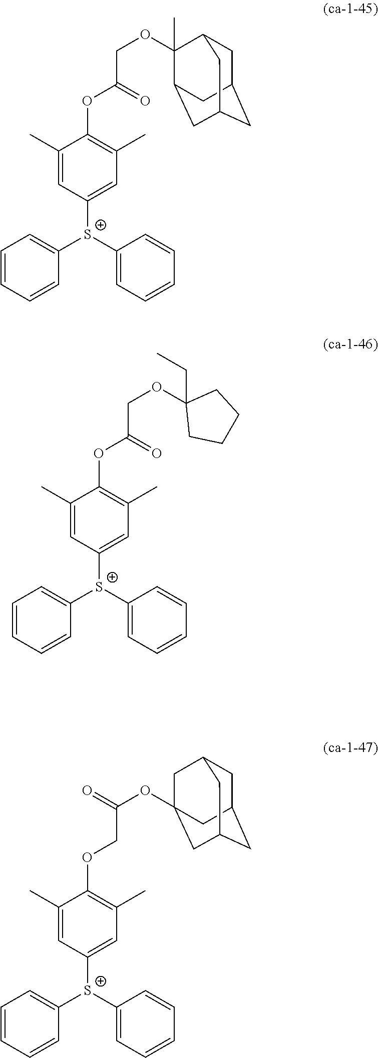

[In the formulae, g1, g2, and g3 represent a repeating number, g1 represents an integer of 1 to 5, g2 represents an integer of 0 to 20, and g3 represents an integer of 0 to 20.]

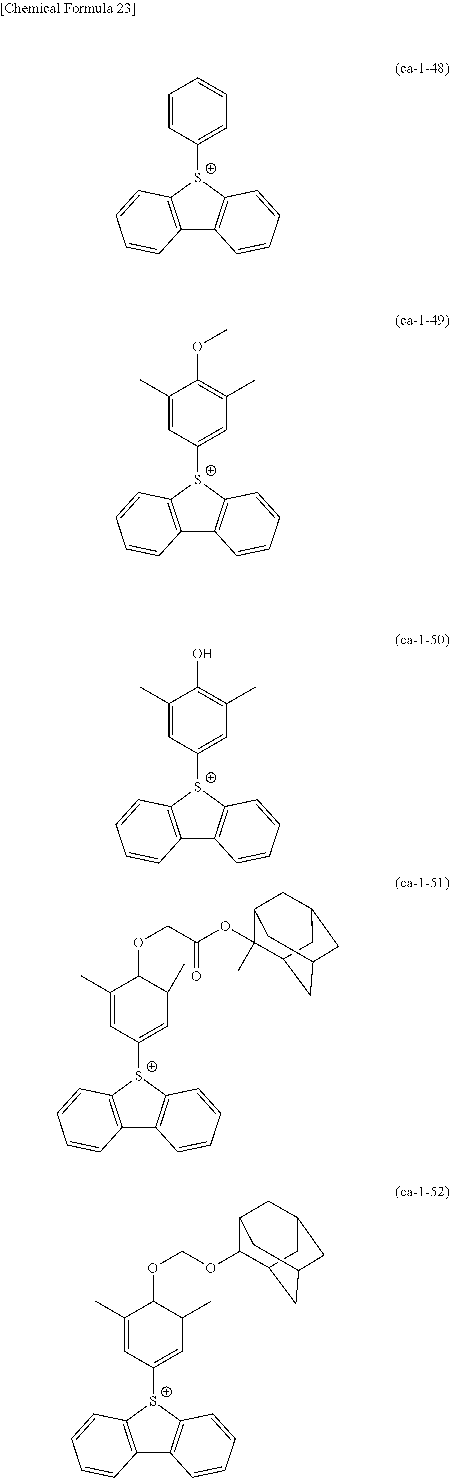 [SMILES: c1ccc(-[s+]2c3ccccc3c3ccccc32)cc1 ; COc1c(C)cc(-[s+]2c3ccccc3c3ccccc32)cc1C ; Cc1cc(-[s+]2c3ccccc3c3ccccc32)cc(C)c1O ; CC1=CC([s+]2c3ccccc3c3ccccc32)=CC(C)C1OCC(=O)OC1(C)C2CC3CC(C2)CC1C3 ; CC1=CC([s+]2c3ccccc3c3ccccc32)=CC(C)C1OCOC1C2CC3CC(C2)CC1C3]

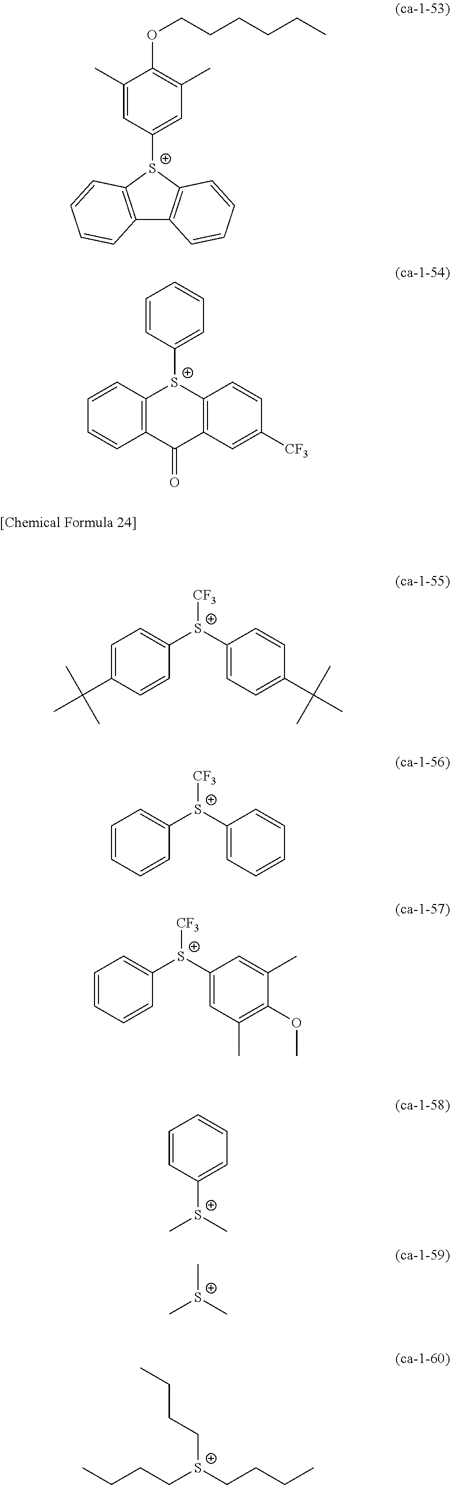

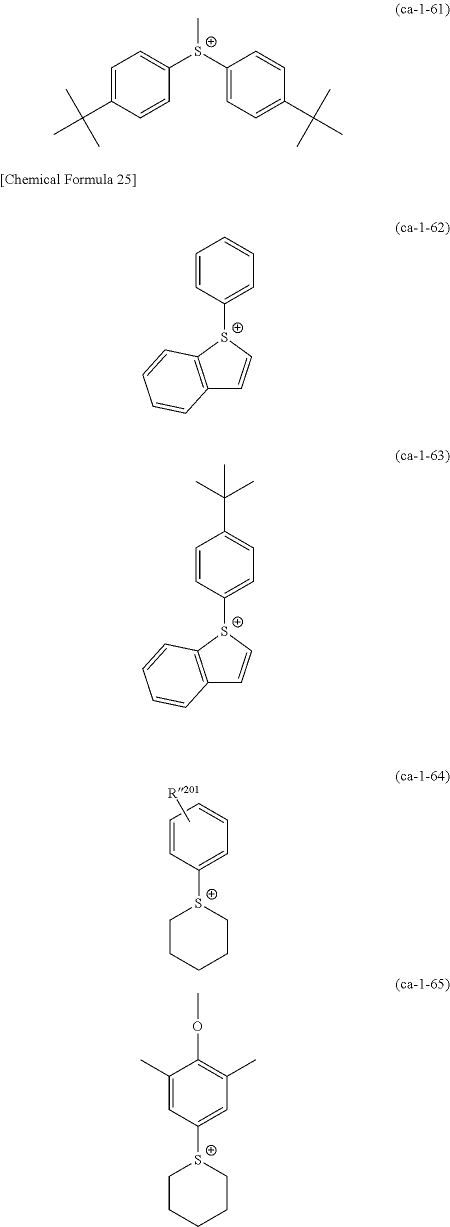

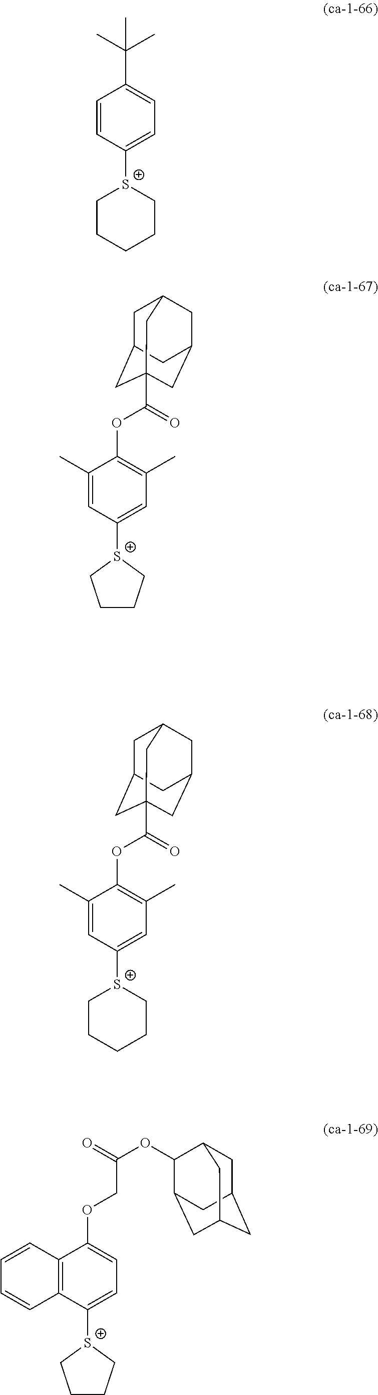 [SMILES: CC(C)(C)c1ccc([S+]2CCCCC2)cc1 ; Cc1cc([S+]2CCCC2)cc(C)c1OC(=O)C12CC3CC(CC(C3)C1)C2 ; Cc1cc([S+]2CCCCC2)cc(C)c1OC(=O)C12CC3CC(CC(C3)C1)C2 ; O=C(COc1ccc([S+]2CCCC2)c2ccccc12)OC1C2CC3CC(C2)CC1C3]

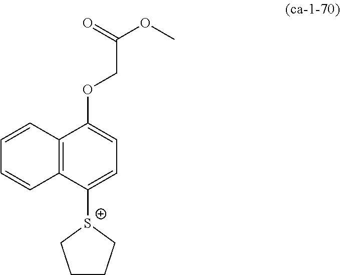 [SMILES: COC(=O)COc1ccc([S+]2CCCC2)c2ccccc12]

[In the formulae, R″²⁰¹ represents a hydrogen atom or a substituent, and examples of the substituent include the same groups as those for the substituents which may be included in R²⁰¹ to R²⁰⁷ and R²¹⁰ to R²¹².]

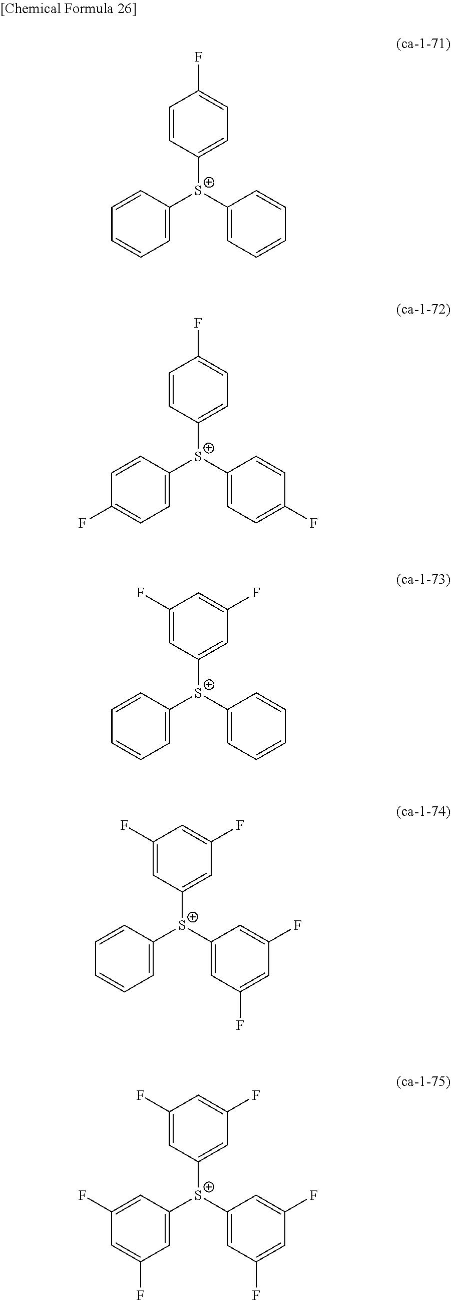 [SMILES: Fc1ccc([S+](c2ccccc2)c2ccccc2)cc1 ; Fc1ccc([S+](c2ccc(F)cc2)c2ccc(F)cc2)cc1 ; Fc1cc(F)cc([S+](c2ccccc2)c2ccccc2)c1 ; Fc1cc(F)cc([S+](c2ccccc2)c2cc(F)cc(F)c2)c1 ; Fc1cc(F)cc([S+](c2cc(F)cc(F)c2)c2cc(F)cc(F)c2)c1]

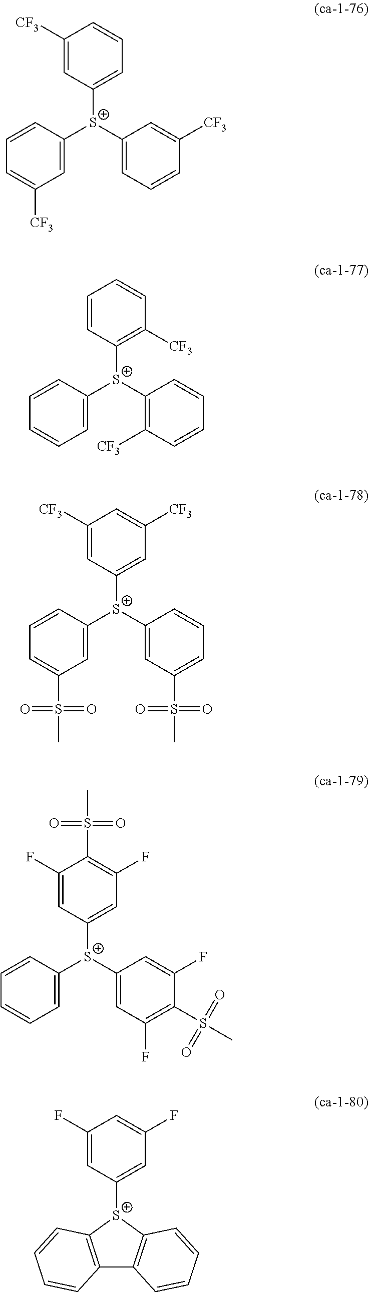 [SMILES: FC(F)(F)c1cccc([S+](c2cccc(C(F)(F)F)c2)c2cccc(C(F)(F)F)c2)c1 ; FC(F)(F)c1ccccc1[S+](c1ccccc1)c1ccccc1C(F)(F)F ; CS(=O)(=O)c1cccc([S+](c2cc(C(F)(F)F)cc(C(F)(F)F)c2)c2cccc(S(C)(=O)=O)c2)c1 ; CS(=O)(=O)c1c(F)cc([S+](c2ccccc2)c2cc(F)c(S(C)(=O)=O)c(F)c2)cc1F ; Fc1cc(F)cc(-[s+]2c3ccccc3c3ccccc32)c1]

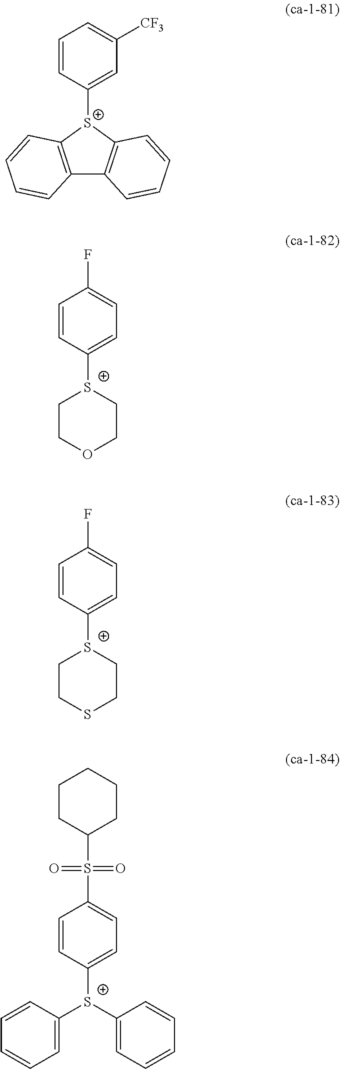 [SMILES: FC(F)(F)c1cccc(-[s+]2c3ccccc3c3ccccc32)c1 ; Fc1ccc([S+]2CCOCC2)cc1 ; Fc1ccc([S+]2CCSCC2)cc1 ; O=S(=O)(c1ccc([S+](c2ccccc2)c2ccccc2)cc1)C1CCCCC1]

Specific examples of suitable cations represented by Formula (ca-2) include a diphenyliodonium cation and a bis(4-tert-butylphenyl)iodonium cation.

Specific examples of suitable cations represented by Formula (ca-3) include cations each represented by Formulae (ca-3-1) to (ca-3-6).

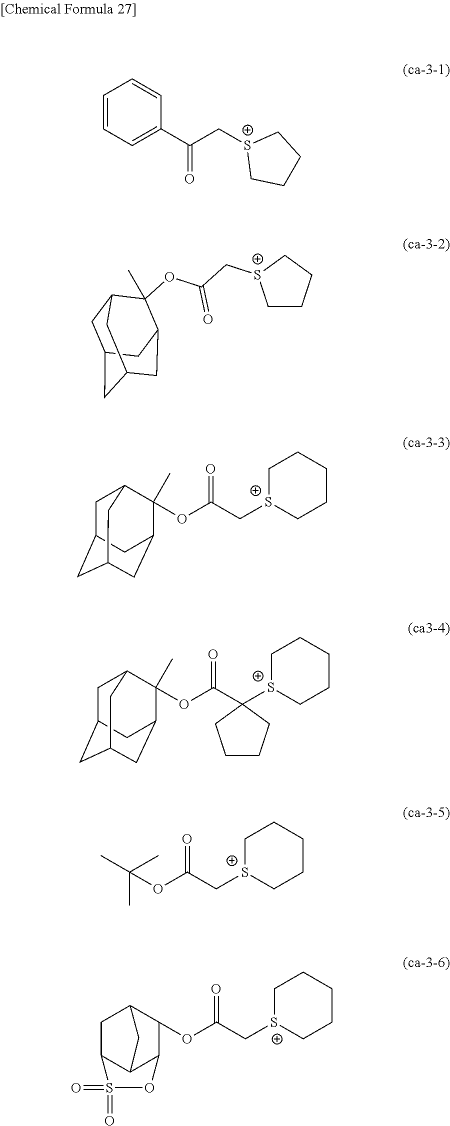 [SMILES: O=C(C[S+]1CCCC1)c1ccccc1 ; CC1(OC(=O)C[S+]2CCCC2)C2CC3CC(C2)CC1C3 ; CC1(OC(=O)C[S+]2CCCCC2)C2CC3CC(C2)CC1C3 ; CC1(OC(=O)C2([S+]3CCCCC3)CCCC2)C2CC3CC(C2)CC1C3 ; CC(C)(C)OC(=O)C[S+]1CCCCC1 ; O=C(C[S+]1CCCCC1)OC1C2CC3C1OS(=O)(=O)C3C2]

As the onium cation as Mⁿ⁺, at least one selected from the group consisting of cations each represented by General Formulae (ca-1) to (ca-3) is preferable, a cation represented by General Formula (ca-1) is more preferable, and a cation represented by General Formula (b0-ca) is still more preferable.

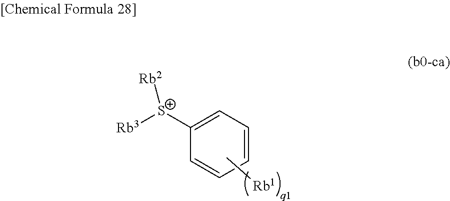

[In the formula, Rb¹ represents a fluorinated alkyl group or a fluorine atom. q1 represents an integer of 1 to 5. Rb² and Rb³ each independently represent an aryl group, an alkyl group, or an alkenyl group, each of which may have a substituent. Rb² and Rb³ may be bonded to each other to form a ring together with a sulfur atom in the formula. Rb² or Rb³ may form a fused ring together with a sulfur atom and a benzene ring in the formula.]

In General Formula (b0-ca), the fluorinated alkyl group as Rb¹ is preferably a linear or branched fluorinated alkyl group having 1 to 5 carbon atoms, more preferably a linear fluorinated alkyl group having 1 to 5 carbon atoms, and particularly preferably a trifluoromethyl group.

In General Formula (b0-ca), q1 represents an integer of 1 to 5, preferably an integer of 1 to 4, and more preferably 2 or 3.

In General Formula (b0-ca), it is preferable that Rb¹ is bonded to the ortho-position or meta-position of the benzene ring from the viewpoint of photolysis efficiency.

In General Formula (b0-ca), Rb² and Rb³ each have the same definition as that for R²⁰¹ to R²⁰³ in General Formula (ca-1).

In particular, from the viewpoint of increasing the sensitivity, it is preferable that the suitable cation represented by General Formula (ca-1) has, as a substituent, an electron-withdrawing group such as a fluorine atom, a fluorinated alkyl group, or a sulfonyl group, and for example, a cation selected from the group consisting of cations each represented by Chemical Formulae (ca-1-44), (ca-1-71) to (ca-1-77), (ca-1-80), and (ca-1-81) is s particularly preferable.

Specific preferred examples of the onium salt (component (B0)) represented by General Formula (b0) are shown below.

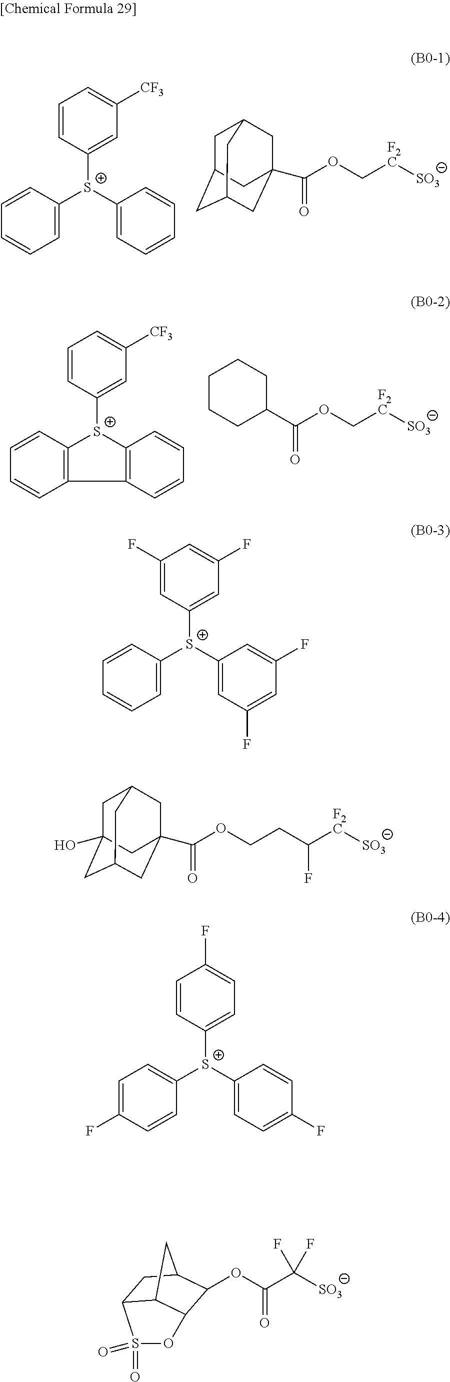

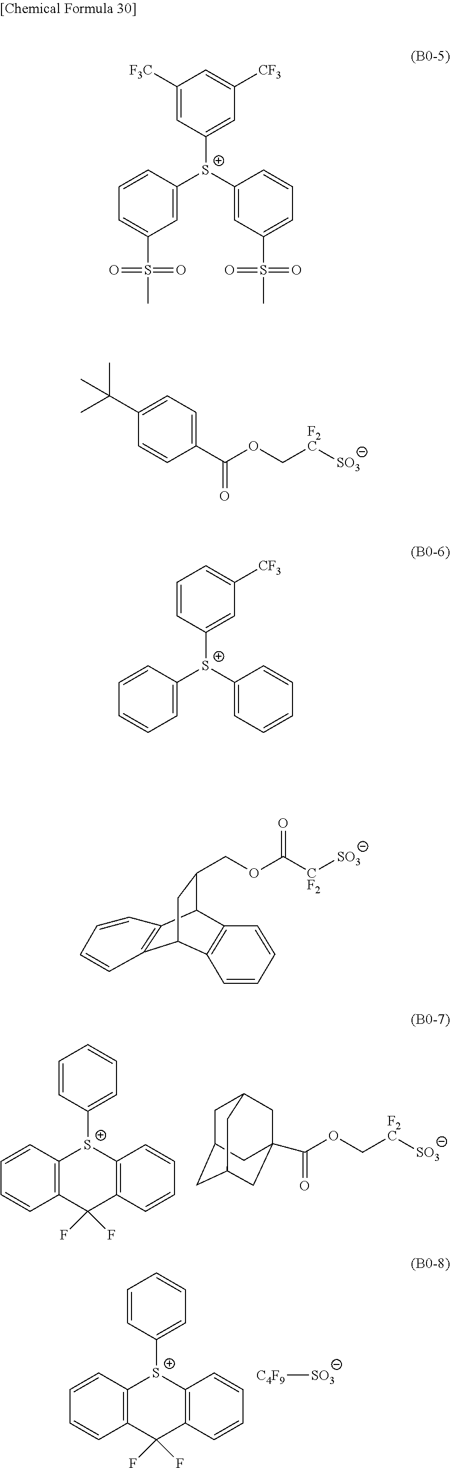

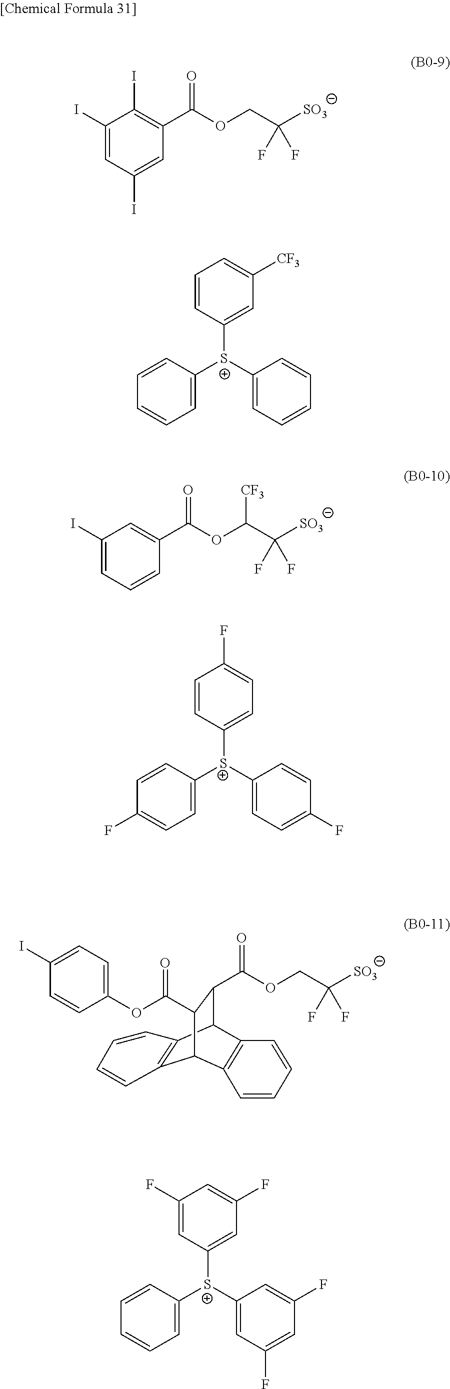

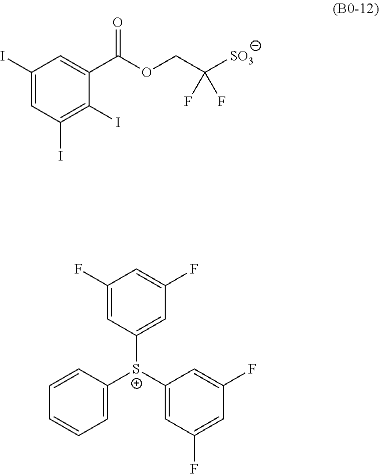

Among these, the component (B0) is preferably selected from the group consisting of compounds each represented by Chemical Formulae (B0-1) to (B0-12) and particularly preferably compounds each represented by Chemical Formulae (B0-11) and (B0-12).

In the film-forming composition according to the present embodiment, the component (B0) may be used alone or in combination of two or more kinds thereof.

The content of the component (B0) is preferably in a range of 10 to 50 parts by mass, more preferably in a range of 20 to 45 parts by mass, and still more preferably in a range of 25 to 40 parts by mass with respect to 100 parts by mass of the component (A1).

In a case where the content of the component (B0) is greater than or equal to the lower limits of the above-described preferable ranges, lithography characteristics such as the sensitivity, the resolution performance, reduction of the line width roughness (LWR) in resist pattern formation are further improved. Meanwhile, in a case where the content thereof is less than or equal to the upper limits of the above-described preferable ranges, a uniform solution is likely to be obtained and the storage stability of the composition is further improved in a case of dissolving each component of the film-forming composition in an organic solvent.

### <Crosslinking Agent Component>

The film-forming composition of the present embodiment contains a crosslinking agent component (component (C)) in addition to the silicon-containing compound (A) and the acid generating agent component.

That is, the film-forming composition according to the present embodiment is “negative-tone resist composition for an alkali developing process” that forms a negative-tone resist pattern in an alkali developing process or “positive-tone resist composition for a solvent developing process” that forms a positive-tone resist pattern in a solvent developing process.

Examples of the component (C) include a melamine-based crosslinking agent, a urea-based crosslinking agent, an alkylene urea-based crosslinking agent, a glycoluril-based crosslinking agent, a phenol-based crosslinking agent, and an epoxy-based crosslinking agent.

Further, the term “lower” used below denotes that the number of carbon atoms is in a range of 1 to 5.

Examples of the melamine-based crosslinking agent include a compound obtained by reacting melamine with formaldehyde to substitute a hydrogen atom of an amino group with a hydroxymethyl group; and a compound obtained by reacting melamine, formaldehyde, and a lower alcohol to substitute a hydrogen atom of an amino group with a lower alkoxymethyl group. Specific examples thereof include hexamethoxymethyl melamine, hexaethoxymethyl melamine, hexapropoxymethyl melamine, and hexabutoxybutyl melamine. Among these, hexamethoxymethyl melamine is preferable.

Examples of the urea-based crosslinking agent include a compound obtained by reacting urea with formaldehyde to substitute a hydrogen atom of an amino group with a hydroxymethyl group; and a compound obtained by reacting urea, formaldehyde, and a lower alcohol to substitute a hydrogen atom of an amino group with a lower alkoxymethyl group. Specific examples thereof include bismethoxymethyl urea, bisethoxymethyl urea, bispropoxymethyl urea, and bisbutoxymethyl urea. Among these, bismethoxymethyl urea is preferable.

Examples of the alkylene urea-based crosslinking agent include a compound represented by General Formula (CA-1).

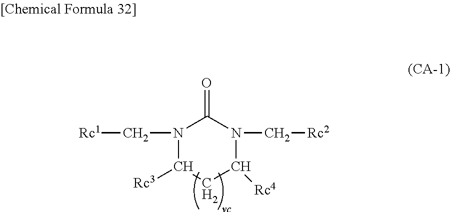

[In General Formula (CA-1), Rc¹ and Rc² each independently represent a hydroxyl group or a lower alkoxy group. Rc³ and Rc⁴ each independently represent a hydrogen atom, a hydroxyl group, or a lower alkoxy group. vc represents an integer of 0 to 2.]

In a case where Rc¹ and Rc² represent a lower alkoxy group, an alkoxy group having 1 to 4 carbon atoms is preferable, and the alkoxy group may be linear or branched. Rc¹ and Rc² may be the same as or different from each other, where they are more preferably the same.

In a case where Rc³ and Rc⁴ represent a lower alkoxy group, an alkoxy group having 1 to 4 carbon atoms is preferable, and the alkoxy group may be linear or branched. Rc³ and Rc⁴ may be the same as or different from each other, where they are more preferably the same.

vc represents an integer of 0 to 2 and preferably 0 or 1.

In particular, the alkylene urea-based crosslinking agent is preferably a compound in which vc represents 0 (an ethylene urea-based crosslinking agent) and/or a compound in which vc represents 1 (a propylene urea-based crosslinking agent).

The compound represented by General Formula (CA-1) can be obtained by performing a condensation reaction of alkylene urea with formalin or by reacting this product with lower alcohol.

Specific examples of the alkylene urea-based crosslinking agent include ethylene urea-based crosslinking agents such as mono- and/or dihydroxymethylated ethylene urea, mono- and/or dimethoxymethylated ethylene urea, mono- and/or diethoxymethylated ethylene urea, mono- and/or dipropoxymethylated ethylene urea, and mono- and/or dibutoxymethylated ethylene urea; propylene urea-based crosslinking agents such as mono- and/or dihydroxymethylated propylene urea, mono- and/or dimethoxymethylated propylene urea, mono- and/or diethoxymethylated propylene urea, mono- and/or dipropoxymethylated propylene urea, and mono- and/or dibutoxymethylated propylene urea; 1,3-di(methoxymethyl) 4,5-dihydroxy-2-imidazolidinone; and 1,3-di(methoxymethyl)-4,5-dimethoxy-2-imidazolidinone.

Examples of the glycoluril-based crosslinking agent include a glycoluril derivative having a substitution with one or both of a hydroxyalkyl group and an alkoxyalkyl group having 1 to 4 carbon atoms at the N-position. Such a glycoluril derivative can be obtained by performing a condensation reaction of glycoluril with formalin or by reacting this product with lower alcohol.

Specific examples of the glycoluril-based crosslinking agents include mono-, di-, tri-, and/or tetra-hydroxymethylated glycoluril; mono-, di-, tri-, and/or tetra-methoxymethylated glycoluril; mono-, di-, tri-, and/or tetra-ethoxymethylated glycoluril; mono-, di-, tri-, and/or tetra-propoxymethylated glycoluril; and mono-, di-, tri-, and/or tetra-butoxymethylated glycoluril.

The phenol-based crosslinking agent is not particularly limited as long as the phenol-based crosslinking agent is a compound having a plurality of phenol nucleus structures in the same molecule, and any phenol-based crosslinking agent can be selected and used. In a case where the phenol-based crosslinking agent has a plurality of phenol nucleus structures, crosslinking reactivity is improved.

The number of phenol nucleus structures is preferably in a range of 2 to 5, more preferably in a range of 2 to 4, and still more preferably 2 or 3.

Suitable examples of the phenol-based crosslinking agent are shown below.

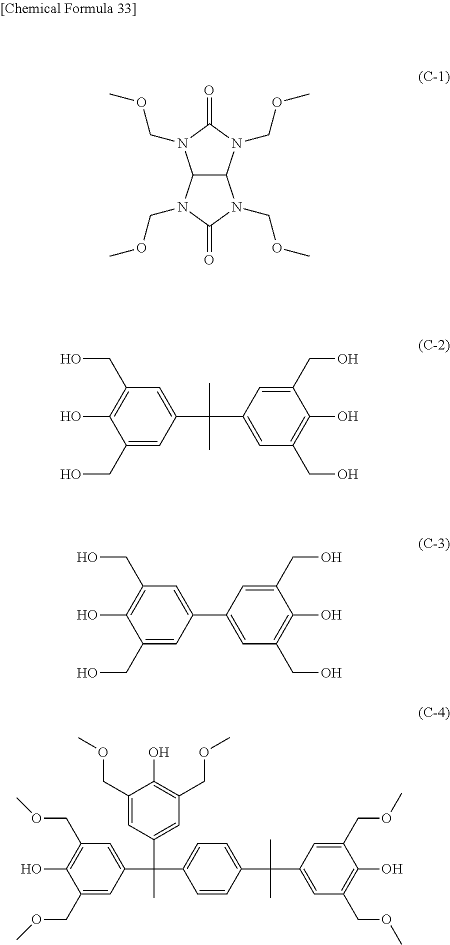

The epoxy-based crosslinking agent is not particularly limited as long as it has an epoxy group, and any epoxy-based crosslinking agent can be selected and used. Among the examples, an epoxy-based crosslinking agent containing two or more epoxy groups is preferable. In a case where the epoxy-based crosslinking agent contains two or more epoxy groups, crosslinking reactivity is improved.

The number of epoxy groups is preferably 2 or more, more preferably 2 to 4, and most preferably 2.

Suitable epoxy-based crosslinking agents are shown below.

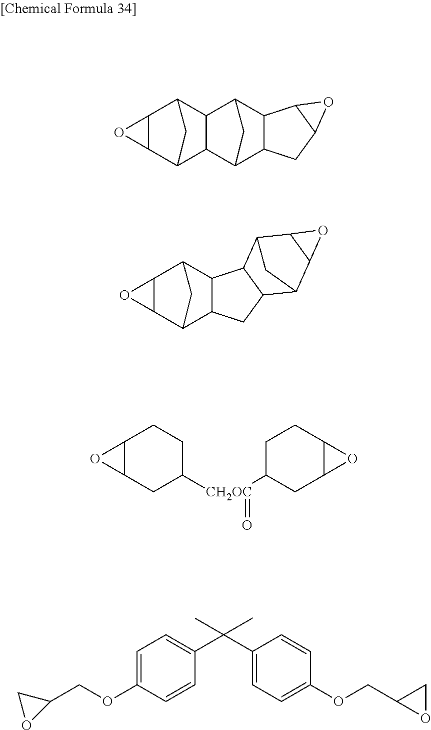

Among these, the component (C) is preferably a compound containing an alkylol group such as a methylol group, or an alkoxyalkyl group such as a methoxymethyl group, more preferably a crosslinking agent selected from the group consisting of a glycoluril-based crosslinking agent and a phenol-based crosslinking agent, and still more preferably a glycoluril-based crosslinking agent.

In the film-forming composition according to the present embodiment, the component (C) may be used alone or in combination of two or more kinds thereof.

In the film-forming composition according to the present embodiment, the content of the component (C) is preferably in a range of 1 to 50 parts by mass, more preferably in a range of 3 to 30 parts by mass, still more preferably in a range of 5 to 20 parts by mass, and most preferably in a range of 5 to 15 parts by mass with respect to 100 parts by mass of the component (A1).

In a case where the content of the component (C) is greater than or equal to the lower limits of the above-described preferable ranges, the crosslinking sufficiently proceeds so that the dissolution contrast is likely to be obtained, and thus resolution performance and lithography characteristics are further improved. In addition, a satisfactory resist pattern with less swelling can be obtained. In addition, in a case where the content thereof is less than or equal to the upper limits of the above-described preferable ranges, the storage stability of the film-forming composition is satisfactory, and the temporal deterioration of the sensitivity is likely to be suppressed.

### <Other Components>

The film-forming composition according to the present embodiment may further contain other components in addition to the component (A1), the component (B), and the component (C) described above. Known components blended into a film-forming composition formed by using a silicon-containing compound as a base material component in the related art can be used as the other components. Examples of such other components include a base component, an organic carboxylic acid and the like, a fluorine additive component, and an organic solvent component.

### <<Base Component>>

The film-forming composition according to the present embodiment may further contain a base component (hereinafter, also referred to as “component (D)”) that controls diffusion of an acid generated upon light exposure, in addition to the component (A1), the component (B), and the component (C) described above.

The component (D) acts as a quencher (an acid diffusion control agent) that traps an acid generated in the film-forming composition upon light exposure. In a case where the component (D) is further used in combination, a fine pattern is likely to be formed in a satisfactory shape particularly as “negative-tone resist composition for an alkali developing process”.

Examples of the component (D) include a photodecomposable base (D0) (hereinafter, referred to as “component (D0)”) that is decomposed upon light exposure and loses the acid diffusion controllability and a nitrogen-containing organic compound (D2) (hereinafter, referred to as “component (D2)”) which does not correspond to the component (D0). Among these, the photodecomposable base (component (D0)) is preferable from the viewpoint of easily enhancing all the characteristics of the sensitivity, reduction of the roughness, and suppression of the occurrence of coating defects.

### In Regard to Photodecomposable Base (Component (D0))

The component (D0) is not particularly limited as long as the component is decomposed upon light exposure and loses the acid diffusion controllability, and it is preferable that the component contains at least one onium salt selected from the group consisting of a compound represented by General Formula (d0-1) (hereinafter, referred to as “component (d0-1)”) and a compound represented by General Formula (d0-2) (hereinafter, referred to as “component (d0-2)”).

Since the components (d0-1) and (d0-2) are decomposed and lose the acid diffusion controllability (basicity), the components (d0-1) to (d0-2) do not act as a quencher in the exposed portion of the resist film, but act as a quencher in the unexposed portion of the resist film.

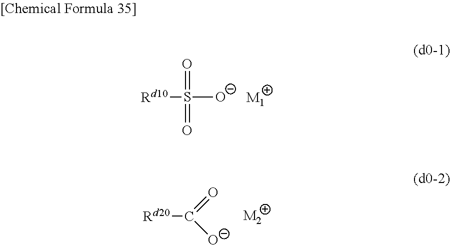

[In Formula (d0-1), R^{d10} represents an organic group having 1 to 40 carbon atoms. M₁⁺ represents an onium cation. In Formula (d0-2), R^{d20} represents an organic group having 1 to 20 carbon atoms. M₂⁺ represents an onium cation.]

In Regard to Component (d0-1)

In Formula (d0-1), examples of the organic group having 1 to 40 carbon atoms as R^{d10} include a hydrocarbon group which may have a substituent, a divalent linking group having an oxygen atom, and a combination thereof.

Examples of the organic group as R^{d10} include a cyclic group which may have a substituent, a chain-like alkyl group which may have a substituent, a chain-like alkenyl group which may have a substituent, and the same groups as described in the section of R^{b101} in Formula (b0-1b).

Among these, it is preferable that R^{d100} represents a chain-like alkyl group having an iodine atom or an aliphatic cyclic group having an iodine atom. The chain-like alkyl group has preferably 1 to 10 carbon atoms and more preferably 3 to 10 carbon atoms. As the aliphatic cyclic group, a group in which one or more hydrogen atoms have been removed from adamantane, norbornane, isobornane, tricyclodecane, or tetracyclododecane (group which may have a substituent); and a group in which one or more hydrogen atoms have been removed from camphor are more preferable.

Here, the carbon atom adjacent to the S atom in R^{d10} has no fluorine atom bonded thereto (the carbon atom is not substituted with a fluorine atom). In this manner, the anion moiety of the sulfonate represented by General Formula (d0-1) is an appropriately weak acid anion, and thus the quenching ability is improved.

The hydrocarbon group as R^{d10} may have a substituent, and examples of the substituent include the same groups as those for the substituent that the hydrocarbon group (an aromatic hydrocarbon group, an aliphatic cyclic group, a chain-like alkyl group, or a chain-like alkenyl group) as R^{b101} in Formula (b0-1b) may have.

Specific preferred examples of the anion moiety of the sulfonate which is represented by General Formula (d0-1) are shown below.

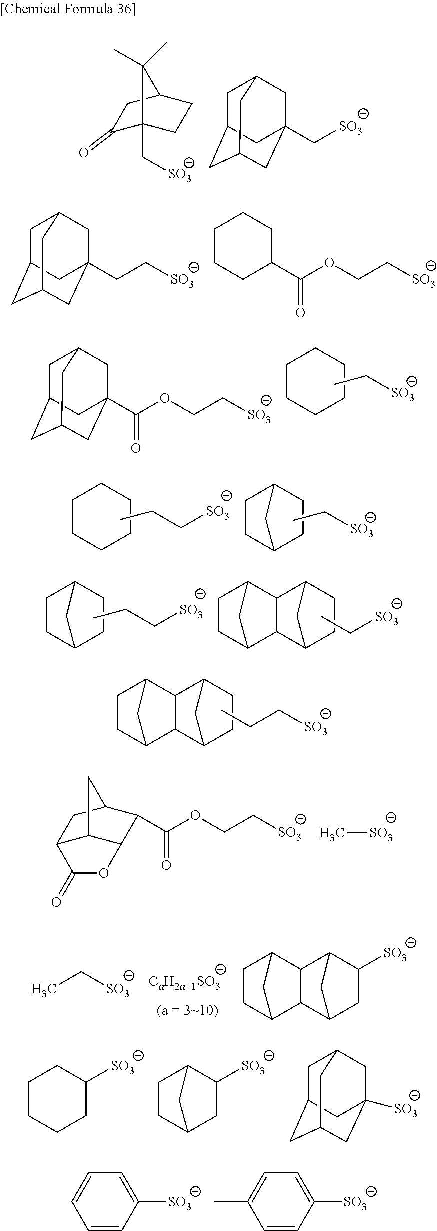

In Formula (d0-1), M₁⁺ represents an onium cation. Among the examples, a sulfonium cation or an iodonium cation is more preferable.

Suitable examples of M₁⁺ include the same cations as those each represented by General Formulae (ca-1) to (ca-3). Among these, a cation represented by General Formula (ca-1) is more preferable, and cations each represented by Formulae (ca-1-1) to (ca-1-84) are still more preferable. Among these, a cation represented by General Formula (b0-ca) is particularly preferable.

The component (d0-1) may be used alone or in combination of two or more kinds thereof.

In Regard to Component (d0-2)

In Formula (d0-2), examples of the organic group having 1 to 20 carbon atoms as R^{d20} include a hydrocarbon group which may have a substituent, a divalent linking group having an oxygen atom, and a combination thereof.

Preferred examples of the onium salt include a carboxylate represented by General Formula (d0-2d).

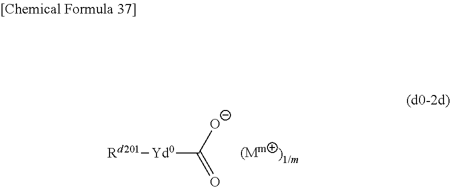

[In the formula, R^{d201} represents a cyclic group which may have a substituent, a chain-like alkyl group which may have a substituent, or a chain-like alkenyl group which may have a substituent. Yd⁰ represents a divalent linking group or a single bond. Mⁿ⁺ represents an m-valent onium cation. m represents an integer of 1 or greater.]

In Formula (d0-2d), R^{d201} represents a cyclic group which may have a substituent, a chain-like alkyl group which may have a substituent, or a chain-like alkenyl group which may have a substituent, and has the same definition as that for R^{b101} in Formula (b0-1b). Among these, R^{d201} represents preferably a cyclic group having an iodine atom or a cyclic group having a bromine atom, more preferably a cyclic group having an iodine atom, still more preferably an aromatic hydrocarbon group having an iodine atom, and even still more preferably a phenyl group having an iodine atom or a naphthyl group having an iodine atom.

Preferred examples of R^{d201} include a group represented by General Formula (b0-r-1p). nb1 in General Formula (b0-r-1p) represents an integer of 1 to 5, preferably an integer of 1 to 3, more preferably 2 or 3, and still more preferably 2. Further, it is preferable that R^{b02} in General Formula (b0-r-1p) represents a hydrogen atom from the viewpoints of the sensitivity and reduction of roughness. nb2 represents preferably 1 or 2 and more preferably 1.

In Formula (d0-2d), suitable examples of the divalent linking group as Yd⁰ include a divalent linking group having an oxygen atom.

In a case where Yd⁰ represents a divalent linking group containing an oxygen atom, Yd⁰ may have an atom other than the oxygen atom. Examples of the atom other than the oxygen atom include a carbon atom, a hydrogen atom, a sulfur atom, and a nitrogen atom.

Examples of the divalent linking group containing an oxygen atom include a non-hydrocarbon-based oxygen atom-containing linking group such as an oxygen atom (ether bond; —O—), an ester bond (—C(═O)—O—), an oxycarbonyl group (—O—C(═O)—), an amide bond (—C(═O)—NH—), a carbonyl group (—C(═O)—), or a carbonate bond (—O—C(═O)—O—); a combination of the above-described non-hydrocarbon-based oxygen atom-containing linking group with an alkylene group; and a combination of a non-hydrocarbon-based oxygen atom-containing linking group with an arylene group. Further, a sulfonyl group (—SO₂—) may be further linked to the combination. Examples of the arylene group include a phenylene group and a naphthylene group. The arylene group may have a substituent such as a halogen atom.

Among the examples, Yd⁰ represents preferably a single bond, a combination of the non-hydrocarbon-based oxygen atom-containing linking group with an alkylene group, or a combination of the non-hydrocarbon-based oxygen atom-containing linking group with an arylene group and more preferably a single bond.

Specific preferred examples of the anion moiety of the carboxylate represented by General Formula (d0-2d) are shown below.

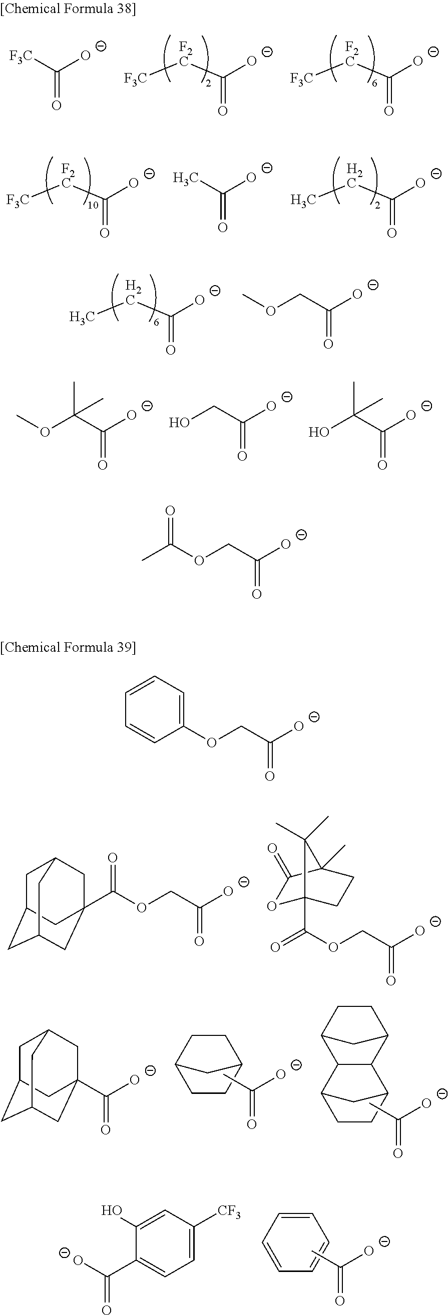

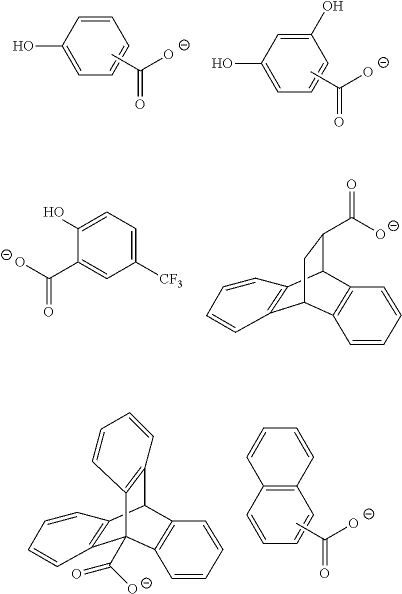

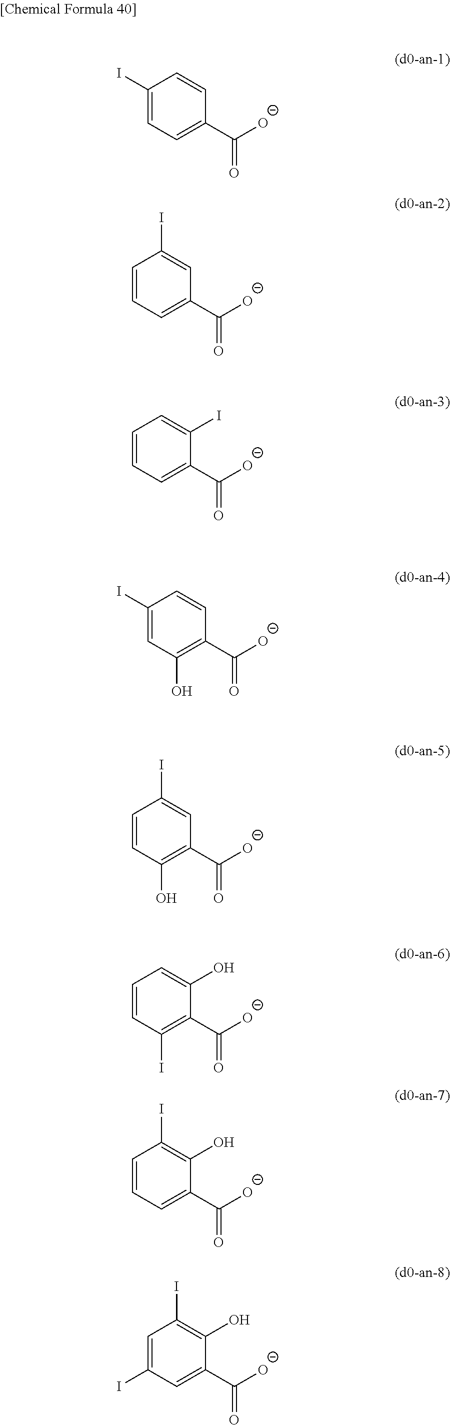

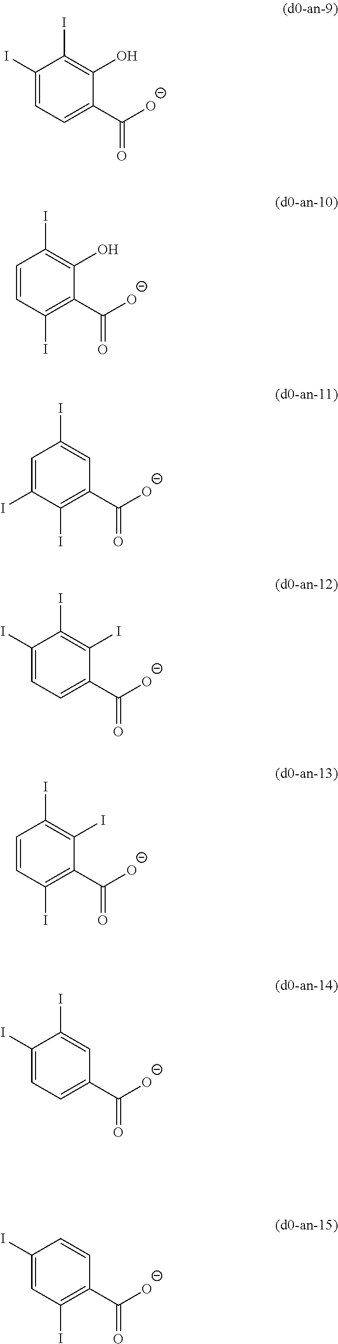

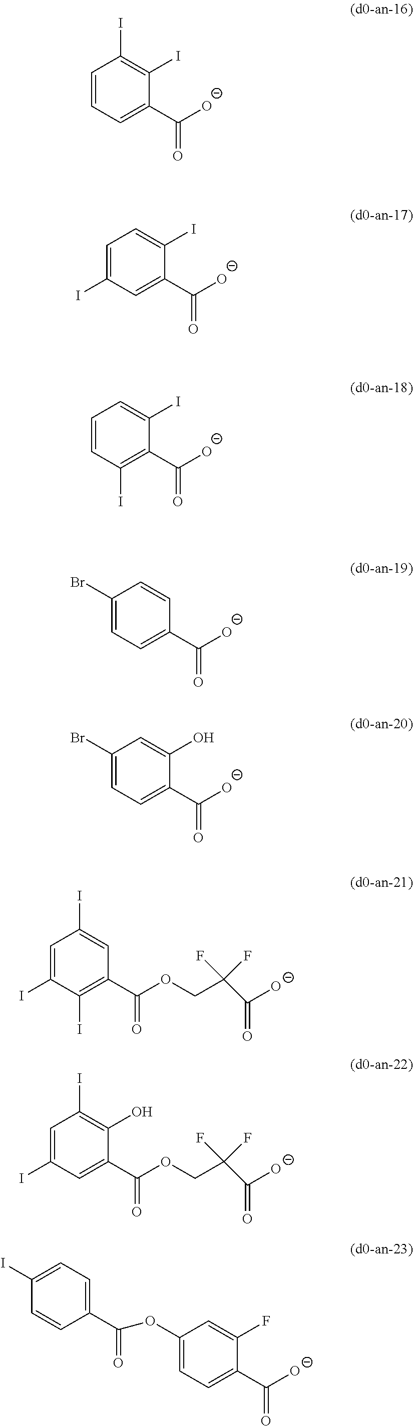

The anion moiety of the carboxylate represented by General Formula (d0-2d) is preferably a group containing a cyclic group having an iodine atom or a group containing a cyclic group having a bromine atom and more preferably at least one selected from the group consisting of anions each represented by Chemical Formulae (d0-an-1) to (d0-an-23).

Among these, a group containing a cyclic group having an iodine atom is still more preferable, and at least one selected from the group consisting of anions each represented by Chemical Formulae (d0-an-1) to (d0-an-18) and Chemical formulae (d0-an-21) to (d0-an-23) is particularly preferable.

In Formula (d0-2), M₂⁺ represents an onium cation. Among the examples, a sulfonium cation or an iodonium cation is preferable.

In Formula (d0-2d), Mⁿ⁺ represents an m-valent onium cation. Among the examples, a sulfonium cation or an iodonium cation is preferable.

Suitable examples of M₂⁺ and Mⁿ⁺ include the same cations as those each represented by General Formulae (ca-1) to (ca-3). Among these, a cation represented by General Formula (ca-1) is preferable, and cations each represented by Formulae (ca-1-1) to (ca-1-84) are still more preferable. Among these, a cation represented by General Formula (b0-ca) is particularly preferable.

The component (d0-2) may be used alone or in combination of two or more kinds thereof.

As the component (D0), only any one of the above-described components (d0-1) to (d0-2) or a combination of two or more kinds thereof may be used.

In a case where the film-forming composition contains the component (D0), the content of the component (D0) in the film-forming composition is appropriately set according to the molar ratio with the component (B), and for example, is preferably in a range of 5 to 60 parts by mass, more preferably in a range of 10 to 50 parts by mass, and still more preferably in a range of 20 to 45 parts by mass with respect to 100 parts by mass of the component (A1).

It is preferable that the component (D0) includes the component (d0-2).

The content of the component (d0-2) in the entire component (D0) is preferably 50% by mass or greater, more preferably 70% by mass or greater, and still more preferably 90% by mass or greater, and the component (D0) may be formed of only the component (d0-2).

In regard to nitrogen-containing organic compound (component (D2))

The component (D) may include a nitrogen-containing organic compound component (component (D2)) that does not correspond to the component (D0) described above.

The component (D2) is not particularly limited as long as the component acts as an acid diffusion control agent and does not correspond to the component (D0), and an optional component may be selected from known components and then used. Among the examples, an aliphatic amine is preferable, and particularly a secondary aliphatic amine and a tertiary aliphatic amine are more preferable.

The aliphatic amine is an amine containing one or more aliphatic groups, and the number of carbon atoms in the aliphatic group is preferably in a range of 1 to 12.

Examples of these aliphatic amines include amines in which at least one hydrogen atom of ammonia NH₃ has been substituted with an alkyl group or hydroxyalkyl group having 12 or less carbon atoms (alkylamines or alkylalcoholamines), and cyclic amines.

Specific examples of the alkylamines and the alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, and tri-n-dodecylamine; and alkylalcoholamines such as diethanolamine, triethanolamine, diisopropanolamine, triisopropanolamine, di-n-octanolamine, and tri-n-octanolamine. Among these, a trialkylamine having 6 to 30 carbon atoms is still more preferable, and tri-n-pentylamine or tri-n-octylamine is particularly preferable.

Examples of the cyclic amine include a heterocyclic compound having a nitrogen atom as a hetero atom. The heterocyclic compound may be a monocyclic compound (aliphatic monocyclic amine) or a polycyclic compound (aliphatic polycyclic amine).

Specific examples of the aliphatic monocyclic amine include piperidine and piperazine. The aliphatic polycyclic amine preferably has 6 to 10 carbon atoms, and specific examples thereof include 1, 5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine, and triethanolamine triacetate. Among these, triethanolamine triacetate is preferable.

As the component (D2), an aromatic amine may be used.

Examples of the aromatic amine include 4-dimethylaminopyridine, pyrrole, indole, pyrazole, imidazole, and derivatives thereof, tribenzylamine, 2,6-diisopropylaniline, N-tert-butoxycarbonylpyrrolidine, 2,6-di-tert-butylpyridine, and 2,6-tert-butylpyridine.

The component (D2) may be used alone or in combination of two or more kinds thereof. In a case where the film-forming composition contains the component (D2), the content of the component (D2) in the film-forming composition is typically in a range of 0.01 to 5 parts by mass with respect to 100 parts by mass of the component (A1). In a case where the content thereof is set to be in the above-described range, the resist pattern shape, the post exposure temporal stability, and the like are improved.

<<At Least One Compound (E) Selected from Group Consisting of Organic Carboxylic Acids, Phosphorus Oxo Acids, and Derivatives Thereof>>

For the purpose of preventing deterioration in sensitivity and improving the resist pattern shape and the post exposure temporal stability, the film-forming composition according to the present embodiment may contain, as an optional component, at least one compound (E) (hereinafter referred to as “component (E)”) selected from the group consisting of an organic carboxylic acid, and phosphorus oxo acid and a derivative thereof.

Specific examples of the organic carboxylic acid include acetic acid, malonic acid, citric acid, malic acid, succinic acid, benzoic acid, and salicylic acid. Among these, salicylic acid is preferable.

Examples of the phosphorus oxo acid include phosphoric acid, phosphonic acid, and phosphinic acid. Among these, phosphonic acid is particularly preferable.

In the film-forming composition according to the present embodiment, the component (E) may be used alone or in combination of two or more kinds thereof.

In a case where the film-forming composition contains the component (E), the content of the component (E) is preferably in a range of 0.1 to 10 parts by mass and more preferably in a range of 1 to 5 parts by mass with respect to 100 parts by mass of the component (A1). In a case where the content thereof is in the above-described ranges, the temporal stability of the film-forming composition is improved.

### <<Fluorine Additive Component (F)>>

The film-forming composition according to the present embodiment may contain a fluorine additive component (hereinafter, referred to as “component (F)”) as a hydrophobic resin. The component (F) is used to impart water repellency to the resist film and used as a resin different from the component (A), whereby the lithography characteristics can be improved.

As the component (F), for example, the fluorine-containing high molecular weight compounds described in Japanese Unexamined Patent Application, First Publication Nos. 2010-002870, 2010-032994, 2010-277043, 2011-13569, and 2011-128226 can be used.

Specific examples of the component (F) include a polymer having a constitutional unit (f1) represented by General Formula (f1-1). As the polymer, a polymer (homopolymer) formed of only the constitutional unit (f1) represented by Formula (f1-1); a copolymer of the constitutional unit (f1) and a constitutional unit (a101) containing an acid decomposable group whose polarity is increased due to the action of an acid; or a copolymer of the constitutional unit (f1), a constitutional unit derived from acrylic acid or methacrylic acid, and the constitutional unit (a101) is preferable, and a copolymer of the constitutional unit (f1) and the constitutional unit (a101) is more preferable.

Here, the constitutional unit (a101) to be copolymerized with the constitutional unit (f1) is preferably a constitutional unit derived from 1-ethyl-1-cyclooctyl (meth)acrylate or a constitutional unit derived from 1-methyl-1-adamantyl (meth)acrylate and more preferably a constitutional unit derived from 1-ethyl-1-cyclooctyl (meth)acrylate.

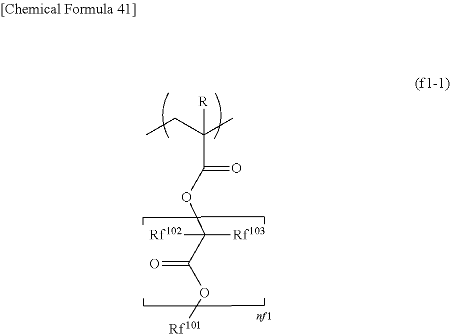

[In the formula, R has the same definition as described above, Rf¹⁰² and Rf¹¹³ each independently represent a hydrogen atom, a halogen atom, an alkyl group having 1 to 5 carbon atoms, or a halogenated alkyl group having 1 to 5 carbon atoms, and Rf¹⁰² and Rf¹⁰³ may be the same as or different from each other. nf¹ represents an integer of 0 to 5, and Rf¹⁰¹ represents an organic group having a fluorine atom.]

In General Formula (f1-1), examples of R bonded to the carbon atom at the α-position include an alkyl group having 1 to 5 carbon atoms, a halogenated alkyl group having 1 to 5 carbon atoms, or a hydrogen atom. It is preferable that R represents a hydrogen atom or a methyl group.

In Formula (f1-1), a fluorine atom is preferable as the halogen atom as Rf¹⁰² and Rf¹⁰³. The alkyl group having 1 to 5 carbon atoms as Rf¹⁰² and Rf¹⁰³ is preferably a methyl group or an ethyl group. Specific examples of the halogenated alkyl group having 1 to 5 carbon atoms for Rf¹⁰² and Rf¹⁰³ include groups in which some or all hydrogen atoms of an alkyl group having 1 to 5 carbon atoms have been substituted with halogen atoms. Among these, a fluorine atom is preferable as the halogen atom. Among these, Rf¹⁰² and Rf¹⁰³ represent preferably a hydrogen atom, a fluorine atom, or an alkyl group having 1 to 5 carbon atoms, more preferably a hydrogen atom, a fluorine atom, a methyl group, or an ethyl group, and still more preferably a hydrogen atom.

In Formula (f1-1), nf¹ represents an integer of 0 to 5, preferably an integer of 0 to 3, and more preferably 1 or 2.

In Formula (f1-1), Rf¹⁰¹ represents an organic group having a fluorine atom and preferably a hydrocarbon group having a fluorine atom.

The hydrocarbon group having a fluorine atom may be linear, branched, or cyclic, and the number of carbon atoms thereof is preferably in a range of 1 to 20, more preferably in a range of 1 to 15, and particularly preferably in a range of 1 to 10.

In the hydrocarbon group having a fluorine atom, preferably 25% or greater of the hydrogen atoms in the hydrocarbon group are fluorinated, more preferably 50% or greater thereof are fluorinated, and still more preferably 60% or greater thereof are fluorinated from the viewpoint of increasing the hydrophobicity of the resist film during immersion exposure.

Among examples, Rf¹⁰¹ represents more preferably a fluorinated hydrocarbon group having 1 to 6 carbon atoms and particularly preferably a trifluoromethyl group, —CH₂—CF₃, —CH₂—CF₂—CF₃, —CH(CF₃)₂, —CH₂—CH₂—CF₃, or —CH₂—CH₂—CF₂—CF₂—CF₂—CF₃.

The weight-average molecular weight (Mw) (in terms of polystyrene according to gel permeation chromatography) of the component (F) is preferably in a range of 1,000 to 50,000, more preferably in a range of 5,000 to 40,000, and most preferably in a range of 10,000 to 30,000. In a case where the weight-average molecular weight thereof is less than or equal to the upper limits of the above-described ranges, the resist composition exhibits sufficient solubility in a solvent for a resist enough to be used as a resist. Meanwhile, in a case where the weight-average molecular weight thereof is greater than or equal to the lower limits of the above-described ranges, water repellency of the resist film is improved.

Further, the dispersity (Mw/Mn) of the component (F) is preferably in a range of 1.0 to 5.0, more preferably in a range of 1.0 to 3.0, and most preferably in a range of 1.0 to 2.5.

In the film-forming composition according to the present embodiment, the component (F) may be used alone or in combination of two or more kinds thereof.

In a case where the film-forming composition contains the component (F), the content of the component (F) is preferably in a range of 0.5 to 10 parts by mass and more preferably in a range of 1 to 10 parts by mass with respect to 100 parts by mass of the component (A1).

### <<Organic Solvent Component (S)>>

The film-forming composition according to the present embodiment can be produced by dissolving the resist materials in an organic solvent component (hereinafter, referred to as “component (S)”).

In the film-forming composition according to the present embodiment, the component (S) may be used alone or in the form of a mixed solvent of two or more kinds thereof. Among these, propylene glycol monomethyl ether acetate (PGMEA), propylene glycol monomethyl ether, γ-butyrolactone, ethyl lactate (EL), or cyclohexanone is preferable.

Further, a mixed solvent obtained by mixing PGMEA with a polar solvent is also preferable as the component (S). The blending ratio (mass ratio) may be appropriately determined in consideration of the compatibility between PGMEA and the polar solvent.

Further, a mixed solvent of γ-butyrolactone and at least one selected from PGMEA and EL is also preferable as the component (S). In this case, as the mixing ratio, the mass ratio between the former and the latter is preferably in a range of 70:30 to 95:5.

The amount of the component (S) to be used is not particularly limited and is appropriately set to have a concentration which enables coating of a substrate or the like with the component depending on the thickness of the coating film.

In the film-forming composition according to the present embodiment, the solid content concentration of the film-forming composition is preferably in a range of 0.1% to 10% by mass, more preferably in a range of 0.2% to 5% by mass, and still more preferably in a range of 0.3% to 2% by mass from the viewpoint of coating properties with respect to a substrate or the like.

Further, in the film-forming composition according to the present embodiment, the content proportion of the component (A1) in the solid content of the film-forming composition is preferably 40% by mass or greater, more preferably 40% by mass or greater and 75% by mass or less, still more preferably 45% by mass or greater and 70% by mass or less, and particularly preferably 50% by mass or greater and 65% by mass or less.

In a case where the content proportion of the component (A1) in the solid content of the film-forming composition is in the above-described preferable ranges, the effect of reducing pattern roughness is likely to be increased, and the etching resistance is likely to be enhanced.

Further, the term “solid content of the film-forming composition” denotes the content of the components excluding the organic solvent component (S) among the components constituting the film-forming composition.

In the film-forming composition according to the present embodiment, the content proportion of the silicon (Si) in the solid content of the film-forming composition is preferably 5% by mass or greater, more preferably in a range of 5% to 20% by mass, and still more preferably in a range of 5% to 15% by mass.

The etching resistance is likely to be enhanced in a case where the content proportion of the silicon (Si) in the solid content of the film-forming composition is greater than or equal to the lower limits of the above-described preferable ranges, and a resist pattern with satisfactory lithography characteristics is likely to be formed in a case where the content proportion thereof is less than or equal to the upper limits of the above-described preferable ranges.

Other miscible additives such as an additive resin, a dissolution inhibitor, a plasticizer, a stabilizer, a colorant, a halation prevention agent, and a dye for improving the performance of the resist film can be appropriately added to as desired and contained in the film-forming composition according to the present embodiment.

For example, in the film-forming composition according to the present embodiment, a hydroxystyrene resin, a resin that is a novolak resin and does not contain silicon, or the like may be used in combination, in addition to the component (A1) described above. In the hydroxystyrene resin, the hydrogen atom at the α-position of hydroxystyrene may be substituted with a substituent. Examples of the substituent include an alkyl group and a halogenated alkyl group.

The resist material is dissolved in the component (S), impurities may be removed from the film-forming composition of the present embodiment using a porous polyimide film, a porous polyamideimide film, or the like. For example, the film-forming composition may be filtered using a filter formed of a porous polyimide film, a filter formed of a porous polyamideimide film, a filter formed of a porous polyimide film and a porous polyamideimide film, or the like. Examples of the porous polyimide film and the porous polyamideimide film include those described in Japanese Unexamined Patent Application, First Publication No. 2016-155121.

The film-forming composition according to the present embodiment described above contains a polyhedral oligomeric silsesquioxane (component (A1)) having a siloxane bond and a cage type structure containing a phenolic hydroxyl group.

Since the component (A1) has a siloxane bond, the film-forming composition according to the present embodiment is advantageous in terms that the dry etching resistance of a resist film to be formed is high as compared with a resist composition containing a typical organic material as a base material component.

In addition, since the component (A1) has a cage type structure containing a phenolic hydroxyl group, the molecular weight dispersity (Mw/Mn) is close to 1.0, and the molecular weight distribution is narrowed. In this manner, a state in which the component (A1) is more uniformly dispersed in the resist film can be prepared in the pattern formation. Therefore, according to the film-forming composition containing the component (A1), the effect of reducing the roughness of a pattern to be formed is enhanced.

Such a film-forming composition has an excellent effect of reducing the roughness and fine resolution in EUV lithography. In addition, a pattern having fine dimensions with a line width of several tens of nanometers can be formed in a satisfactory shape by suppressing roughness, which has been difficult in the related art, and thus both the etching resistance and the lithography characteristics can be achieved.

Such a film-forming composition is a resist material that can form, for example, a silicon-containing pattern having a fine line width and reduced roughness and that can be suitably used for fine processing in EUV lithography.

### (Resist Pattern Formation Method)

A resist pattern formation method according to a second aspect of the present invention includes a step of forming a resist film on a support using the film-forming composition according to the first aspect of the present invention described above (hereinafter, referred to as “step (i)”), a step of exposing the resist film to light (hereinafter, referred to as “step (ii)”), and a step of developing the resist film exposed to light to form a negative-tone resist pattern (hereinafter, referred to as “step (iii)”).

A negative-tone resist pattern formation method carried out in the following manner is an exemplary example of the embodiment of such a resist pattern formation method.

[Step (i)]

First, a support is coated with the film-forming composition according to the embodiment described above using a spinner or the like, and a baking (post applied bake (PAB)) treatment is performed, for example, under a temperature condition of 80° C. to 150° C. for 40 to 120 seconds and preferably 60 to 90 seconds to form a resist film.

[Step (ii)]

The selective light exposure is carried out on the resist film, for example, by the light exposure through a mask (mask pattern) having a predetermined pattern formed on the mask by using an exposure apparatus such as an electron beam drawing apparatus or an EUV exposure apparatus, or direct irradiation of the resist film for drawing with an electron beam without using a mask pattern.

After the light exposure, a baking (post-exposure baking (PEB)) treatment is carried out, for example, under a temperature condition of 80° C. 150° C. for 40 to 120 seconds and preferably 60 to 90 seconds.

[Step (iii)]

Next, the exposed resist film is subjected to a developing treatment. The developing treatment is conducted using an alkali developing solution in a case of an alkali developing process and using a developing solution containing an organic solvent (organic developing solution) in a case of a solvent developing process.

After the developing treatment, it is preferable to conduct a rinse treatment. As the rinse treatment, water rinsing using pure water is preferable in a case of the alkali developing process, and rinsing using a rinse solution containing an organic solvent is preferable in a case of the solvent developing process.

In a case of a solvent developing process, after the developing treatment or the rinse treatment, the developing solution or the rinse solution remaining on the pattern may be removed by a treatment using a supercritical fluid.

After the developing treatment or the rinse treatment, drying is conducted. As desired, a baking treatment (post bake) may be conducted after the developing treatment.

The support is not particularly limited and a known support of the related art can be used, and examples thereof include a substrate for an electronic component and a substrate on which a predetermined wiring pattern has been formed. Specific examples thereof include a metal substrate such as a silicon wafer, copper, chromium, iron, or aluminum; and a glass substrate. As the materials of the wiring pattern, copper, aluminum, nickel, or gold can be used.

Further, as the support, any one of the above-described supports provided with an inorganic and/or organic film on the above-described substrate may be used. As the inorganic film, an inorganic antireflection film (inorganic BARC) can be used. As the organic film, an organic film such as an organic antireflection film (organic BARC) or a lower-layer organic film used in a multilayer resist method can be used.

Here, the multilayer resist method is a method of providing at least one layer of an organic film (lower-layer organic film) and at least one layer of a resist film (upper-layer resist film) on a substrate and performing patterning of the lower-layer organic film using a resist pattern formed on the upper-layer resist film as a mask, and this method is considered to enable formation of a pattern with a high aspect ratio. That is, according to the multilayer resist method, since a desired thickness can be ensured by the lower-layer organic film, the thickness of the resist film can be reduced, and a fine pattern with a high aspect ratio can be formed.

The multilayer resist method is basically classified into a method in which a double-layer structure consisting of an upper-layer resist film and a lower-layer organic film is formed (two-layer resist method), and a method in which a multilayer structure having three or more layers consisting of an upper-layer resist film, a lower-layer organic film, and one or more intermediate layers (thin metal film and the like) provided between the upper-layer resist film and the lower-layer organic film (three-layer resist method).

The wavelength to be used for light exposure is not particularly limited and the exposure can be conducted using radiation such as an ArF excimer laser, a KrF excimer laser, an F₂ excimer laser, extreme ultraviolet (EUV) rays, vacuum ultraviolet rays (VUV), electron beams (EB), X-rays, and soft X-rays.

The resist pattern formation method according to the present embodiment is a particularly suitably used for a method in which the resist film is exposed to extreme ultraviolet (EUV) rays or electron beams (EB) in the step of exposing the resist film to light.

The exposure of the resist film to light can be a general exposure (dry exposure) conducted in air or an inert gas such as nitrogen, or liquid immersion exposure (liquid immersion lithography).

The liquid immersion lithography is an exposure method in which the region between the resist film and the lens at the lowermost position of the exposure apparatus is pre-filled with a solvent (liquid immersion medium) that has a larger refractive index than the refractive index of air, and the exposure (immersion exposure) is carried out in this state.

As the liquid immersion medium, a solvent which has a refractive index larger than the refractive index of air but smaller than the refractive index of the resist film to be exposed to light is preferable. The refractive index of such a solvent is not particularly limited as long as the refractive index is in the above-described range.

Examples of the solvent which has a refractive index that is larger than the refractive index of air but smaller than the refractive index of the resist film include water, a fluorine-based inert liquid, a silicon-based solvent, and a hydrocarbon-based solvent.

Specific examples of the fluorine-based inert liquid include a liquid containing a fluorine-based compound such as C₃HCl₂F₅, C₄F₉OCH₃, C₄F₉₀C₂H5, or C₅H3F₇ as a main component, and a liquid with a boiling point of 70° C. to 180° C. is preferable and a liquid with a boiling point of 80° C. to 160° C. is more preferable. A fluorine-based inert liquid having a boiling point in the above-described range is preferable from the viewpoint that a medium used for liquid immersion can be removed using a simple method after completion of light exposure.

As the fluorine-based inert liquid, a perfluoroalkyl compound in which all hydrogen atoms in the alkyl group have been substituted with fluorine atoms is particularly preferable. Specific examples of the perfluoroalkyl compound include a perfluoroalkylether compound and a perfluoroalkylamine compound.

Further, specific examples of the perfluoroalkylether compound include perfluoro(2-butyl-tetrahydrofuran) (boiling point of 102° C.), and specific examples of the perfluoroalkylamine compound include perfluorotributylamine (boiling point of 174° C.).

As the liquid immersion medium, water is preferable from the viewpoints of the cost, the safety, the environmental issues, and the versatility.

As the alkali developing solution used for the developing treatment in the alkali developing process, a 0.1 to 10 mass % tetramethylammonium hydroxide (TMAH) aqueous solution is an exemplary example.

The organic solvent contained in the organic developing solution used for the developing treatment in the solvent developing process may be any solvent that is capable of dissolving the component (A) (the component (A) before light exposure) and can be appropriately selected from known organic solvents. Specific examples thereof include a polar solvent such as a ketone-based solvent, an ester-based solvent, an alcohol-based solvent, a nitrile-based solvent, an amide-based solvent, and an ether-based solvent, and a hydrocarbon-based solvent.

The ketone-based solvent is an organic solvent containing C—C(═O)—C in the structure thereof. The ester-based solvent is an organic solvent containing C—C(═O)—O—C in the structure thereof. The alcohol-based solvent is an organic solvent containing an alcoholic hydroxyl group in the structure thereof. The term “alcoholic hydroxyl group” denotes a hydroxyl group bonded to a carbon atom of an aliphatic hydrocarbon group. The nitrile-based solvent is an organic solvent containing a nitrile group in the structure thereof. The amide-based solvent is an organic solvent containing an amide group in the structure thereof. The ether-based solvent is an organic solvent containing C—O—C in the structure thereof.

Some organic solvents have a plurality of the functional groups which characterize each of the solvents in the structure thereof. In such a case, the organic solvents are considered to correspond to all the solvents containing the functional groups. For example, diethylene glycol monomethylether corresponds to both the alcohol-based solvent and the ether-based solvent which have been classified above.

The hydrocarbon-based solvent is a hydrocarbon solvent which is formed of a hydrocarbon that may be halogenated and does not have a substituent other than halogen atoms. Among these, a fluorine atom is preferable as the halogen atom.

Among the examples, as the organic solvent contained in the organic developing solution, a polar solvent is preferable. Further, a ketone-based solvent, an ester-based solvent, and a nitrile-based solvent are preferable.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, propylene carbonate, γ-butyrolactone, and methylamyl ketone (2-heptanone). Among these examples, methyl amyl ketone (2-heptanone) is preferable as the ketone-based solvent.

Examples of the ester-based solvent include methyl acetate, butyl acetate, ethyl acetate, isopropyl acetate, amyl acetate, isoamyl acetate, ethyl methoxyacetate, ethyl ethoxyacetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these examples, butyl acetate is preferable as the ester-based solvent.

Examples of the nitrile-based solvent include acetonitrile, propionitrile, valeronitrile, and butyronitrile.

Known additives can be blended into the organic developing solution as necessary. Examples of the additive include a surfactant. The surfactant is not particularly limited, and for example, an ionic or non-ionic fluorine-based and/or silicon-based surfactant can be used.

The developing treatment can be performed by a known developing method, and examples thereof include a method of immersing a support in a developing solution for a certain time (a dip method), a method of raising a developing solution on the surface of a support using the surface tension and maintaining the state for a certain time (a puddle method), a method of spraying a developing solution to the surface of a support (spray method), and a method of continuously ejecting a developing solution onto a support rotating at a certain rate while scanning a developing solution ejection nozzle at a certain rate (dynamic dispense method).

As the organic solvent contained in the rinse solution used for the rinse treatment after the developing treatment in the solvent developing process, a solvent that is unlikely to dissolve a resist pattern can be appropriately selected from the organic solvents described as the organic solvent used in the organic developing solution and then used. Typically, at least one solvent selected from a hydrocarbon-based solvent, a ketone-based solvent, an ester-based solvent, an alcohol-based solvent, an amide-based solvent, and an ether-based solvent is used.

These organic solvents may be used alone or in combination of two or more kinds thereof. Further, an organic solvent other than the above-described solvents and water may be mixed and used.

The rinse treatment carried out using a rinse solution (washing treatment) can be performed according to a known rinse method. Examples of the method of performing the rinse treatment include a method of continuously ejecting a rinse solution onto a support rotating at a certain rate (rotary coating method), a method of immersing a support in a rinse solution for a certain time (dip method), and a method of spraying a rinse solution to the surface of a support (spray method).

According to the resist pattern formation method of the present embodiment described above, since the film-forming composition according to the first aspect described above is used, a pattern with fine dimensions, in which both the etching resistance and the lithography characteristics such as the effect of reducing pattern roughness are achieved, can be formed even in a case where the composition contains a silicon-containing compound as the base material component. For example, even in the lithography by EUV, a fine pattern with a size of several tens of nanometers, which has excellent fine resolution and sufficient etching resistance can be formed in a satisfactory shape. In a case of a line and space pattern (LS pattern), an LS pattern in which the roughness of a line side wall is low and has a more uniform width can be easily formed.

In particular, the resist pattern formation method according to the present embodiment is a method useful for performing alkali development on the resist film exposed to light to form a negative-tone resist pattern in the step (iii).

It is preferable that various materials (for example, a resist solvent, a developing solution, a rinse solution, a composition for forming an antireflection film, and a composition for forming a top coat) that are used in the film-forming composition according to the embodiment described above and in the resist pattern formation method according to the embodiment described above do not contain impurities such as a metal, a metal salt containing halogen, an acid, an alkali, and a component containing a sulfur atom or a phosphorus atom. Here, examples of the impurities containing metal atoms include Na, K, Ca, Fe, Cu, Mn, Mg, Al, Cr, Ni, Zn, Ag, Sn, Pb, Li, and salts thereof. The content of the impurities contained in these materials is preferably 200 ppb or less, more preferably 1 ppb or less, still more preferably 100 parts per trillion (ppt) or less, particularly preferably 10 ppt or less, and most preferably substantially zero (less than or equal to the detection limit of the measuring device).

(Polyhedral Oligomeric Silsesquioxane Represented by General Formula (a0))

The polyhedral oligomeric silsesquioxane according to a third aspect of the present invention includes a polyhedral oligomeric silsesquioxane represented by General Formula (a0) (hereinafter, this polyhedral oligomeric silsesquioxane will also be referred to as “component (A0)”).

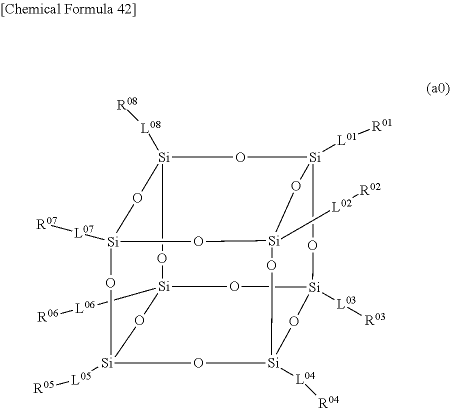

[In Formula (a0), R⁰¹ to R⁰⁸ each independently represent an aromatic group containing a phenolic hydroxyl group, a hydrocarbon group having 1 to 10 carbon atoms, or a hydrogen atom. Here, at least one of R⁰¹ to R⁰⁸ represents an aromatic group containing a phenolic hydroxyl group. L⁰¹ to L⁰⁸ each independently represent a divalent linking group represented by any one of General Formulae (a0-L-1) to (a0-L-3), (a0-L-5), and (a0-L-6).]

In Formula (a0), the description for R⁰¹ to R⁰⁸ is the same as the description for R¹ to R⁸ in Formula (a1).

Specific suitable examples of R⁰¹ to R⁰⁸ include groups each represented by Chemical Formulae (R-101) to (R-115).

In Formula (a0), L⁰¹ to L⁰⁸ each independently represent a divalent linking group represented by any of General Formulae (a0-L-1) to (a0-L-3), (a0-L-5), and (a0-L-6).

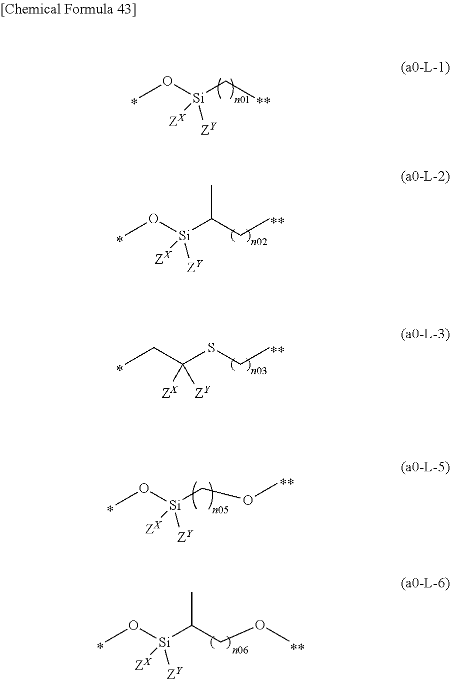

[In Formulae (a0-L-1) to (a0-L-3), (a0-L-5), and (a0-L-6), Z^{X} and Z^{Y} each independently represent a hydrocarbon group having 1 to 6 carbon atoms or a hydrogen atom. n01 represents an integer of 3 or greater. n02 represents an integer of 1 or greater. n03 represents an integer of 0 or greater. n05 represents an integer of 2 or greater. n06 represents an integer of 0 or greater. * represents a bonding site with respect to Si. ** represents a bonding site with respect to any one of R⁰¹ to R⁰⁸.]

In Formulae (a0-L-1) to (a0-L-3), (a0-L-5), and (a0-L-6), the hydrocarbon group having 1 to 6 carbon atoms as Z^{X} and Z^{Y} may be any of linear, branched, or cyclic and is preferably linear or branched. Further, the hydrocarbon group as Z^{X} and Z^{Y} may be a saturated hydrocarbon group or an unsaturated hydrocarbon group and is preferably a saturated hydrocarbon group.

The hydrocarbon group as Z^{X} and Z^{Y} has 1 to 6 carbon atoms, preferably 1 to 5 carbon atoms, and more preferably 1 to 3 carbon atoms. Among these, a methyl group, an ethyl group, a propyl group, or an isopropyl group is more preferable, a methyl group or an ethyl group is still more preferable, and a methyl group is particularly preferable.

In Formulae (a0-L-1) and (a0-L-2), it is preferable that Z^{X} and Z^{Y} each represent a hydrocarbon group having 1 to 6 carbon atoms, Z^{X} and Z^{Y} both represent more preferably a hydrocarbon group having 1 to 6 carbon atoms, still more preferably a hydrocarbon group having 1 to 3 carbon atoms, and particularly preferably a methyl group.

In Formula (a0-L-3), Z^{X} and Z^{Y} preferably each represent a hydrogen atom and more preferably both represent a hydrogen atom.

In Formulae (a0-L-5) and (a0-L-6), it is preferable that Z^{X} and Z^{Y} each represent a hydrocarbon group having 1 to 6 carbon atoms, Z^{X} and Z^{Y} both represent more preferably a hydrocarbon group having 1 to 6 carbon atoms, still more preferably a hydrocarbon group having 1 to 3 carbon atoms, and particularly preferably a methyl group.

In Formula (a0-L-1), n01 represents preferably an integer of 3 to 10, more preferably an integer of 3 to 7, still more preferably an integer of 3 to 5, and particularly preferably 3.

In Formula (a0-L-2), n02 represents preferably an integer of 1 to 10, more preferably an integer of 1 to 5, still more preferably an integer of 1 to 3, and particularly preferably 1.

In Formula (a0-L-3), n03 represents preferably an integer of 0 to 10, more preferably an integer of 0 to 5, still more preferably an integer of 0 to 3, and particularly preferably 0 or 1.

In Formula (a0-L-5), n05 represents preferably an integer of 2 to 10, more preferably an integer of 2 to 8, still more preferably an integer of 2 to 5, and particularly preferably 2 or 3.

In Formula (a0-L-6), n06 represents preferably an integer of 0 to 10, more preferably an integer of 0 to 6, still more preferably an integer of 0 to 3, and particularly preferably 0 or 1.

Specific suitable examples of L⁰¹ to L⁰⁸ include groups each represented by Chemical Formulae (L-103) to (L-107), groups each represented by Chemical Formulae (L-203) to (L-207), groups each represented by Chemical Formulae (L-301) to (L-304), groups each represented by Chemical Formulae (L-501) to (L-507), and groups each represented by Chemical Formulae (L-601) to (L-607).

The weight-average molecular weight (Mw) (in terms of polystyrene according to gel permeation chromatography (GPC)) of the polyhedral oligomeric silsesquioxane which is the component (A0) is not particularly limited, but is preferably in a range of 1,000 to 4,000, more preferably in a range of 1,200 to 3,000, and still more preferably in a range of 1,500 to 2,500.

The solubility in a solvent is sufficiently high in a case where the Mw of the component (A0) is less than or equal to the upper limits of the above-described preferable ranges, and dry etching resistance is enhanced and the cross-sectional shape of the resist pattern is satisfactory in a case where the Mw is greater than or equal to the lower limits of the above-described preferable ranges.

Further, the dispersity (Mw/Mn) of the component (A0) is not particularly limited, but is preferably in a range of 1.0 to 1.2, more preferably in a range of 1.0 to 1.1, and particularly preferably in a range of 1.0 to 1.05.

Specific suitable examples of the component (A0) include a polyhedral oligomeric silsesquioxane represented by any of Chemical Formulae (A1-2) to (A1-5).

The component (A0) can be produced by a known production method.

For example, the component (A0) can be produced by reacting a raw material (X) with a raw material (Y) described below as in Synthesis Examples (1) to (5) described below and performing a deprotection reaction as appropriate.

Raw material (X): an octasilsesquioxane having a cage type structure, in which a functional group that can react with the raw material (Y) is bonded to silicon (Si) at each apex Examples of the functional group that can react with the raw material (Y) include a dimethylsilyloxy group and a vinyl group.

Raw material (Y): a raw material that contains “aromatic group containing a phenolic hydroxyl group” Examples of the raw material include 1-(1-ethoxyethoxy)-4-vinylbenzene, 4-allylphenol, 3,4-dihydroxystyrene, 4-hydroxybenzenethiol, and 4-(mercaptomethyl)phenol.

The polyhedral oligomeric silsesquioxane according to the third aspect of the present invention described above can be a resin component useful as a base material component of a film-forming composition.

### Examples

Hereinafter, the present invention will be described in more detail based on examples, but the present invention is not limited to these examples.

### <Production of Polyhedral Oligomeric Silsesquioxane>

Each of polymers (A1-1) to (A1-5) serving as a polyhedral oligomeric silsesquioxane was produced in Synthesis Examples (1) to (5).

### Synthesis Example (1): Production of Polymer (A1-1)

2.5 g of octakis(dimethylsilyloxy)octasilsesquioxane, 4.2 g of 1-(1-ethoxyethoxy)-4-vinylbenzene, 0.25 g of platinum (0)-1,3-divinyl-1,1,3,3-tetramethyldisiloxane complex xylene solution (content of platinum: 2%), and 29 g of toluene were stirred at room temperature for 2 hours and 30 minutes.

Thereafter, 0.53 g of activated carbon was added to the solution, the solution was stirred at room temperature for 30 minutes, and the filtrate was collected by filtration using celite.

Next, the filtrate was concentrated using a rotary evaporator.

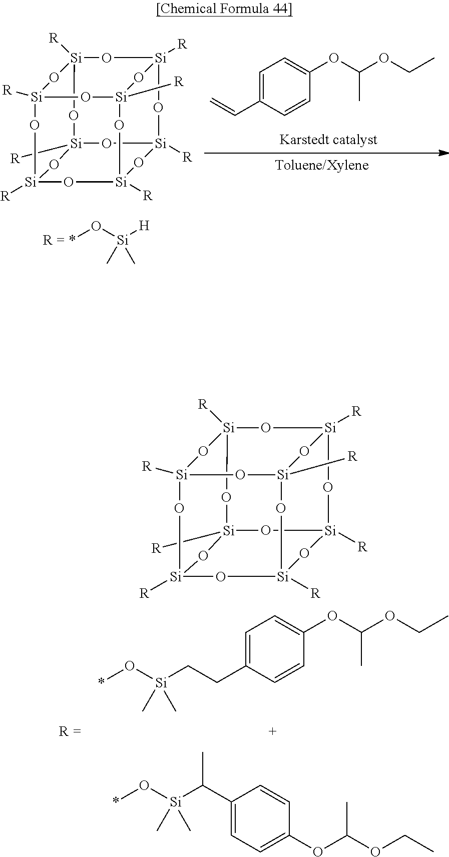

After the concentration, 63 g of tetrahydrofuran was added thereto, 96 g of 2M hydrochloric acid was added dropwise thereto over 5 minutes while the mixture was cooled in an ice bath and stirred, and the mixture was further stirred at room temperature for 2 hours.

The solution was extracted four times with 38 g of ethyl acetate and washed three times with 50 g of saturated saline. The solution was dried over sodium sulfate and concentrated using a rotary evaporator. 12 g of tetrahydrofuran was added to and dissolved in the solution, and 12 g of heptane was added thereto to re-precipitate the product. The product was purified by removing the supernatant therefrom. The purification by re-precipitation was repeated 5 times in total.

Propylene glycol monomethyl ether acetate (PGMEA) was added to the obtained product, the product was repeatedly concentrated, dried, and hardened three times using a rotary evaporator, and PGMEA was added to and dissolved in the obtained product such that the concentration reached 15%, thereby obtaining 34 g of a 15% PGMEA solution of a target polymer (A1-1).

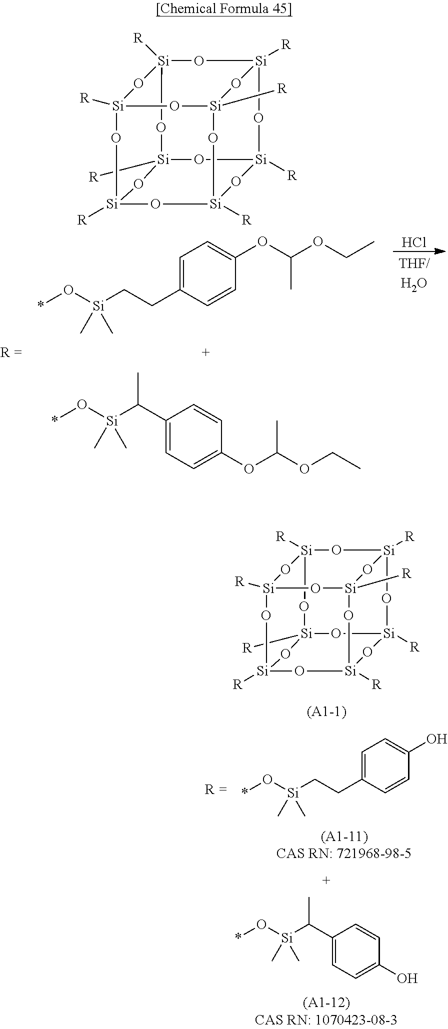

The obtained polymer (A1-1) is a mixture of a polymer in which a group (group that contains an aromatic group containing a phenolic hydroxyl group) represented by Chemical Formula (A1-11) on the upper side and a group (group that contains an aromatic group containing a phenolic hydroxyl group) represented by Chemical Formula (A1-12) on the lower side are bonded to R in the cage type structure. The introduction ratio ((A1-11):(A1-12)) of these groups to R in the cage type structure was 56:44 (molar ratio). The introduction ratio (molar ratio) between the groups was calculated from the results of NMR (the same applies hereinafter).

The polymer in which a group (group that contains an aromatic group containing a phenolic hydroxyl group) represented by Chemical Formula (A1-11) on the upper side is bonded to all R's in the cage type structure is represented by CAS RN: 721968-98-5.

The polymer in which a group (group that contains an aromatic group containing a phenolic hydroxyl group) represented by Chemical Formula (A1-12) on the lower side is bonded to all R's in the cage type structure is represented by CAS RN: 1070423-08-3.

The weight-average molecular weight (Mw) of the obtained polymer (A1-1) in terms of standard polystyrene measured by GPC was 1,900, and the molecular weight dispersity (Mw/Mn) was 1.01.

The following structure was confirmed by analyses of ¹H-NMR, ¹³C-NMR, and ²⁹Si-NMR.

[¹H-NMR (600 MHz, DMSO-d₆)]

Hydrogen of hydroxy group in R: 8H, 8.9 ppm

[¹³C-NMR (150 MHz, DMSO-d₆)]

Carbon to which hydroxy group is bonded in R: 8C, 156 ppm

[²⁹Si-NMR (120 MHz, DMSO-d₆)]

Silicon ∘ in R: 8 Si, 14 ppm

Silicon □ constituting cage form: 8Si, −109 ppm

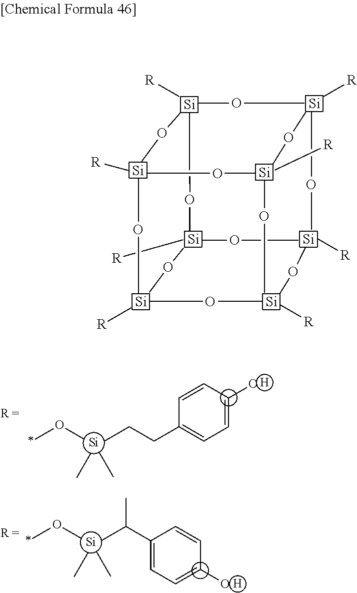

### Synthesis Example (2): Production of Polymer (A1-2)

2.5 g of octakis(dimethylsilyloxy)octasilsesquioxane, 2.9 g of 4-allylphenol, 0.25 g of platinum (0)-1,3-divinyl-1,1,3,3-tetramethyldisiloxane complex xylene solution (content of platinum: 2%), and 29 g of toluene were stirred at room temperature for 2 hours and 30 minutes.

Thereafter, 0.45 g of activated carbon was added to the solution, the solution was stirred at room temperature for 30 minutes, and the filtrate was collected by filtration using celite.

Next, the filtrate was concentrated using a rotary evaporator.

After the concentration, 12 g of tetrahydrofuran was added to and dissolved in the solution, and 12 g of heptane was added thereto to re-precipitate the product. The product was purified by removing the supernatant therefrom. The purification by re-precipitation was repeated 5 times in total.

Propylene glycol monomethyl ether acetate (PGMEA) was added to the obtained product, the product was repeatedly concentrated, dried, and hardened three times using a rotary evaporator, and PGMEA was added to and dissolved in the obtained product such that the concentration reached 15%, thereby obtaining 25 g of a 15% PGMEA solution of a target polymer (A1-2).

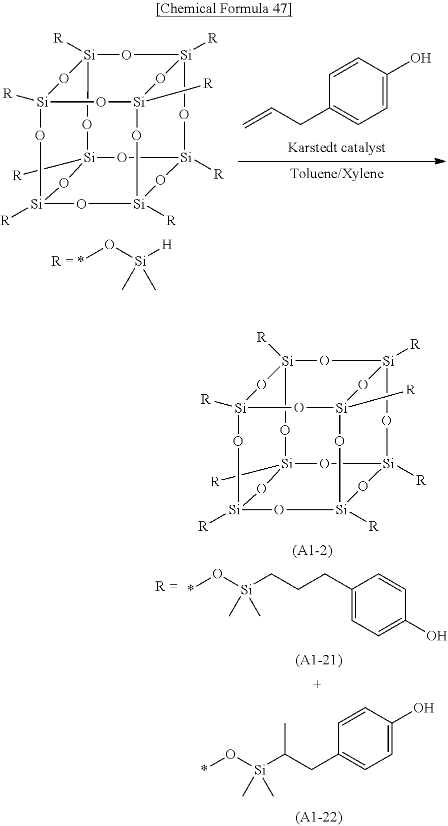

The obtained polymer (A1-2) is a mixture of a polymer in which a group (group that contains an aromatic group containing a phenolic hydroxyl group) represented by Chemical Formula (A1-21) on the upper side and a group (group that contains an aromatic group containing a phenolic hydroxyl group) represented by Chemical Formula (A1-22) on the lower side are bonded to R in the cage type structure. The introduction ratio ((A1-21):(A1-22)) of these groups to R in the cage type structure was 60:40 (molar ratio).

The weight-average molecular weight (Mw) of the obtained polymer (A1-2) in terms of standard polystyrene measured by GPC was 2,000, and the molecular weight dispersity (Mw/Mn) was 1.01.

The following structure was confirmed by analyses of ¹H-NMR, ¹³C-NMR, and ²⁹Si-NMR.

[¹H-NMR (600 MHz, DMSO-d₆)]

Hydrogen of hydroxy group in R: 8H, 8.8 ppm

[¹³C-NMR (150 MHz, DMSO-d₆)]

Carbon to which hydroxy group is bonded in R: 8C, 154 ppm

[²⁹Si-NMR (120 MHz, DMSO-d₆)]

Silicon ∘ in R: 8Si, 15 ppm

Silicon □ constituting cage form: 8Si, −110 ppm

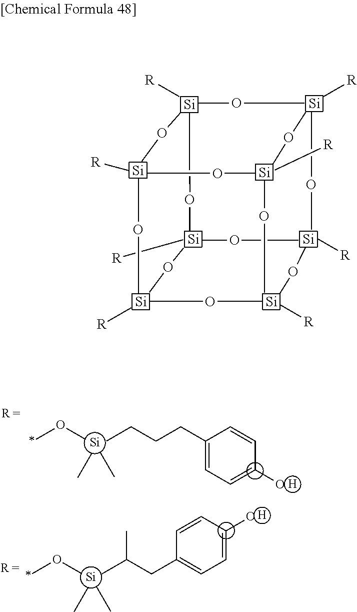

### Synthesis Example (3): Production of Polymer (A1-3)

A target polymer (A1-3) was synthesized by performing the same operation as in Synthesis Example (2) except that 2.9 g of 4-allylphenol was changed to 3.0 g of 3,4-dihydroxystyrene in Synthesis Example (2).

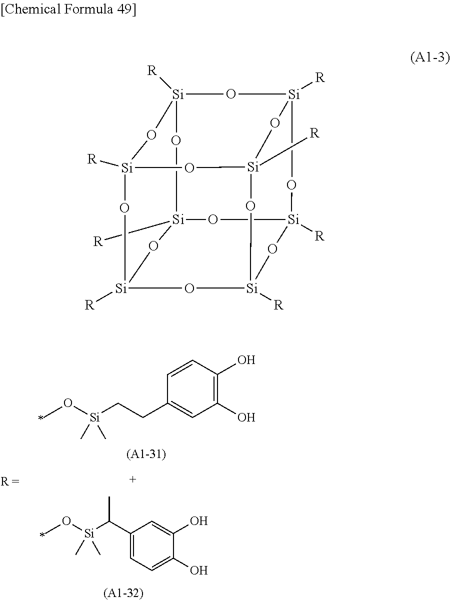

The obtained polymer (A1-3) is a mixture of a polymer in which a group (group that contains two aromatic groups containing a phenolic hydroxyl group) represented by Chemical Formula (A1-31) on the upper side and a group (group that contains two aromatic groups containing a phenolic hydroxyl group) represented by Chemical Formula (A1-32) on the lower side are bonded to R in the cage type structure. The introduction ratio ((A1-31):(A1-32)) of these groups to R in the cage type structure was 58:42 (molar ratio).

The weight-average molecular weight (Mw) of the obtained polymer (A1-3) in terms of standard polystyrene measured by GPC was 2,100, and the molecular weight dispersity (Mw/Mn) was 1.02.

The following structure was confirmed by analyses of ¹H-NMR, ¹³C-NMR, and ²⁹Si-NMR.

[¹H-NMR (600 MHz, DMSO-d₆)]

Hydrogen ∘ of 3-hydroxy group in R: 8H, 8.7 ppm

Hydrogen □ of 4-hydroxy group in R: 8H, 8.6 ppm

[¹³C-NMR (150 MHz, DMSO-d₆)]

Carbon ∘ to which 3-hydroxy group is bonded in R: 8C, 145 ppm

Carbon □ to which 4-hydroxy group is bonded in R: 8C, 143 ppm

[²⁹Si-NMR (120 MHz, DMSO-d₆)]

Silicon ∘ in R: 8 Si, 14 ppm

Silicon □ constituting cage form: 8Si, −109 ppm

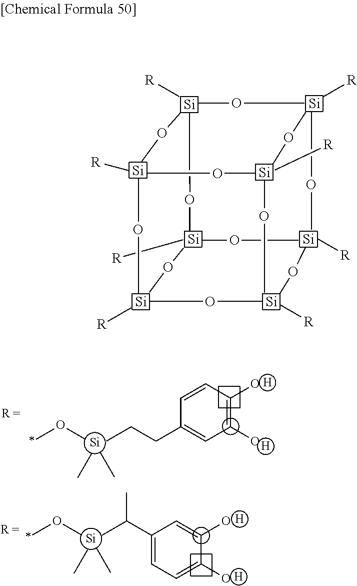

### Synthesis Example (4): Production of Polymer (A1-4)

3.2 g of 4-hydroxybenzenethiol, 2.4 g of pyridine, 6.8 g of chlorotrimethylsilane, and 9 g of toluene were stirred at 40° C. for 1 hour and 30 minutes.

Thereafter, 1.8 g of octavinyl octasilsesquioxane and 0.19 g of azobisisobutyronitrile (AIBN) were added thereto, and the solution was stirred at 70° C. for 24 hours.

The solution was filtered, and the filtrate was washed 3 times with 18 g of water.

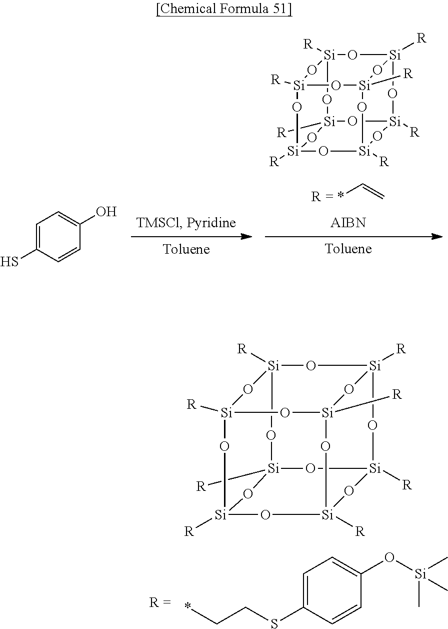

After the filtrate was washed, 63 g of tetrahydrofuran was added thereto, the mixture was cooled in an ice bath, 36 g of 2M hydrochloric acid was added dropwise thereto over 5 minutes, and the mixture was further stirred at room temperature for 2 hours.

The solution was extracted three times with 38 g of ethyl acetate and washed three times with 50 g of saturated saline. The solution was dried over sodium sulfate and concentrated using a rotary evaporator.

After the concentration, 12 g of tetrahydrofuran was added to and dissolved in the solution, and 12 g of heptane was added thereto to re-precipitate the product. The product was purified by removing the supernatant therefrom. The purification by re-precipitation was repeated 5 times in total.

Propylene glycol monomethyl ether acetate (PGMEA) was added to the obtained product, the product was repeatedly concentrated, dried, and hardened three times using a rotary evaporator, and PGMEA was added to and dissolved in the obtained product such that the concentration reached 15%, thereby obtaining 22 g of a 15% PGMEA solution of a target polymer (A1-4).

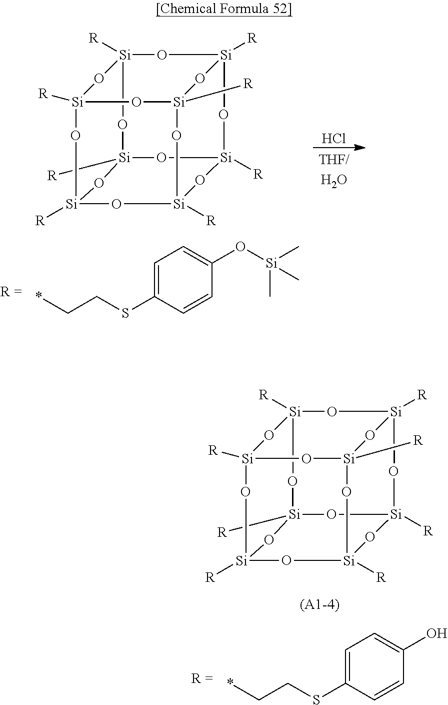

The polymer (A1-4) is a polymer in which a group represented by the chemical formula shown above (group that contains an aromatic group containing a phenolic hydroxyl group) is bonded to R in the cage type structure.

The weight-average molecular weight (Mw) of the obtained polymer (A1-4) in terms of standard polystyrene measured by GPC was 1,600, and the molecular weight dispersity (Mw/Mn) was 1.01.

The following structure was confirmed by analyses of ¹H-NMR, ¹³C-NMR, and ²⁹Si-NMR.

[¹H-NMR (600 MHz, DMSO-d₆)]

Hydrogen ∘ of hydroxy group in R: 8H, 9.4 ppm

Hydrogen Δ of CH₂ bonded to Si in R: 16H, 2.7 ppm

Hydrogen □ of CH₂ bonded to S in R: 16H, 0.8 ppm

[¹³C-NMR (150 MHz, DMSO-d₆)]

Carbon ∘ to which hydroxy group is bonded in R: 8C, 158 ppm

Carbon Δ of CH₂ bonded to Si in R: 8C, 31 ppm

Carbon □ of CH₂ bonded to S in R: 8C, 19 ppm

[²⁹Si-NMR (120 MHz, DMSO-d₆)]

Silicon constituting cage form: 8Si, −68 ppm

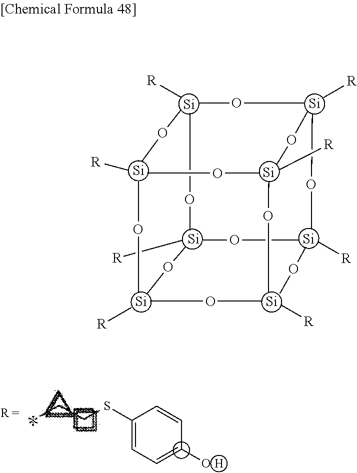

### Synthesis Example (5): Production of Polymer (A1-5)

A target polymer (A1-5) was synthesized by performing the same operation as in Synthesis Example (4) except that 3.2 g of 4-hydroxybenzenethiol was changed to 3.5 g of 4-(mercaptomethyl)phenol in Synthesis Example (4).

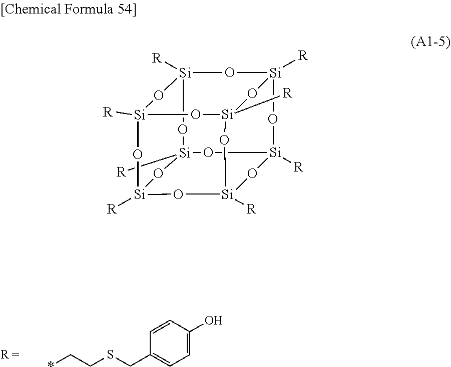

The polymer (A1-5) is a polymer in which a group represented by the chemical formula shown above (group that contains an aromatic group containing a phenolic hydroxyl group) is bonded to R in the cage type structure.

The weight-average molecular weight (Mw) of the obtained polymer (A1-5) in terms of standard polystyrene measured by GPC was 1,700, and the molecular weight dispersity (Mw/Mn) was 1.01.

The following structure was confirmed by analyses of ¹H-NMR, ¹³C-NMR, and ²⁹Si-NMR.

[¹H-NMR (600 MHz, DMSO-d₆)]

Hydrogen ∘ of hydroxy group in R: 8H, 9.3 ppm

Hydrogen Δ of CH₂ bonded to Si in R: 16H, 2.7 ppm

Hydrogen □ of CH₂ bonded to S in ethylene group of R: 16H, 1.1 ppm

[¹³C-NMR (150 MHz, DMSO-d₆)]

Carbon ∘ to which hydroxy group is bonded in R: 8C, 156 ppm

Carbon Δ of CH₂ bonded to Si in R: 8C, 26 ppm

Carbon □ of CH₂ bonded to S in ethylene group of R: 8C, 13 ppm

[²⁹Si-NMR (120 MHz, DMSO-d₆)]

Silicon constituting cage form: 8Si, −69 ppm

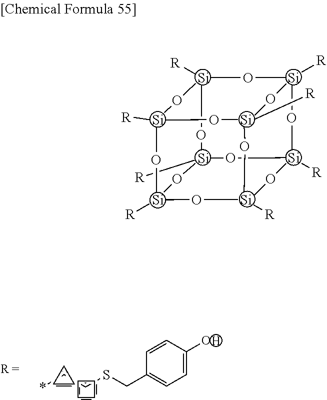

### <Preparation of Film-Forming Composition>

### Examples 1 to 13 and Comparative Examples 1 to 6

The components listed in Tables 1 and 2 were mixed and dissolved to prepare a film-forming composition of each example.

TABLE 1

| | Component | Component | Component | Component | Component | | |
|---|---|---|---|---|---|---|---|
| | (A) | (B) | (D) | (C) | (E) | Component (S) | |
| Example 1 | (A)-1 | (B)-1 | (D)-1 | (C)-1 | (E)-1 | (S)-1 | (S)-2 |
| | [100] | [32] | [41] | [10] | [3] | [15800] | [4000] |
| Example 2 | (A)-2 | (B)-1 | (D)-1 | (C)-1 | (E)-1 | (S)-1 | (S)-2 |
| | [100] | [32] | [41] | [10] | [3] | [15800] | [4000] |
| Example 3 | (A)-3 | (B)-1 | (D)-1 | (C)-1 | (E)-1 | (S)-1 | (S)-2 |
| | [100] | [32] | [41] | [10] | [3] | [15800] | [4000] |
| Example 4 | (A)-4 | (B)-1 | (D)-1 | (C)-1 | (E)-1 | (S)-1 | (S)-2 |
| | [100] | [32] | [41] | [10] | [3] | [15800] | [4000] |
| Example 5 | (A)-5 | (B)-1 | (D)-1 | (C)-1 | (E)-1 | (S)-1 | (S)-2 |
| | [100] | [32] | [41] | [10] | [3] | [15800] | [4000] |
| Example 6 | (A)-1 | (B)-2 | (D)-1 | (C)-1 | (E)-1 | (S)-1 | (S)-2 |
| | [100] | [36] | [41] | [10] | [3] | [15800] | [4000] |
| Example 7 | (A)-1 | (B)-1 | (D)-2 | (C)-1 | (E)-1 | (S)-1 | (S)-2 |
| | [100] | [32] | [27] | [10] | [3] | [15800] | [4000] |
| Example 8 | (A)-1 | (B)-1 | (D)-1 | (C)-2 | (E)-1 | (S)-1 | (S)-2 |
| | [100] | [32] | [41] | [10] | [3] | [15800] | [4000] |
| Example 9 | (A)-1 | (B)-2 | (D)-2 | (C)-1 | (E)-1 | (S)-1 | (S)-2 |
| | [100] | [36] | [27] | [10] | [3] | [15800] | [4000] |
| Example 10 | (A)-1 | (B)-2 | (D)-1 | (C)-2 | (E)-1 | (S)-1 | (S)-2 |
| | [100] | [36] | [41] | [10] | [3] | [15800] | [4000] |
| Example 11 | (A)-1 | (B)-1 | (D)-2 | (C)-2 | (E)-1 | (S)-1 | (S)-2 |
| | [100] | [32] | [27] | [10] | [3] | [15800] | [4000] |
| Example 12 | (A)-1 | (B)-2 | (D)-2 | (C)-2 | (E)-1 | (S)-1 | (S)-2 |
| | [100] | [36] | [27] | [10] | [3] | [15800] | [4000] |
| Example 13 | (A)-1 | (B)-1 | (D)-1 | (C)-1 | (E)-1 | (S)-1 | (S)-2 |
| | [75] | [32] | [41] | [10] | [3] | [15800] | [4000] |
| | (A)-6 | | | | | | |
| | [25] | | | | | | |

TABLE 2

| | Component | Component | Component | Component | Component | | |
|---|---|---|---|---|---|---|---|
| | (A) | (B) | (D) | (C) | (E) | Component (S) | |
| Comparative | (A)-6 | (B)-1 | (D)-1 | (C)-1 | (E)-1 | (S)-1 | (S)-2 |
| Example 1 | [100] | [32] | [41] | [10] | [3] | [15800] | [4000] |
| Comparative | (A)-7 | (B)-1 | (D)-1 | — | (E)-1 | (S)-1 | (S)-2 |
| Example 2 | [100] | [32] | [41] | | [3] | [15800] | [4000] |
| Comparative | (A)-7 | (B)-1 | (D)-1 | (C)-1 | (E)-1 | (S)-1 | (S)-2 |
| Example 3 | [100] | [32] | [41] | [10] | [3] | [15800] | [4000] |
| Comparative | (A)-8 | (B)-1 | (D)-1 | — | (E)-1 | (S)-1 | (S)-2 |
| Example 4 | [100] | [32] | [41] | | [3] | [15800] | [4000] |
| Comparative | (A)-8 | (B)-1 | (D)-1 | (C)-1 | (E)-1 | (S)-1 | (S)-2 |
| Example 5 | [100] | [32] | [41] | [10] | [3] | [15800] | [4000] |
| Comparative | (A)-9 | (B)-1 | (D)-1 | (C)-1 | (E)-1 | (S)-1 | (S)-2 |
| Example 6 | [100] | [32] | [41] | [10] | [3] | [15800] | [4000] |

In Tables 1 and 2, each abbreviation has the following meaning. The numerical values in the brackets denote blending amounts (parts by mass).

(A)-1 to (A)-5: polymers (A1-1) to (A1-5) shown above

(A)-6: polymer having repeating structure of constitutional unit represented by Chemical Formula (A2-1). The weight-average molecular weight (Mw) of the polymer (A2-1) in terms of standard polystyrene measured by GPC was 5,100, the molecular weight dispersity (Mw/Mn) was 1.48, and the ratio (molar ratio) of the constitutional unit in the structural formula was 1=100.

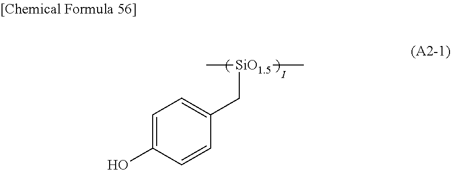

(A)-7: polymer represented by Chemical Formula (A2-2). The weight-average molecular weight (Mw) of the polymer (A2-2) in terms of standard polystyrene measured by GPC was 200,000, and the molecular weight dispersity (Mw/Mn) was 10.

* The polymer (A2-2) is a polymer in which a group represented by Chemical Formula [M-2] or a group represented by Chemical Formula [M-3] is bonded to R in a polymer [M-1]. The introduction ratio of these groups (polymer [M-1]: group represented by Chemical Formula [M-2]: group represented by Chemical Formula [M-3]) to R in the polymer [M-1] was 1:2.5:5.5 (molar ratio). In the group represented by Chemical Formula [M-3], the terminals (*) on both sides are each bonded to R in the polymer [M-1].

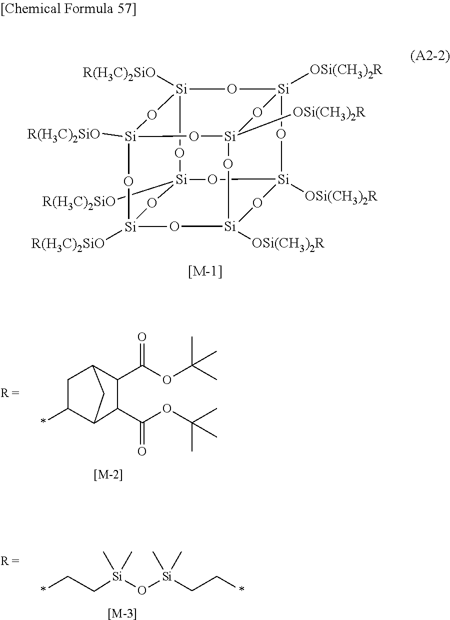

(A)-8: polymer represented by Chemical Formula (A2-3). The polymer (A2-3) is a polymer in which a group represented by the following chemical formula (group containing a tert-butoxycarbonyl group) is bonded to R in the cage type structure. The weight-average molecular weight (Mw) of the polymer (A2-3) in terms of standard polystyrene measured by GPC is 1,819.

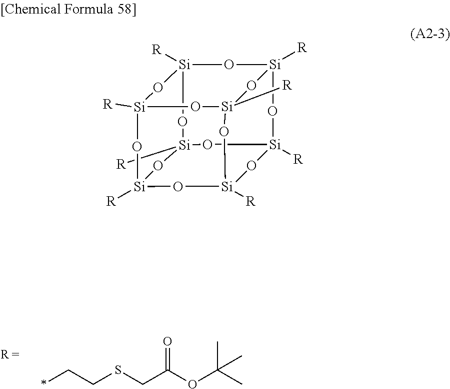

(A)-9: polymer having repeating structure of constitutional unit represented by Chemical Formula (A2-4). The weight-average molecular weight (Mw) of the polymer (A2-4) in terms of standard polystyrene measured by GPC was 58,600, and the molecular weight dispersity (Mw/Mn) was 3.31.

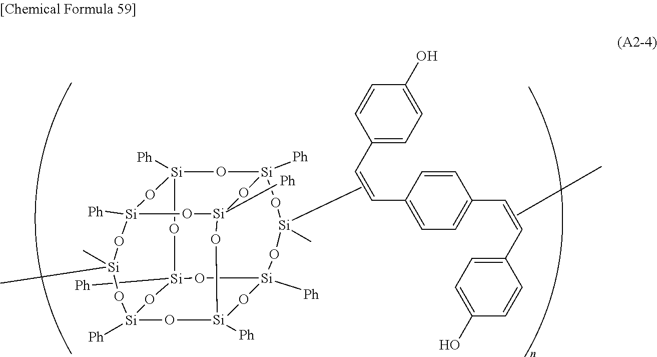

(B)-1: acid generating agent formed of the compound represented by Chemical Formula (B0-11)

(B)-2: acid generating agent formed of the compound represented by Chemical Formula (B0-12)

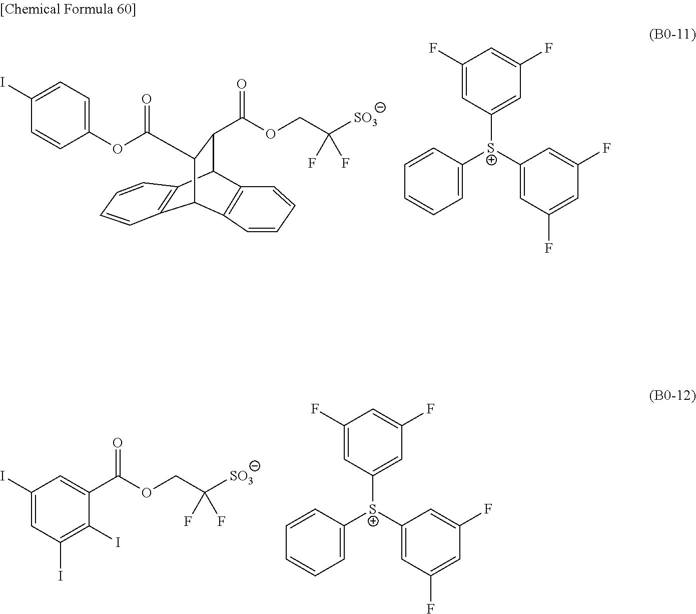

(D)-1: base formed of the compound represented by Chemical Formula (DO-21)

(D)-2: base formed of the compound represented by Chemical Formula (DO-22)

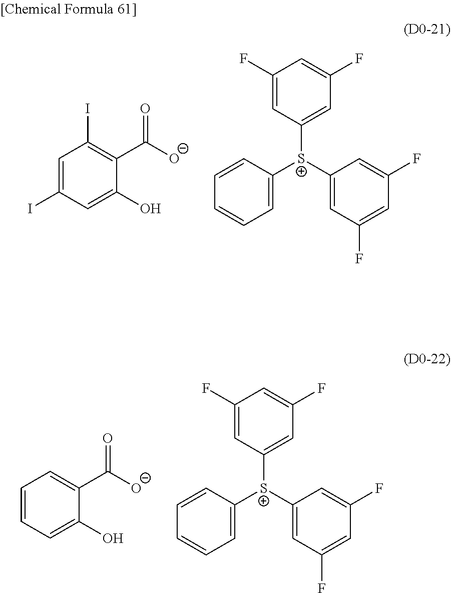 [SMILES: O=C([O-])c1c(O)cc(I)cc1I ; Fc1cc(F)cc([S+](c2ccccc2)c2cc(F)cc(F)c2)c1 ; O=C([O-])c1ccccc1O ; Fc1cc(F)cc([S+](c2ccccc2)c2cc(F)cc(F)c2)c1]

(C)-1: A crosslinking agent consisting of the compound represented by Chemical Formula (C-1).

(C)-2: A crosslinking agent consisting of the compound represented by Chemical Formula (C-2).

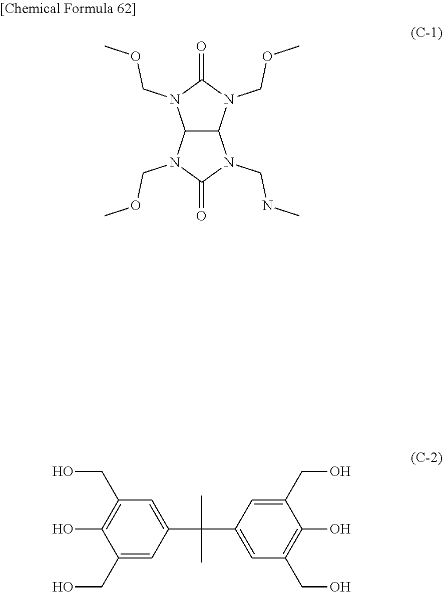

(E)-1: Salicylic acid.

(S)-1: Propylene glycol monomethyl ether.

(S)-2: Propylene glycol monomethyl ether acetate.

### <Resist Pattern Formation>

A 12-inch silicon wafer was coated with a resist organic underlayer film composition “AL412” (manufactured by Brewer Science Inc.) using a spin coater and sintered on a hot plate at 205° C. for 60 seconds, thereby forming an organic underlayer film having a film thickness of 20 nm.

The organic underlayer film was coated with the film-forming composition of each example using a spin coater, and subjected to a pre-baking (PAB) treatment on a hot plate at 90° C. for 60 seconds, thereby forming a resist film having a film thickness of 22 nm.

Next, the resist film was irradiated with EUV light (13.5 nm) through a photomask by an EUV exposure apparatus NXE3400 (manufactured by ASML Holding N.V., numerical aperture (NA)=0.33, illumination conditions: annular α-in =0.60, α-out=0.82).

Thereafter, a PEB treatment was carried out at 90° C. for 60 seconds.

Next, alkali development was carried out with a 2.38 mass % TMAH aqueous solution (trade name: NMD-3, manufactured by Tokyo Ohka Kogyo Co., Ltd.) at 23° C. for 10 seconds.

Thereafter, water rinsing was carried out for 30 seconds using pure water, followed by shake-off drying.

In this manner, a line and space pattern (LS pattern) having a line width of 14 nm was formed.

### [Evaluation of Optimum Exposure Amount (Eop)]

An optimum exposure amount Eop (mJ/cm²) for forming an LS pattern having a line width of 14 nm was determined by the resist pattern formation. The results are listed in Tables 3 and 4.

### [Evaluation of Line Width Roughness (LWR)]

In the LS pattern having a line width of 14 nm formed by the resist pattern formation described above, 3σ, which is a scale indicating LWR, was determined. The results are listed in Tables 3 and 4.

Here, “3σ” denotes three times (3σ) (unit: nm) the standard deviation (σ) determined based on the result of measurement performed by measuring 400 sites of line positions in the longitudinal direction of the line using a scanning electron microscope (trade name: S-9380, manufactured by Hitachi High-Technologies Corporation, accelerating voltage of 800 V).

In a case where the value of the 3a decreases, this indicates that the roughness of a line side wall decreases and an LS pattern with a uniform width can be obtained.

TABLE 3

| | PAB | PEB | Eop | LWR |
|---|---|---|---|---|
| | (° C.) | (° C.) | (mJ/cm²) | (nm) |
| Example 1 | 90 | 90 | 55 | 2.10 |
| Example 2 | 90 | 90 | 54 | 2.15 |
| Example 3 | 90 | 90 | 61 | 2.22 |
| Example 4 | 90 | 90 | 59 | 2.20 |
| Example 5 | 90 | 90 | 58 | 2.23 |
| Example 6 | 90 | 90 | 53 | 2.17 |
| Example 7 | 90 | 90 | 58 | 2.24 |
| Example 8 | 90 | 90 | 60 | 2.20 |
| Example 9 | 90 | 90 | 57 | 2.25 |
| Example 10 | 90 | 90 | 59 | 2.34 |
| Example 11 | 90 | 90 | 62 | 2.29 |
| Example 12 | 90 | 90 | 58 | 2.19 |
| Example 13 | 90 | 90 | 59 | 2.40 |

TABLE 4

| | PAB | PEB | Eop | LWR |
|---|---|---|---|---|
| | (° C.) | (° C.) | (mJ/cm²) | (nm) |
| Comparative Example 1 | 90 | 90 | 56 | 2.70 |

| | | | |
|---|---|---|---|
| Comparative Example 2 | 90 | 90 | No resolution |
| Comparative Example 3 | 90 | 90 | No resolution |
| Comparative Example 4 | 90 | 90 | No resolution |
| Comparative Example 5 | 90 | 90 | No resolution |

| | | | | |
|---|---|---|---|---|
| Comparative Example 6 | 90 | 90 | 53 | 3.53 |

As shown in the results in Tables 3 to 4, it can be confirmed that in the film-forming compositions of Examples 1 to 13 to which the present invention had been applied, the roughness of line side wall was reduced and a resist pattern having a more satisfactory shape was formed as compared with the film-forming compositions in Comparative Examples 1 and 6.

Further, in a case where the film-forming compositions of Comparative Examples 2 to 5 were used, no resolution occurred.

Hereinbefore, the preferable examples of the present invention have been described, but the present invention is not limited thereto. Additions, omissions, substitutions, and other modifications can be made without departing from the scope of the invention. Accordingly, the present invention is not limited by the description above but by the scope of the appended claims.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

What is claimed is:

1. A film-forming composition comprising:
a silicon-containing compound (A);
an acid generating agent component that generates an acid upon light exposure; and
a crosslinking agent component,
wherein the silicon-containing compound (A) contains a polyhedral oligomeric silsesquioxane (A1) represented by General Formula (a1): 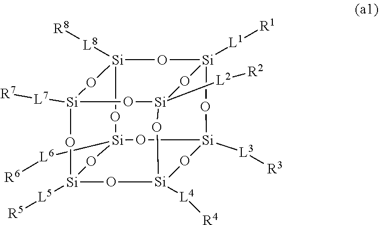
wherein R¹ to R⁸ each independently represents an aromatic group containing a phenolic hydroxyl group, a hydrocarbon group having 1 to 10 carbon atoms, or a hydrogen atom, where at least one of R¹ to R⁸ represents an aromatic group containing a phenolic hydroxyl group, and L¹ to L⁸ each independently represents a divalent linking group represented by any one of General Formulae (a1-L-1) to (a1-L-6), where at least one of L¹ to L⁸ represents a divalent linking group represented by General Formula (a1-L-2) or General Formula (a1-L-3); 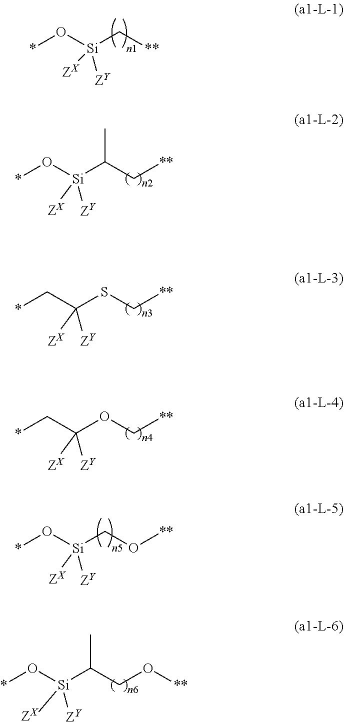
wherein Z^{X} and Z^{Y} each independently represents a hydrocarbon group having 1 to 6 carbon atoms or a hydrogen atom, n1 to n6 each independently represents an integer of 0 to 10, * represents a bonding site with respect to Si, and ** represents a bonding site with respect to any one of R¹ to R⁸.

2. The film-forming composition according to claim 1, further comprising a base component that controls diffusion of the acid generated upon light exposure.

3. The film-forming composition according to claim 1, wherein a content of the silicon-containing compound (A) is less than 5% by mass with respect to a total mass of the film-forming composition.

4. The film-forming composition according to claim 1, wherein a total content of polyhedral oligomeric silsesquioxanes including the polyhedral oligomeric silsesquioxane (A1) in the silicon-containing compound (A) is 70% by mass or greater with respect to a total mass of the silicon-containing compound (A).

5. The film-forming composition according to claim 1, wherein the acid generating agent component contains an onium salt represented by General Formula (b0): 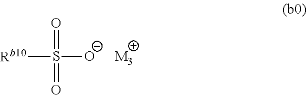
wherein R^{b10} represents an organic group having 1 to 40 carbon atoms, and M₃⁺ represents an onium cation.

6. The film-forming composition according to claim 2, wherein the base component contains at least one onium salt selected from the group consisting of a compound represented by General Formula (d0-1) and a compound represented by General Formula (d0-2): 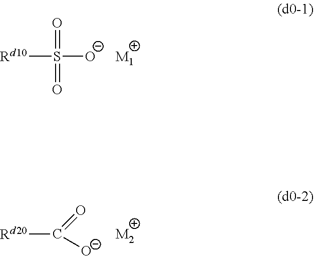
wherein in Formula (d0-1), R^{d10} represents an organic group having 1 to 40 carbon atoms, and M₁⁺ represents an onium cation, and in Formula (d0-2), R^{d20} represents an organic group having 1 to 20 carbon atoms, and M₂⁺ represents an onium cation.

7. A method of forming a resist pattern, the method comprising:
forming a resist film on a support using the film-forming composition according to claim 2;
exposing the resist film to light; and
developing the resist film exposed to light to form a negative-tone resist pattern.

8. A polyhedral oligomeric silsesquioxane which is represented by General Formula (a0): 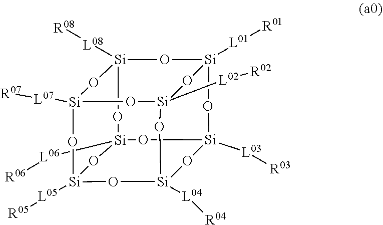
wherein R⁰¹ to R⁰⁸ each independently represents an aromatic group containing a phenolic hydroxyl group, a hydrocarbon group having 1 to 10 carbon atoms, or a hydrogen atom, where at least one of R⁰¹ to R⁰⁸ represents an aromatic group containing a phenolic hydroxyl group, and L⁰¹ to L⁰⁸ each independently represents a divalent linking group represented by any one of General Formulae (a0-L-1) to (a0-L-3), (a0-L-5), and (a0-L-6), 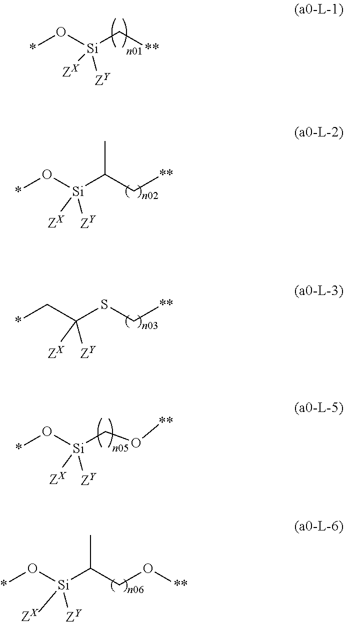
wherein Z^{X} and Z^{Y} each independently represents a hydrocarbon group having 1 to 6 carbon atoms or a hydrogen atom, n01 represents an integer of 3 or greater, n02 represents an integer of 1 or greater, n03 represents an integer of 0 or greater, n05 represents an integer of 2 or greater, n06 represents an integer of 0 or greater, * represents a bonding site with respect to Si, and ** represents a bonding site with respect to any one of R⁰¹ to R⁰⁸.
